(19) United States
(12) Patent Application Publication
(10) Pub. No.: US 2020/0098996 A1
(43) Pub. Date: Mar. 26, 2020

(54) MIXTURES COMPRISING AT LEAST TWO ORGANOFUNCTIONAL COMPOUNDS

(71) Applicant: Merck Patent GmbH, Darmstadt (DE)

(72) Inventors: NILS KOENEN, Griesheim (DE); Irina MARTYNOVA, Griesheim (DE); Anja JATSCH, Frankfurt am Main (DE); Volker HILARIUS, Gross-Umstadt (DE); Claus-Peter NIESERT, Seeheim-Jugenheim (DE)

(21) Appl. No.: 16/471,771

(22) PCT Filed: Dec. 19, 2017
(86) PCT No.: PCT/EP2017/083438

§ 371 Date: Jun. 20, 2019

(30) Foreign Application Priority Data
Dec. 22, 2016 (EP) 16206133.7

(51) Int. Cl. H01L 51/00

(52) U.S. Cl. CPC H01L 51/0072; H01L 51/0067; H01L 51/006; H01L 51/0058; H01L 51/0073; H01L 51/0074; H01L 51/0056

(57) ABSTRACT

The present invention describes mixtures comprising at least two organic-functional compounds OSM1 and OSM2 that are constitutional isomers of one another, especially for use in electronic devices. The invention further relates to a process for preparing the mixtures of the invention and to electronic devices comprising these.

The present invention describes mixtures comprising at least two organic-functional compounds, especially for use in electronic devices. The invention further relates to a process for preparing the mixtures of the invention comprising at least two organic-functional compounds, and to electronic devices comprising these compounds.

Electronic devices containing organic, organometallic and/or polymeric semiconductors are becoming increasingly important, and are being used in many commercial products for reasons of cost and because of their performance. Examples here include organic-based charge transport materials (for example triarylamine-based hole transporters) in photocopiers, organic or polymeric light-emitting diodes (OLEDs or PLEDs) and in readout and display devices or organic photoreceptors in photocopiers. Organic solar cells (O-SCs), organic field-effect transistors (O-FETs), organic thin-film transistors (O-TFTs), organic integrated circuits (O-ICs), organic optical amplifiers and organic laser diodes (O-lasers) are at an advanced stage of development and may have great future significance.

These devices are in many cases produced using solutions of organic-functional materials. However, since the solubility of these materials is relatively low in many cases, solutions that are highly concentrated or oversaturated with respect to the solubility limit are used, but these have a tendency to crystallize in the event of minor perturbations, for example variations in temperature, mechanical stresses, etc.

This problem has to date been solved by using solubility-improving groups as described, for example, in WO 2011/137922 A1. Moreover, documents US 2003/031893 A1 and US 2007/020485 A1 disclose stereoisomers, but these do not lead to a satisfactory solution to the problem detailed above. Known compounds or compositions for production of electronic devices have a usable profile of properties. However, there is a constant need to improve the properties of these materials and devices.

These properties especially include the processibility, transportability and storability of materials for production of electronic devices.

Moreover, the lifetime of the electronic devices and other properties thereof should at the same time not be adversely affected by the improvement in the materials in the abovementioned respect. These include the energy efficiency with which an electronic device solves the problem defined. In the case of organic light-emitting diodes, which may be based either on low molecular weight compounds or on polymeric materials, the light yield in particular should be sufficiently high that a minimum amount of electrical power has to be applied to achieve a particular luminous flux. In addition, a minimum voltage should also be necessary to achieve a defined luminance.

A further problem addressed can be considered that of providing electronic devices having excellent performance very inexpensively and in constant quality.

Furthermore, it should be possible to use or adapt the electronic devices for many purposes. More particularly, the performance of the electronic devices should be maintained over a broad temperature range.

A further problem addressed by the present invention is that of providing materials which are suitable for use in an organic electronic device, especially in an organic electroluminescent device, and which lead to good device properties when used in this device, and that of providing the corresponding electronic device.

More particularly, the problem addressed by the present invention is that of providing compounds which lead to a high lifetime, good efficiency and low operating voltage. Particularly the properties of the matrix materials too have an essential influence on the lifetime and efficiency of the organic electroluminescent device.

A further problem addressed by the present invention can be considered that of providing compounds suitable for use in a phosphorescent or fluorescent OLED, especially as a matrix material. A particular problem addressed by the present invention is that of providing matrix materials suitable for red-, yellow- and green-phosphorescing OLEDs and possibly also for blue-phosphorescing OLEDs. In addition, fluorescent emitters having excellent properties should be provided.

Moreover, the compounds should be processible in a very simple manner, and especially exhibit good solubility and film formation. For example, the compounds should exhibit elevated oxidation stability and an improved glass transition temperature.

It has been found that, surprisingly, particular compounds that are described in detail hereinafter solve these problems and eliminate the disadvantage from the prior art. The use of mixtures can especially achieve improvements with regard to the processibility, transportability and storability of materials for production of electronic devices. In this context, the use of mixtures leads to very good properties of organic electronic devices, especially of organic electroluminescent devices, especially with regard to lifetime, efficiency and operating voltage. The present invention therefore provides electronic devices, especially organic electroluminescent devices, containing such mixtures, and the corresponding preferred embodiments.

The present invention therefore provides a mixture comprising at least two organic-functional compounds OSM1 and OSM2 usable for production of functional layers of electronic devices, which is characterized in that the compounds OSM1 and OSM2 are constitutional isomers of one another.

Constitutional isomers are compounds that have the same general empirical formula but differ in their constitution, i.e. in their structure, such that they can have a different sequence of the atoms and/or different bonds. Constitutional isomers are therefore fundamentally different from stereoisomers, which include both enantiomers and diastereomers.

Constitutional isomers are in many cases grouped into functional isomers, skeletal isomers, positional isomers and bonding isomers. In the case of functional isomers and bonding isomers, the compounds can have different reactivity; for example, ethanol comprises a hydroxyl group, whereas the constitutionally isomeric dimethyl ether has an ether group. Skeletal isomers and positional isomers differ in the branching and/or the position of functional groups, such that these constitutional isomers can have essentially the same functionality. The expression “essentially the same functionality” accordingly means that the underlying functional group, i.e., for example, a hydroxyl group, a phenyl ring or an ester group, is present in all constitutional isomers, but does not take account of altered reactivity of these groups as a result of different substitution. For example, there is a measurable difference in the reactivity of 1-n-butanol and tert-butanol owing to the stereochemistry, but the functionality as such is identical. In this connection, however, these measurable differences that are covered by the term “essentially the same functionality” are to be neglected, since both compounds in the present case have a hydroxyl functionality. On the other hand, propyne has one alkyne functionality and propadiene has two alkene functionalities. Alkenes, by comparison with alkynes, have a different functionality in the context of this invention, since they exhibit different acidity, for example. Therefore, propyne, by comparison with propadiene, does not have “essentially the same functionality”.

Preferred mixtures comprise at least two organic-functional compounds OSM1 and OSM2 having essentially the same functionality. Accordingly, preferred organic-functional compounds OSM1 and OSM2 are constitutional isomers but not functional isomers, and instead are skeletal isomers and/or positional isomers. In a further configuration of the present invention, the mixture may preferably comprise at least three, more preferably at least four, functional compounds OSM1, OSM2, OSM3 and/or OSM4, where the preferred embodiments set out above and hereinafter that are detailed for mixtures comprising at least two organic-functional compounds OSM1 and OSM2 are also correspondingly applicable to mixtures comprising more than two organic-functional compounds.

The two organic-functional compounds OSM1 and OSM2 present in the present mixtures that are usable for production of functional layers of electronic devices may preferably be selected from the group consisting of fluorescent emitters, phosphorescent emitters, emitters that exhibit TADF (thermally activated delayed fluorescence), host materials, electron transport materials, exciton blocker materials, electron injection materials, hole conductor materials, hole injection materials, n-dopants, p-dopants, wide band gap materials, electron blocker materials and/or hole blocker materials.

The at least two organic-functional compounds OSM1 and OSM2 of the mixtures of the invention may preferably have the same number of aromatic or heteroaromatic ring systems each having 5 to 40 ring atoms, where the degree of condensation of the ring systems is the same and the ring systems have essentially the same substituents.

It may preferably be the case that the at least two organic-functional compounds OSM1 and OSM2 each have at least two aromatic or heteroaromatic ring systems each having 5 to 40 ring atoms, where the at least two organic-functional compounds OSM1 and OSM2 differ in that the at least two aromatic or heteroaromatic ring systems are joined to one another at different sites.

In a further configuration, a mixture of the invention may comprise at least two organic-functional compounds OSM1 and OSM2 each selected from the group of the phenyls, fluorenes, indenofluorenes, spirobifluorenes, carbazoles, indenocarbazoles, indolocarbazoles, spirocarbazoles, pyrimidines, triazines, lactams, triarylamines, dibenzofurans, dibenzothienes, imidazoles, benzimidazoles, benzoxazoles, benzothiazoles, 5-arylphenanthridin-6-ones, 9,10-dehydrophenanthrenes, fluoranthenes, anthracenes, benzanthracenes, fluoradenes.

Preferably, the organic-functional compound OSM1 may comprise at least one functional structural element and at least one substituent S1 and the organic-functional compound OSM2 may comprise at least one functional structural element and at least one substituent S2, where the functional structural element of the organic-functional compound OSM1 and of the organic-functional compound OSM2 are the same.

It may further be the case that the substituent S1 binds to the functional structural element in the organic-functional compound OSM1 at a different site from the substituent S2 in the organic-functional compound OSM2.

In a further embodiment, it may be the case that the substituent S1 of the organic-functional compound OSM1 and the substituent S2 of the organic-functional compound OSM2 are constitutional isomers of one another.

The substituents S1 and S2 may be chosen as desired, but are preferably selected from solubilizing groups, crosslinkable groups and/or functional groups, for example hole transport groups, electron transport groups, host material groups or wide band gap groups. These groups will be described in more detail later on, and so reference is made thereto.

In a preferred configuration, the mixtures of the invention may comprise at least one organic-functional compound OSM1 and at least one organic-functional compound OSM2, each of which conforms to the general formula (I):

(A)_{q}(B)ᵣ Formula (I)

where the symbols used are as follows:
A is a first functional structural element;
B is a second structural element and
q is an integer in the range from 1 to 20, preferably 1 to 10, particularly preferably 1 to 5 and especially preferably 1, 2 or 3, and
r is an integer in the range from 0 to 20, preferably 1 to 10, particularly preferably 1 to 5 and especially preferably 1, 2 or 3,

where the sum total of q and r is at least 2 and A or B, if q or r is 2 or greater, are each the same or different,

where the two constitutional isomers OSM1 and OSM2 differ in that at least one structural element binds to a further structural element at a different site.

The sum total of q and r is at least 2 and is preferably in the range from 2 to 20, preferably 2 to 10, particularly preferably 2 to 5, and is especially preferably 2, 3 or 4.

In a preferred configuration, the mixtures of the invention may contain at least one organic-functional compound OSM1 and at least one organic-functional compound OSM2, each of which contains at least one structure of the formula (II), preferably conforms to this formula:

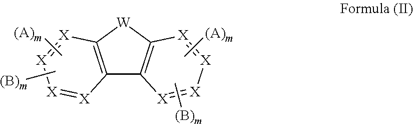

X is the same or different at each instance and is N or CR¹, preferably CR¹, or C if an A or B group is bonded to this atom, with the proviso that not more than two of the X groups in one cycle are N;
W is O, S, NR¹, NA, NB, C(R¹)₂, CR¹A, C(A)₂, CR¹B, C(B)₂, CAB, —R¹C═CR¹—, —R¹C═CA-, -AC═CA-, —R¹C═CB—, —BC═CB—, —BC═CA-, SO, SO₂, SiR¹₂ or C═O;
m at each instance is independently 0, 1, 2, 3 or 4, preferably 0, 1 or 2, with the proviso that the sum total of the indices m per ring is not more than 4, preferably not more than 2;
A is a first functional structural element, preferably an aromatic or heteroaromatic ring system which has 5 to 40 ring atoms in each case and may be substituted by one or more R¹ substituents;
B is a second structural element, preferably an aromatic or heteroaromatic ring system which has 5 to 40 ring atoms in each case and may be substituted by one or more R¹ substituents;
R¹ is the same or different at each instance and is H, D, F, Cl, Br, I, CN, NO₂, N(Ar¹)₂, N(R²)₂, C(═O)Ar¹, C(═O)R², P(═O)(Ar)₂, P(Ar¹)₂, B(Ar¹)₂, B(OR²)₂, Si(Ar¹)₃, Si(R²)₃, a straight-chain alkyl, alkoxy or thioalkoxy group having 1 to 40 carbon atoms or a branched or cyclic alkyl, alkoxy or thioalkoxy group having 3 to 40 carbon atoms or an alkenyl group having 2 to 40 carbon atoms, each of which may be substituted by one or more R² radicals, where one or more nonadjacent CH₂ groups may be replaced by —R²C═CR²—, —C≡C—, Si(R²)₂, Ge(R²)₂, Sn(R²)₂, C═O, C═S, C═Se, C═NR², —C(═O)O—, —C(═O)NR²—, NR², P(═O)(R²), —O—, —S—, SO or SO₂ and where one or more hydrogen atoms may be replaced by D, F, Cl, Br, I, CN or NO₂, or an aromatic or heteroaromatic ring system which has 5 to 40 aromatic ring atoms and may be substituted in each case by one or more R² radicals, or an aryloxy or heteroaryloxy group which has 5 to 40 aromatic ring atoms and may be substituted by one or more R² radicals, or an aralkyl or heteroaralkyl group which has 5 to 40 aromatic ring atoms and may be substituted by one or more R² radicals, or a combination of these systems; at the same time, two or more preferably adjacent R¹ radicals together may form a mono- or polycyclic, aliphatic, heteroaliphatic, aromatic or heteroaromatic ring system;
Ar¹ is the same or different at each instance and is an aromatic or heteroaromatic ring system which has 5 to 30 aromatic ring atoms and may be substituted by one or more nonaromatic R² radicals; at the same time, it is possible for two Ar¹ radicals bonded to the same silicon atom, nitrogen atom, phosphorus atom or boron atom also to be joined together via a bridge by a single bond or a bridge selected from B(R²), C(R²)₂, Si(R²)₂, C═O, C═NR², C═C(R²)₂, O, S, S═O, SO₂, N(R²), P(R²) and P(═O)R²;
R² is the same or different at each instance and is H, D, F, Cl, Br, I, CN, B(OR³)₂, NO₂, C(═O)R³, CR³═C(R³)₂, C(═O)OR³, C(═O)N(R³)₂, Si(R³)₃, P(R³)₂, B(R³)₂, N(R³)₂, NO₂, P(═O)(R³)₂, OSO₂R³, OR³, S(═O)R³, S(═O)₂R³, a straight-chain alkyl, alkoxy or thioalkoxy group having 1 to 40 carbon atoms or a branched or cyclic alkyl, alkoxy or thioalkoxy group having 3 to 40 carbon atoms, each of which may be substituted by one or more R³ radicals, where one or more nonadjacent CH₂ groups may be replaced by —R³C═CR³—, —C≡C—, Si(R³)₂, Ge(R³)₂, Sn(R³)₂, C═O, C═S, C═NR³, —C(═O)O—, —C(═O)NR³—, NR³, P(═O)(R³), —O—, —S—, SO or SO₂ and where one or more hydrogen atoms may be replaced by D, F, Cl, Br, I, CN or NO₂, or an aromatic or heteroaromatic ring system which has 5 to 40 aromatic ring atoms and may be substituted in each case by one or more R³ radicals, or an aryloxy or heteroaryloxy group which has 5 to 40 aromatic ring atoms and may be substituted by one or more R³ radicals, or a combination of these systems; at the same time, two or more preferably adjacent R² substituents together may also form a mono- or polycyclic, aliphatic, heteroaliphatic, aromatic or heteroaromatic ring system;
R³ is the same or different at each instance and is selected from the group consisting of H, D, F, CN, an aliphatic hydrocarbyl radical having 1 to 20 carbon atoms, or an aromatic or heteroaromatic ring system having 5 to 30 aromatic ring atoms in which one or more hydrogen atoms may be replaced by D, F, Cl, Br, I or CN and which may be substituted by one or more alkyl groups each having 1 to 4 carbon atoms; at the same time, two or more preferably adjacent R³ substituents together may also form a mono- or polycyclic, aliphatic, heteroaliphatic, aromatic or heteroaromatic ring system;

with the proviso that the structure of the formula (II) comprises at least one A and/or B group. Preferably, the structure of the formula (II) comprises at least one A group,

The sum total of the A and/or B groups is preferably 2 to 10, particularly preferably 2 to 5, and is especially preferably 2, 3 or 4.

Adjacent carbon atoms in the context of the present invention are carbon atoms bonded directly to one another. In addition, “adjacent radicals” in the definition of the radicals means that these radicals are bonded to the same carbon atom or to adjacent carbon atoms. These definitions apply correspondingly, inter alia, to the terms “adjacent groups” and “adjacent substituents”.

The wording that two or more radicals together may form a ring, in the context of the present description, shall be understood to mean, inter alia, that the two radicals are joined to one another by a chemical bond with formal elimination of two hydrogen atoms. This is illustrated by the following scheme:

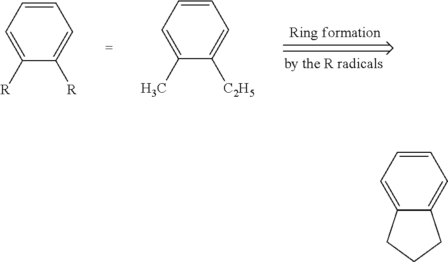

In addition, however, the abovementioned wording shall also be understood to mean that, if one of the two radicals is hydrogen, the second radical binds to the position to which the hydrogen atom was bonded, forming a ring. This shall be illustrated by the following scheme:

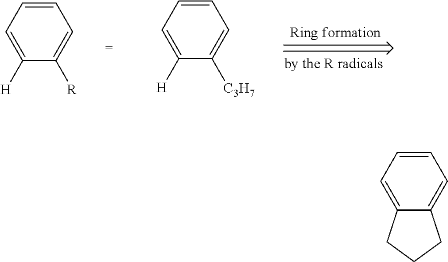

A fused aryl group, a fused aromatic ring system or a fused heteroaromatic ring system in the context of the present invention is a group in which two or more aromatic groups are fused, i.e. annelated, to one another along a common edge, such that, for example, two carbon atoms belong to the at least two aromatic or heteroaromatic rings, as, for example, in naphthalene. By contrast, for example, fluorene is not a fused aryl group in the context of the present invention, since the two aromatic groups in fluorene do not have a common edge. Corresponding definitions apply to heteroaryl groups and to fused ring systems which may but need not also contain heteroatoms.

An aryl group in the context of this invention contains 6 to 60 carbon atoms, preferably 6 to 40 carbon atoms; a heteroaryl group in the context of this invention contains 2 to 60 carbon atoms, preferably 2 to 40 carbon atoms, and at least one heteroatom, with the proviso that the sum total of carbon atoms and heteroatoms is at least 5. The heteroatoms are preferably selected from N, O and/or S. An aryl group or heteroaryl group is understood here to mean either a simple aromatic cycle, i.e. benzene, or a simple heteroaromatic cycle, for example pyridine, pyrimidine, thiophene, etc., or a fused aryl or heteroaryl group, for example naphthalene, anthracene, phenanthrene, quinoline, isoquinoline, etc.

An aromatic ring system in the context of this invention contains 6 to 60 carbon atoms, preferably 6 to 40 carbon atoms, in the ring system. A heteroaromatic ring system in the context of this invention contains 1 to 60 carbon atoms, preferably 1 to 40 carbon atoms, and at least one heteroatom in the ring system, with the proviso that the sum total of carbon atoms and heteroatoms is at least 5. The heteroatoms are preferably selected from N, O and/or S. An aromatic or heteroaromatic ring system in the context of this invention shall be understood to mean a system which does not necessarily contain only aryl or heteroaryl groups, but in which it is also possible for a plurality of aryl or heteroaryl groups to be interrupted by a nonaromatic unit (preferably less than 10% of the atoms other than H), for example a carbon, nitrogen or oxygen atom or a carbonyl group. For example, systems such as 9,9′-spirobifluorene, 9,9-diarylfluorene, triarylamine, diaryl ethers, stilbene, etc. shall thus also be regarded as aromatic ring systems in the context of this invention, and likewise systems in which two or more aryl groups are interrupted, for example, by a linear or cyclic alkyl group or by a silyl group. In addition, systems in which two or more aryl or heteroaryl groups are bonded directly to one another, for example biphenyl, terphenyl, quaterphenyl or bipyridine, shall likewise be regarded as an aromatic or heteroaromatic ring system.

A cyclic alkyl, alkoxy or thioalkoxy group in the context of this invention is understood to mean a monocyclic, bicyclic or polycyclic group.

In the context of the present invention, a C₁- to C₂₀-alkyl group in which individual hydrogen atoms or CH₂ groups may also be replaced by the abovementioned groups are understood to mean, for example, the methyl, ethyl, n-propyl, i-propyl, cyclopropyl, n-butyl, i-butyl, s-butyl, t-butyl, cyclobutyl, 2-methylbutyl, n-pentyl, s-pentyl, t-pentyl, 2-pentyl, neopentyl, cyclopentyl, n-hexyl, s-hexyl, t-hexyl, 2-hexyl, 3-hexyl, neohexyl, cyclohexyl, 1-methylcyclopentyl, 2-methylpentyl, n-heptyl, 2-heptyl, 3-heptyl, 4-heptyl, cycloheptyl, 1-methylcyclohexyl, n-octyl, 2-ethylhexyl, cyclooctyl, 1-bicyclo[2.2.2]octyl, 2-bicyclo[2.2.2]octyl, 2-(2,6-dimethyl)octyl, 3-(3,7-dimethyl)octyl, adamantyl, trifluoromethyl, pentafluoroethyl, 2,2,2-trifluoroethyl, 1,1-dimethyl-n-hex-1-yl, 1,1-dimethyl-n-hept-1-yl, 1,1-dimethyl-n-oct-1-yl, 1,1-dimethyl-n-dec-1-yl, 1,1-dimethyl-n-dodec-1-yl, 1,1-dimethyl-n-tetradec-1-yl, 1,1-dimethyl-n-hexadec-1-yl, 1,1-dimethyl-n-octadec-1-yl, 1,1-diethyl-n-hex-1-yl, 1,1-diethyl-n-hept-1-yl, 1,1-diethyl-n-oct-1-yl, 1,1-diethyl-n-dec-1-yl, 1,1-diethyl-n-dodec-1-yl, 1,1-diethyl-n-tetradec-1-yl, 1,1-diethyl-n-hexadec-1-yl, 1,1-diethyl-n-octadec-1-yl, 1-(n-propyl)cyclohex-1-yl, 1-(n-butyl)cyclohex-1-yl, 1-(n-hexyl)cyclohex-1-yl, 1-(n-octyl)cyclohex-1-yl and 1-(n-decyl)cyclohex-1-yl radicals. An alkenyl group is understood to mean, for example, ethenyl, propenyl, butenyl, pentenyl, cyclopentenyl, hexenyl, cyclohexenyl, heptenyl, cycloheptenyl, octenyl, cyclooctenyl or cyclooctadienyl. An alkynyl group is understood to mean, for example, ethynyl, propynyl, butynyl, pentynyl, hexynyl, heptynyl or octynyl. A C₁- to C₄₀-alkoxy group is understood to mean, for example, methoxy, trifluoromethoxy, ethoxy, n-propoxy, i-propoxy, n-butoxy, i-butoxy, s-butoxy, t-butoxy or 2-methylbutoxy.

An aromatic or heteroaromatic ring system which has 5-60 aromatic ring atoms, preferably 5-40 aromatic ring atoms, and may also be substituted in each case by the abovementioned radicals and which may be joined to the aromatic or heteroaromatic system via any desired positions is understood to mean, for example, groups derived from benzene, naphthalene, anthracene, benzanthracene, phenanthrene, benzophenanthrene, pyrene, chrysene, perylene, fluoranthene, benzofluoranthene, naphthacene, pentacene, benzopyrene, biphenyl, biphenylene, terphenyl, terphenylene, fluorene, spirobifluorene, dihydrophenanthrene, dihydropyrene, tetrahydropyrene, cis- or trans-indenofluorene, cis- or trans-monobenzoindenofluorene, cis- or trans-dibenzoindenofluorene, truxene, isotruxene, spirotruxene, spiroisotruxene, furan, benzofuran, isobenzofuran, dibenzofuran, thiophene, benzothiophene, isobenzothiophene, dibenzothiophene, pyrrole, indole, isoindole, carbazole, indolocarbazole, indenocarbazole, pyridine, quinoline, isoquinoline, acridine, phenanthridine, benzo-5,6-quinoline, benzo-6,7-quinoline, benzo-7,8-quinoline, phenothiazine, phenoxazine, pyrazole, indazole, imidazole, benzimidazole, naphthimidazole, phenanthrimidazole, pyridimidazole, pyrazinimidazole, quinoxalinimidazole, oxazole, benzoxazole, naphthoxazole, anthroxazole, phenanthroxazole, isoxazole, 1,2-thiazole, 1,3-thiazole, benzothiazole, pyridazine, benzopyridazine, pyrimidine, benzopyrimidine, quinoxaline, 1,5-diazaanthracene, 2,7-diazapyrene, 2,3-diazapyrene, 1,6-diazapyrene, 1,8-diazapyrene, 4,5-diazapyrene, 4,5,9,10-tetraazaperylene, pyrazine, phenazine, phenoxazine, phenothiazine, fluorubine, naphthyridine, azacarbazole, benzocarboline, phenanthroline, 1,2,3-triazole, 1,2,4-triazole, benzotriazole, 1,2,3-oxadiazole, 1,2,4-oxadiazole, 1,2,5-oxadiazole, 1,3,4-oxadiazole, 1,2,3-thiadiazole, 1,2,4-thiadiazole, 1,2,5-thiadiazole, 1,3,4-thiadiazole, 1,3,5-triazine, 1,2,4-triazine, 1,2,3-triazine, tetrazole, 1,2,4,5-tetrazine, 1,2,3,4-tetrazine, 1,2,3,5-tetrazine, purine, pteridine, indolizine and benzothiadiazole.

In a preferred configuration, compounds OSM1 and OSM2 usable in accordance with the invention can be represented by structures of the formula (I) and/or (II). Preferably, compounds OSM1 and OSM2 usable in accordance with the invention, comprising structures of formula (I) and/or (II), have a molecular weight of not more than 5000 g/mol, preferably not more than 4000 g/mol, particularly preferably not more than 3000 g/mol, especially preferably not more than 2000 g/mol and most preferably not more than 1200 g/mol.

It may further be the case that the substituent S1 and the substituent S2, or at least one of the structural elements A and/or B in the compounds OSM1 and OSM2 of the invention, in each case is selected from the group consisting of phenyl, ortho-, meta- or para-biphenyl, terphenyl, especially branched terphenyl, quaterphenyl, especially branched quaterphenyl, 1-, 2-, 3- or 4-fluorenyl, 9,9′-diarylfluorenyl 1-, 2-, 3- or 4-spirobifluorenyl, pyridyl, pyrimidinyl, 1-, 2-, 3- or 4-dibenzofuranyl, 1-, 2-, 3- or 4-dibenzothienyl, pyrenyl, triazinyl, imidazolyl, benzimidazolyl, benzoxazolyl, benzothiazolyl, 1-, 2-, 3- or 4-carbazolyl, 1- or 2-naphthyl, anthracenyl, preferably 9-anthracenyl, trans- and cis-indenofluorenyl, indenocarbazolyl, indolocarbazolyl, spirocarbazolyl, 5-aryl-phenanthridin-6-on-yl, 9,10-dehydrophenanthrenyl, fluoranthenyl, tolyl, mesityl, phenoxytolyl, anisolyl, triarylaminyl, bis(triarylaminyl), tris(triarylaminyl), hexamethylindanyl, tetralinyl, monocycloalkyl, biscycloalkyl, tricycloalkyl, alkyl, for example tert-butyl, methyl, propyl, alkoxyl, alkylsulfanyl, alkylaryl, triarylsilyl, trialkylsilyl, xanthenyl, 10-arylphenoxazinyl, phenanthrenyl and/or triphenylenyl, each of which may be substituted by one or more radicals, but are preferably unsubstituted, particular preference being given to phenyl, spirobifluorene, fluorene, dibenzofuran, dibenzothiophene, anthracene, phenanthrene, triphenylene groups. In this context, the above-detailed groups may be substituted by R¹ groups as described above.

It may further be the case that the compounds OSM1 and OSM2 usable in accordance with the invention each have a functional structural element, preferably a first functional structural element A having at least one aromatic or heteroaromatic ring system which has 5 to 40 ring atoms and may be substituted by one or more substituents, preferably one or more S1, S2 or R¹ substituents.

Preferably, the compounds OSM1 and OSM2 usable in accordance with the invention may each contain a functional structural element, preferably a first functional structural element A selected from the group of the fluorenes, indenofluorenes, spirobifluorenes, carbazoles, indenocarbazoles, indolocarbazoles, spirocarbazoles, pyrimidines, triazines, lactams, triarylamines, dibenzofurans, dibenzothienes, imidazoles, benzimidazoles, benzoxazoles, benzothiazoles, 5-arylphenanthridin-6-ones, 9,10-dehydrophenanthrenes, fluoranthenes, where the functional structural element may be substituted by one or more substituents, preferably one or more S1, S2 or R¹ substituents. Preferably, the organic-functional compounds OSM1 and OSM2 may each comprise at least two functional groups, where the organic-functional compounds OSM1 and OSM2 differ in that the two functional groups in each case are joined to one another at different sites. Preferably, the second structural element may have at least one aromatic or heteroaromatic ring system, each of which has 5 to 40 ring atoms and may be substituted by one or more substituents, preferred substituents being selected from the R¹ groups described above and later on. Preferably, the substituents S1 and S2 may be selected from the R¹ groups described above and later on.

It may preferably be the case that the functional structural element of the compounds OSM1 and OSM2 usable in accordance with the invention, preferably the first functional structural element A, is selected from hole transport groups, electron transport groups, host material groups and wide band gap groups.

In a further embodiment, the compounds OSM1 and OSM2 usable in accordance with the invention comprise at least one hole transport group, these groups being known in the art and in many cases being selected from arylamino groups, preferably di- or triarylamino groups, heteroarylamino groups, preferably di- or triheteroarylamino groups, carbazole groups, preference being given to carbazole groups.

It may preferably be the case that a hole transport group, a structural element A or a substituent S1 or S2 comprises a group and preferably is a group selected from the formulae (H-1) to (H-3)

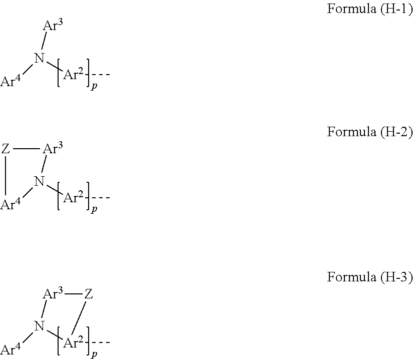

where the dotted bond marks the attachment position and

Ar², Ar³, Ar⁴ are each independently an aryl group having 6 to 40 carbon atoms or a heteroaryl group having 3 to 40 carbon atoms, each of which may be substituted by one or more R¹ radicals;

p is O or 1 and

Z is CR¹₂, SiR¹₂, C═O, N—Ar¹, BR¹, PR¹, POR¹, SO, SO₂, Se, O or S, preferably CR¹₂, N—Ar¹, O or S, where the R¹ radical has the definition given above and Ar¹ is an aromatic or heteroaromatic ring system which has 5 to 60 aromatic, preferably 5 to 40 aromatic, ring atoms and may be substituted by one or more R¹ radicals, an aryloxy group which has 5 to 60 aromatic, preferably 5 to 40 aromatic, ring atoms and may be substituted in each case by one or more R¹ radicals, or an aralkyl group which has 5 to 60 aromatic, preferably 5 to 40 aromatic, ring atoms and may be substituted in each case by one or more R¹ radicals, where it is optionally possible for two or more, preferably adjacent R¹ substituents to form a mono- or polycyclic, aliphatic, heteroaliphatic, aromatic or heteroaromatic ring system which may be substituted by one or more R² radicals.

It may further be the case that a hole transport group, a structural element A or a substituent S1, S2 comprises a group and preferably is a group selected from the formulae (H-4) to (H-26)

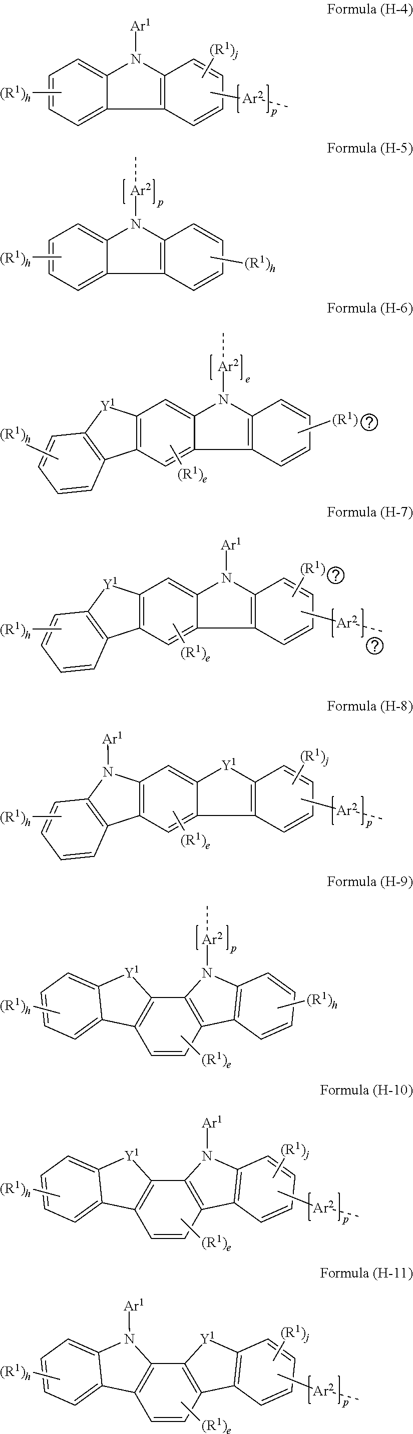

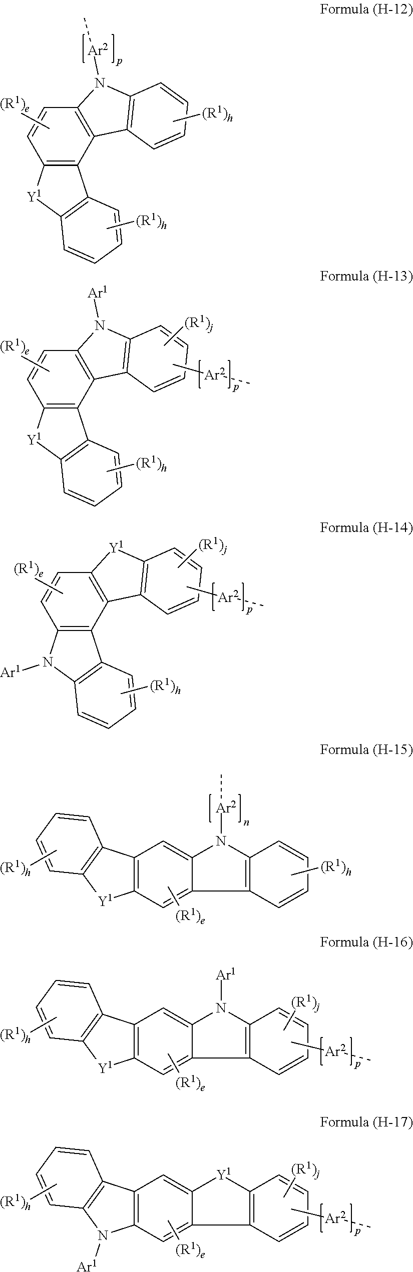

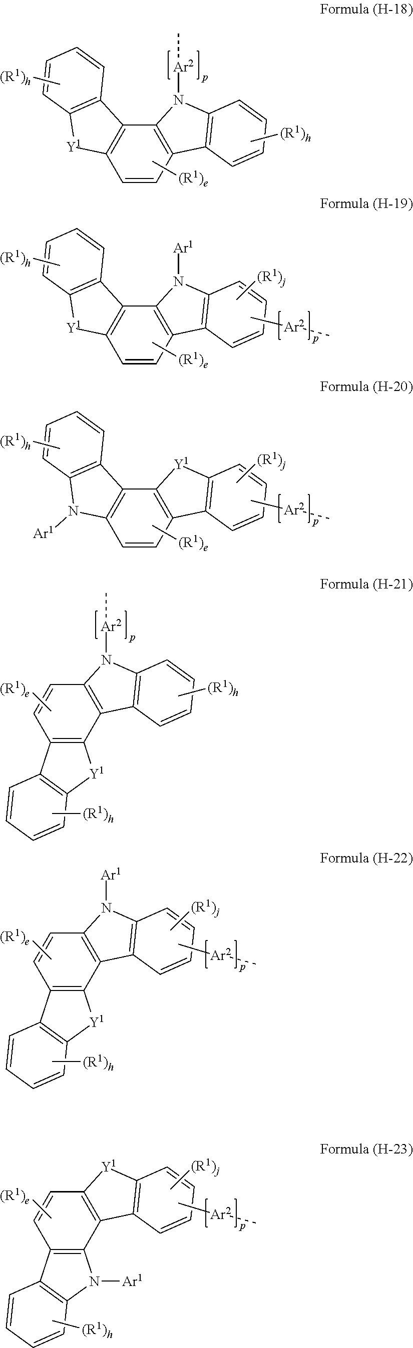

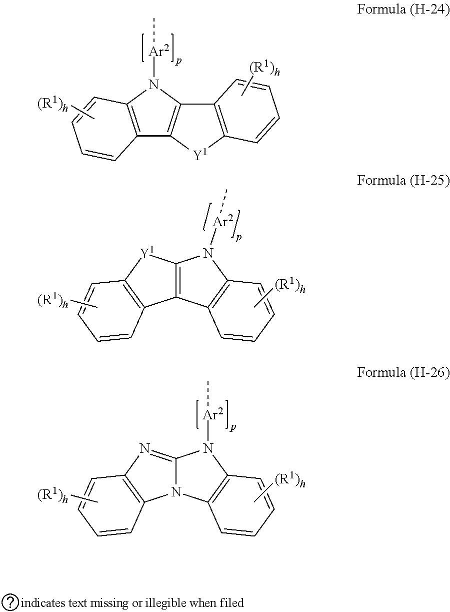

where Y¹ is O, S, C(R¹)₂ or NAr¹, the dotted bond marks the attachment position, e is 0, 1 or 2, j is 0, 1, 2 or 3, h is 0, 1, 2, 3 or 4, p is 0, 1, 2, 3, 4, 5 or 6, preferably 0, 1, 2 or 3 and more preferably 0, 1 or 2, Ar¹ and Ar² have the definition given above, especially for formula (H-1) or (H-2), and R¹ has the definition given above, especially for formula (II).

Of the groups (H-1) to (H-26), preference is given to carbazole groups, especially the groups (H-4) to (H-26).

In a further preferred embodiment of the invention, Ar² is an aromatic or heteroaromatic ring system which has 5 to 14 aromatic or heteroaromatic ring atoms, preferably an aromatic ring system which has 6 to 12 carbon atoms, and which may be substituted by one or more R¹ radicals, but is preferably unsubstituted, where R¹ may have the definition given above, especially for formula (I). More preferably, Ar² is an aromatic ring system having 6 to 10 aromatic ring atoms or a heteroaromatic ring system having 6 to 13 heteroaromatic ring atoms, each of which may be substituted by one or more R¹ radicals, but is preferably unsubstituted, where R¹ may have the definition given above, especially for formula (II).

Further preferably, the symbol Ar² shown in formulae (H-1) to (H-26) inter alia is an aryl or heteroaryl radical having 5 to 24 ring atoms, preferably 6 to 13 ring atoms, more preferably 6 to 10 ring atoms, such that an aromatic or heteroaromatic group of an aromatic or heteroaromatic ring system is bonded to the respective atom of the further group directly, i.e. via an atom of the aromatic or heteroaromatic group.

It may further be the case, for compounds OSM1 or OSM2 that are used as hole transport materials or host materials, that the Ar² group shown in formulae (H-1) to (H-26) comprises an aromatic ring system having not more than two fused aromatic and/or heteroaromatic rings, preferably does not comprise any fused aromatic or heteroaromatic ring system. Accordingly, naphthyl structures are preferred over anthracene structures. In addition, fluorenyl, spirobifluorenyl, dibenzofuranyl and/or dibenzothienyl structures are preferred over naphthyl structures. Particular preference is given to structures having no fusion, for example phenyl, biphenyl, terphenyl and/or quaterphenyl structures.

Compounds OSM1 or OSM2 that find use as fluorescent emitters may also comprise more highly fused ring systems, such as phenanthrene, anthracene or pyrene groups.

Examples of suitable aromatic or heteroaromatic ring systems Ar² are selected from the group consisting of ortho-, meta- or para-phenylene, ortho-, meta- or para-biphenylene, terphenylene, especially branched terphenylene, quaterphenylene, especially branched quaterphenylene, fluorenylene, spirobifluorenylene, dibenzofuranylene, dibenzothienylene and carbazolylene, each of which may be substituted by one or more R¹ radicals, but are preferably unsubstituted.

It may further be the case that the Ar² group shown in formulae (H-1) to (H-26) inter alia has not more than 1 nitrogen atom, preferably not more than 2 heteroatoms, particularly preferably not more than one heteroatom and especially preferably no heteroatom.

In a further preferred embodiment of the invention, Ar³ and/or Ar⁴ are the same or different at each instance and are an aromatic or heteroaromatic ring system having 6 to 24 aromatic ring atoms, preferably 6 to 18 aromatic ring atoms, and are more preferably an aromatic ring system having 6 to 12 aromatic ring atoms or a heteroaromatic ring system having 6 to 13 aromatic ring atoms, each of which may be substituted by one or more R¹ radicals, but is preferably unsubstituted, where R¹ may have the definition given above, especially in formula (II). Examples of suitable Ar³ and/or Ar⁴ groups are selected from the group consisting of phenyl, ortho-, meta- or para-biphenyl, terphenyl, especially branched terphenyl, quaterphenyl, especially branched quaterphenyl, 1-, 2-, 3- or 4-fluorenyl, 1-, 2-, 3- or 4-spirobifluorenyl, pyridyl, pyrimidinyl, 1-, 2-, 3- or 4-dibenzofuranyl, 1-, 2-, 3- or 4-dibenzothienyl and 1-, 2-, 3- or 4-carbazolyl, each of which may be substituted by one or more R³ radicals, but are preferably unsubstituted.

Preferably, the R¹ radicals do not form a fused ring system with the ring atoms of the aryl group or heteroaryl group Ar¹, Ar², Ar³ and/or Ar⁴ to which the R¹ radicals in the formulae (H-1) to (H-26) may be bonded. This includes the formation of a fused ring system with possible R², R³ substituents which may be bonded to the R¹ radicals.

In a preferred embodiment, the compounds OSM1 and OSM2 usable in accordance with the invention, preferably the first functional structural element A, may in each case comprise an electron transport group, where the functional structural element or the substituents S1 and S2 may preferably constitute an electron transport group. Electron transport groups are widely known in the technical field and promote the ability of compounds to transport and/or conduct electrons.

Furthermore, surprising advantages are exhibited by compounds OSM1 and OSM2 usable in accordance with the invention, preferably comprising at least one structure of formula (I) and/or (II) or preferred embodiments thereof, in which the A and/or B group in formulae (I) and/or (II) or the preferred embodiments thereof or the substituents S1 and S2 comprise at least one structure selected from the group of the pyridines, pyrimidines, pyrazines, pyridazines, triazines, quinazolines, quinoxalines, quinolines, isoquinolines, imidazoles and/or benzimidazoles, particular preference being given to pyrimidines, triazines and quinazolines.

In a preferred configuration of the present invention, it may be the case that an electron-transporting group, a structural element A and/or B, a substituent S1, S2 or one of the R¹ radicals comprises a group, preferably is a group, that can be represented by the formula (QL)

Q-L¹ - - - Formula (QL)

in which L¹ represents a bond or an aromatic or heteroaromatic ring system which has 5 to 60 aromatic, preferably 5 to 40 aromatic, ring atoms and may be substituted by one or more R¹ radicals, and Q is an electron transport group, where R¹ has the definition given above, especially for formula (II).

It may further be the case that an electron transport group, the Q group shown in the formula (QL) inter alia and/or the substituent S1 or S2 is selected from structures of the formulae (Q-1), (Q-2), (Q-3), (Q-4), (Q-5), (Q-6), (Q-7), (Q-8), (Q-9) and/or (Q-10)

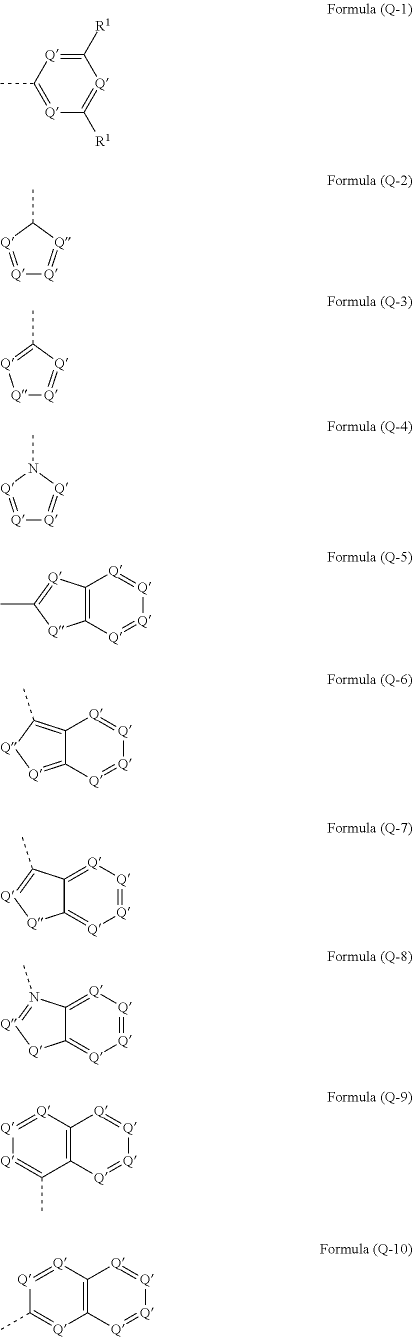

where the dotted bond marks the attachment position,
Q′ is the same or different at each instance and is CR¹ or N, and
Q″ is NR¹, O or S;
where at least one Q′ is N and

R¹ is as defined above for formula (II).

Preferably, an electron transport group, the Q group shown in the formula (QL) inter alia and/or the substituent S1 or S2 may be selected from structures of the formulae (Q-11), (Q-12), (Q-13), (Q-14) and/or (Q15)

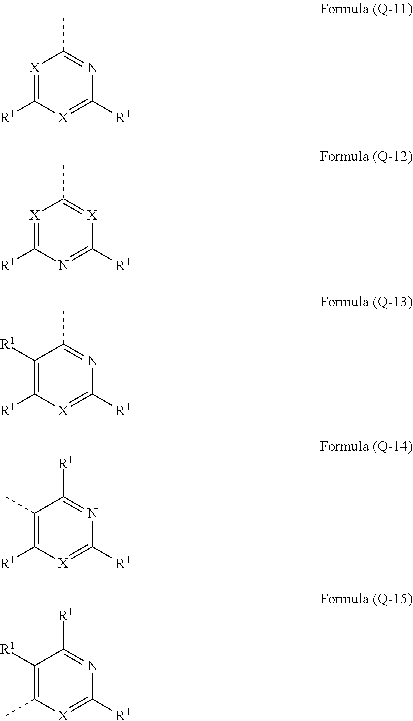

where the symbol R¹ has the definition given for formula (II) inter alia, X is N or CR¹ and the dotted bond marks the attachment position, where X is preferably a nitrogen atom.

In a further embodiment, an electron transport group, the Q group shown in the formula (QL) inter alia and/or the substituent S1 or S2 may be selected from structures of the formulae (Q-16), (Q-17), (Q-18), (Q-19), (Q-20), (Q-21) and/or (Q22)

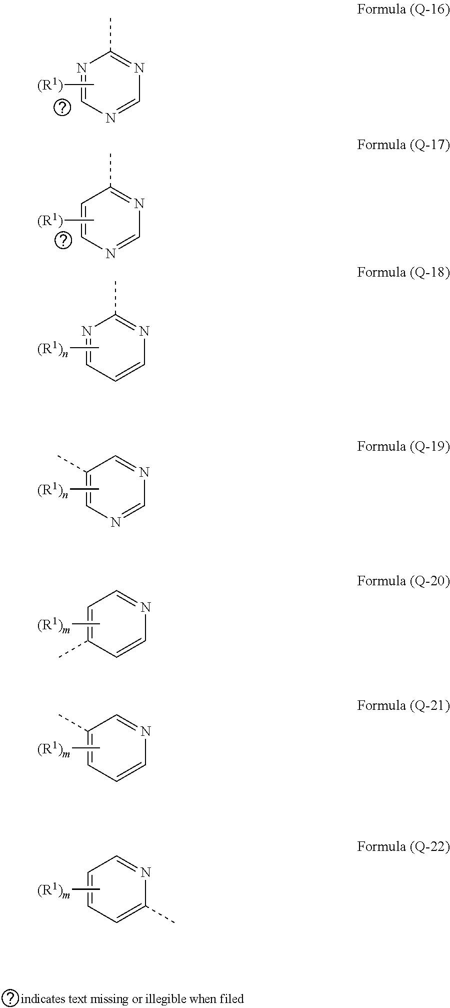

in which the symbol R¹ has the definition detailed above for formula (II) inter alia, the dotted bond marks the attachment position and m is 0, 1, 2, 3 or 4, preferably 0, 1 or 2, n is 0, 1, 2 or 3, preferably 0, 1 or 2, and o is 0, 1 or 2, preferably 1 or 2. Preference is given here to the structures of the formulae (Q-16), Q-17), (Q-18) and (Q-19).

In a further embodiment, an electron transport group, the Q group shown in the formula (QL) inter alia and/or the substituent S1 or S2 may be selected from structures of the formulae (Q-23), (Q-24) and/or (Q-25)

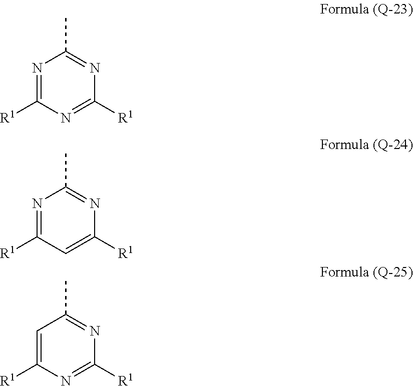

in which the symbol R¹ has the definition set out above for formula (II) inter alia, and the dotted bond marks the attachment position.

In a further embodiment, an electron transport group, the Q group shown in the formula (QL) inter alia and/or the substituent S1 or S2 may be selected from structures of the formulae (Q-26), (Q-27), (Q-28), (Q-29) and/or (Q-30)

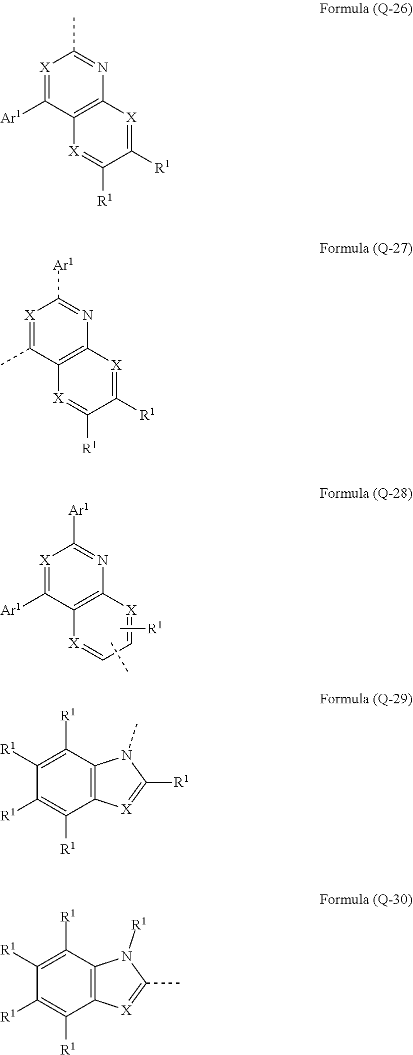

where X is N or CR¹, the symbol R¹ has the definition given above for formula (II) inter alia, the dotted bond marks the attachment position, where X is preferably a nitrogen atom and Ar¹ is an aromatic or heteroaromatic ring system which has 5 to 60 aromatic, preferably 5 to 40 aromatic, ring atoms and may be substituted in each case by one or more R¹ radicals, an aryloxy group which has 5 to 60 aromatic, preferably 5 to 40 aromatic, ring atoms and may be substituted by one or more R¹ radicals, or an aralkyl group which has 5 to 60 aromatic, preferably 5 to 40 aromatic, ring atoms and may be substituted in each case by one or more R¹ radicals, where it is optionally possible for two or more, preferably adjacent R¹ substituents to form a mono- or polycyclic, aliphatic, heteroaliphatic, aromatic or heteroaromatic ring system, preferably a mono- or polycyclic aliphatic ring system, which may be substituted by one or more R² radicals.

Preferably, an electron transport group, the Q group shown in the formula (QL) inter alia and/or the substituent S1 or S2 may be selected from structures of the formulae (Q-31), (Q-32), (Q-33), (Q-34), (Q-35), (Q-36), (Q-37), (Q-38), (Q-39), (Q-40), (Q-41), (Q-42), (Q-43) and/or (Q-44)

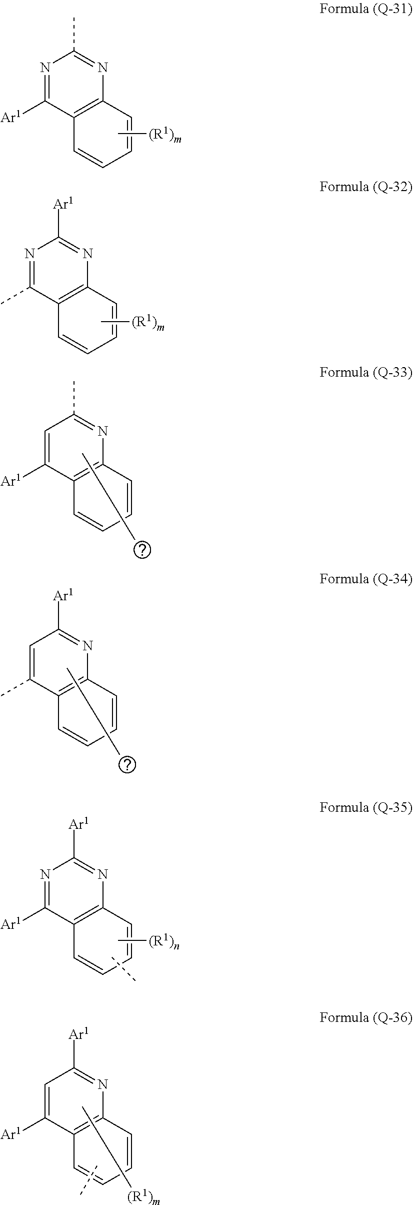

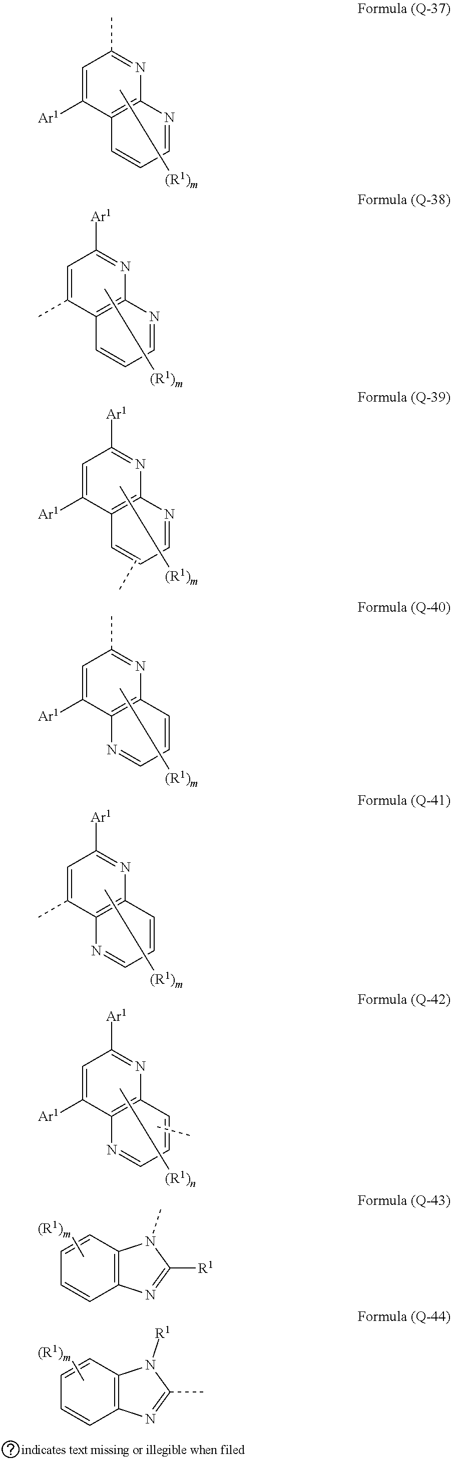

in which the symbols Ar¹ have the definition set out above for formula (Q-26), (Q-27) or (Q-28) inter alia and R¹ has the definition set out above for formula (II) inter alia, the dotted bond marks the attachment position and m is 0, 1, 2, 3 or 4, preferably 0, 1 or 2, n is 0, 1, 2 or 3, preferably 0, 1 or 2, and I is 1, 2, 3, 4 or 5, preferably 0, 1 or 2.

Preferably, the symbol Ar¹ is an aryl or heteroaryl radical, such that an aromatic or heteroaromatic group of an aromatic or heteroaromatic ring system is bonded directly, i.e. via an atom of the aromatic or heteroaromatic group, to the respective atom of the further group, for example a carbon or nitrogen atom of the (H-1) to (H-26) or (Q-26) to (Q-44) groups shown above.

In a further preferred embodiment of the invention, Ar¹ is the same or different at each instance and is an aromatic or heteroaromatic ring system having 6 to 24 aromatic ring atoms, preferably 6 to 18 aromatic ring atoms, and is more preferably an aromatic ring system having 6 to 12 aromatic ring atoms or a heteroaromatic ring system having 6 to 13 aromatic ring atoms, each of which may be substituted by one or more R¹ radicals, but is preferably unsubstituted, where R¹ may have the definition given above, especially in formula (II). Examples of suitable Ar¹ groups are selected from the group consisting of phenyl, ortho-, meta- or para-biphenyl, terphenyl, especially branched terphenyl, quaterphenyl, especially branched quaterphenyl, 1-, 2-, 3- or 4-fluorenyl, 1-, 2-, 3- or 4-spirobifluorenyl, pyridyl, pyrimidinyl, 1-, 2-, 3- or 4-dibenzofuranyl, 1-, 2-, 3- or 4-dibenzothienyl and 1-, 2-, 3- or 4-carbazolyl, each of which may be substituted by one or more R³ radicals, but are preferably unsubstituted.

Advantageously, Ar¹ in the formulae (H-1) to (H-26) or (Q-16) to (Q-34) is an aromatic ring system which has 6 to 12 aromatic ring atoms and may be substituted by one or more R¹ radicals, but is preferably unsubstituted, where R¹ may have the definition detailed above, especially for formula (I).

It may further be the case that the Ar¹, Ar², Ar³ and/or Ar⁴ group is selected from the group consisting of phenyl, ortho-, meta- or para-biphenyl, terphenyl, especially branched terphenyl, quaterphenyl, especially branched quaterphenyl, 1-, 2-, 3- or 4-fluorenyl, 1-, 2-, 3- or 4-spirobifluorenyl, pyridyl, pyrimidinyl, 1-, 2-, 3- or 4-dibenzofuranyl, 1-, 2-, 3- or 4-dibenzothienyl, pyrenyl, triazinyl, imidazolyl, benzimidazolyl, benzoxazolyl, benzothiazolyl, 1-, 2-, 3- or 4-carbazolyl, 1- or 2-naphthyl, anthracenyl, preferably 9-anthracenyl, phenanthrenyl and/or triphenylenyl, each of which may be substituted by one or more R¹ radicals, but are preferably unsubstituted, particular preference being given to phenyl, spirobifluorene, fluorene, dibenzofuran, dibenzothiophene, anthracene, phenanthrene, triphenylene groups, where the R¹ radical has the definition given above, especially for formula (II).

Preferably, the R¹ radicals in the formulae (H-1) to (H-26) or (Q-1) to (Q-44) do not form a fused ring system with the ring atoms of the heteroaryl group or the Ar¹ and/or Ar² group to which the R¹ radicals are bonded. This includes the formation of a fused ring system with possible R², R³ substituents which may be bonded to the R¹ radicals.

It may further be the case that the R¹ substituents do not form a fused aromatic or heteroaromatic ring system, preferably any fused ring system, with ring atoms of an aromatic or heteroaromatic ring system to which the R¹ substituents bind. This includes the formation of a fused ring system with possible R², R³ substituents which may be bonded to the R¹ radicals. It may preferably be the case that the R¹ substituents of an aromatic or heteroaromatic ring system do not form a ring system with the ring atoms of the aromatic or heteroaromatic ring system. This includes the formation of a ring system with possible R², R³ substituents which may be bonded to the R¹ radicals.

When X is CR¹ or when the aromatic and/or heteroaromatic groups are substituted by R¹ substituents, these R¹ substituents are preferably selected from the group consisting of H, D, F, CN, N(Ar¹)₂, C(═O)Ar¹, P(═O)(Ar)₂, a straight-chain alkyl or alkoxy group having 1 to 10 carbon atoms or a branched or cyclic alkyl or alkoxy group having 3 to 10 carbon atoms or an alkenyl group having 2 to 10 carbon atoms, each of which may be substituted by one or more R² radicals, where one or more non-adjacent CH₂ groups may be replaced by O and where one or more hydrogen atoms may be replaced by D or F, an aromatic or heteroaromatic ring system which has 5 to 24 aromatic ring atoms and may be substituted in each case by one or more R² radicals, but is preferably unsubstituted, or an aralkyl or heteroaralkyl group which has 5 to 25 aromatic ring atoms and may be substituted by one or more R² radicals; at the same time, it is optionally possible for two R¹ substituents bonded to the same carbon atom or to adjacent carbon atoms to form a monocyclic or polycyclic, aliphatic, aromatic or heteroaromatic ring system which may be substituted by one or more R¹ radicals, where Ar¹ is the same or different at each instance and is an aromatic or heteroaromatic ring system which has 5 to 40 aromatic ring atoms and may be substituted in each case by one or more R² radicals, an aryloxy group which has 5 to 40 aromatic ring atoms and may be substituted by one or more R² radicals, or an aralkyl group which has 5 to 40 aromatic ring atoms and may be substituted in each case by one or more R² radicals, where two or more preferably adjacent R² substituents may optionally form a mono- or polycyclic, aliphatic, heteroaliphatic, aromatic or heteroaromatic ring system, preferably a mono- or polycyclic aliphatic ring system, which may be substituted by one or more R³ radicals, where the symbol R² may have the definition given above, especially for formula (II). Preferably, Ar¹ is the same or different at each instance and is an aryl or heteroaryl group which has 5 to 24 and preferably 5 to 12 aromatic ring atoms, and which may be substituted in each case by one or more R² radicals, but is preferably unsubstituted.

Examples of suitable Ar¹ groups are selected from the group consisting of phenyl, ortho-, meta- or para-biphenyl, terphenyl, especially branched terphenyl, quaterphenyl, especially branched quaterphenyl, 1-, 2-, 3- or 4-fluorenyl, 1-, 2-, 3- or 4-spirobifluorenyl, pyridyl, pyrimidinyl, 1-, 2-, 3- or 4-dibenzofuranyl, 1-, 2-, 3- or 4-dibenzothienyl and 1-, 2-, 3- or 4-carbazolyl, each of which may be substituted by one or more R² radicals, but are preferably unsubstituted.

More preferably, these R¹ substituents are selected from the group consisting of H, D, F, CN, N(Ar¹)₂, a straight-chain alkyl group having 1 to 8 carbon atoms, preferably having 1, 2, 3 or 4 carbon atoms, or a branched or cyclic alkyl group having 3 to 8 carbon atoms, preferably having 3 or 4 carbon atoms, or an alkenyl group having 2 to 8 carbon atoms, preferably having 2, 3 or 4 carbon atoms, each of which may be substituted by one or more R² radicals, but is preferably unsubstituted, or an aromatic or heteroaromatic ring system which has 6 to 24 aromatic ring atoms, preferably 6 to 18 aromatic ring atoms, more preferably 6 to 13 aromatic ring atoms, and may be substituted in each case by one or more nonaromatic R¹ radicals, but is preferably unsubstituted; at the same time, it is optionally possible for two R¹ substituents bonded to the same carbon atom or to adjacent carbon atoms to form a monocyclic or polycyclic aliphatic ring system which may be substituted by one or more R² radicals, but is preferably unsubstituted, where Ar¹ may have the definition set out above.

Most preferably, the R¹ substituents are selected from the group consisting of H and an aromatic or heteroaromatic ring system which has 6 to 18 aromatic ring atoms, preferably 6 to 13 aromatic ring atoms, and may be substituted in each case by one or more nonaromatic R² radicals, but is preferably unsubstituted: Examples of suitable R¹ substituents are selected from the group consisting of phenyl, ortho-, meta- or para-biphenyl, terphenyl, especially branched terphenyl, quaterphenyl, especially branched quaterphenyl, 1-, 2-, 3- or 4-fluorenyl, 1-, 2-, 3- or 4-spirobifluorenyl, pyridyl, pyrimidinyl, 1-, 2-, 3- or 4-dibenzofuranyl, 1-, 2-, 3- or 4-dibenzothienyl and 1-, 2-, 3- or 4-carbazolyl, each of which may be substituted by one or more R² radicals, but are preferably unsubstituted.

It may further be the case that the organic-functional compounds OSM1 and OSM2 each comprise at least one group, preferably an S1 and S2 substituent; preferably, in the structure of formula (I) and/or (II), at least one structural element A and/or B or at least one Ar¹, Ar², Ar³, Ar⁴ and/or R¹ radical comprises a group, preferably is a group, selected from the formulae (R¹-1) to (R¹-95)

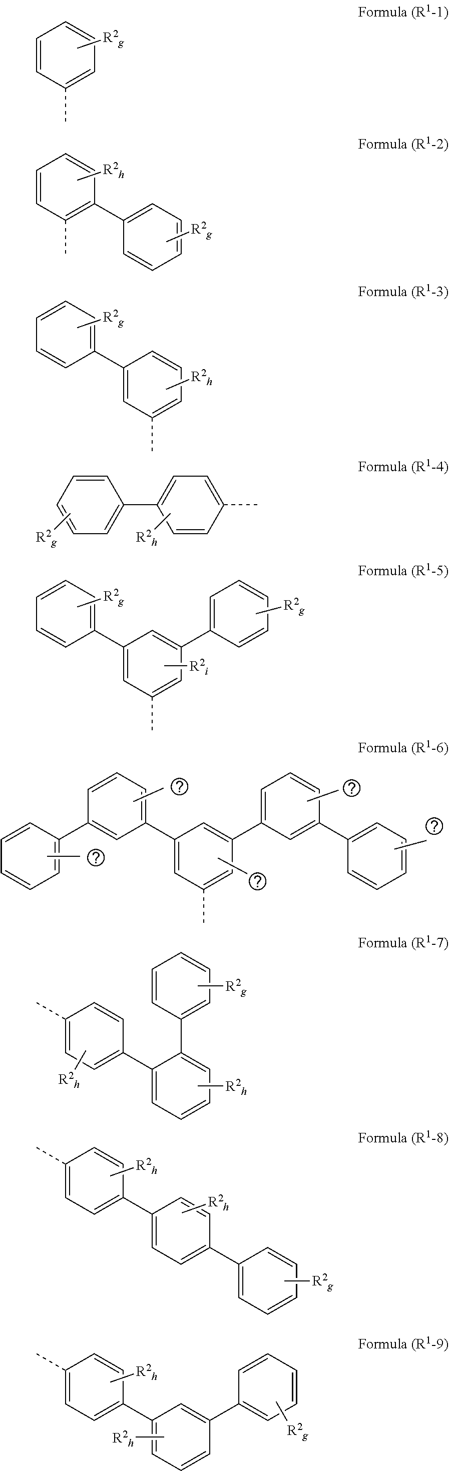

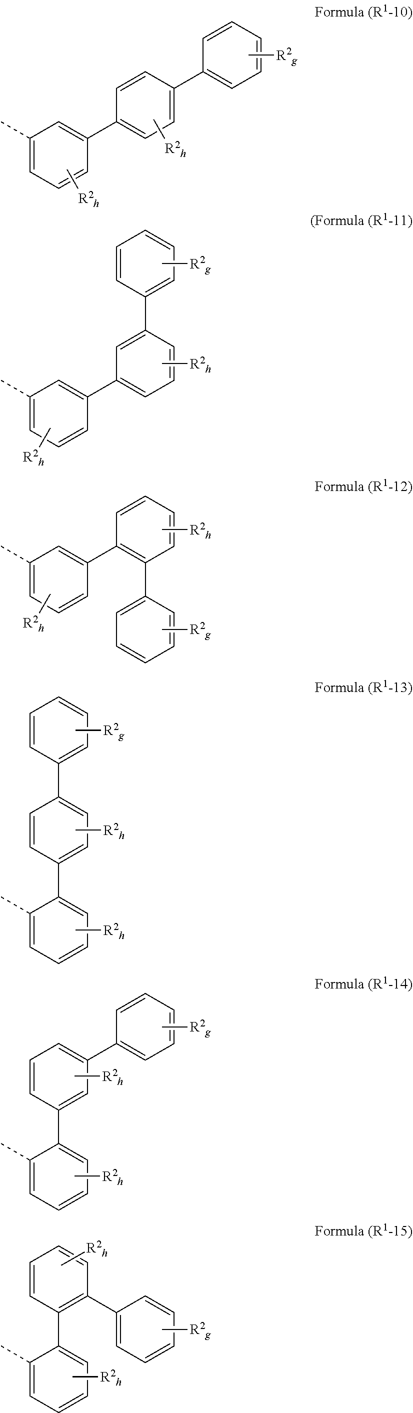

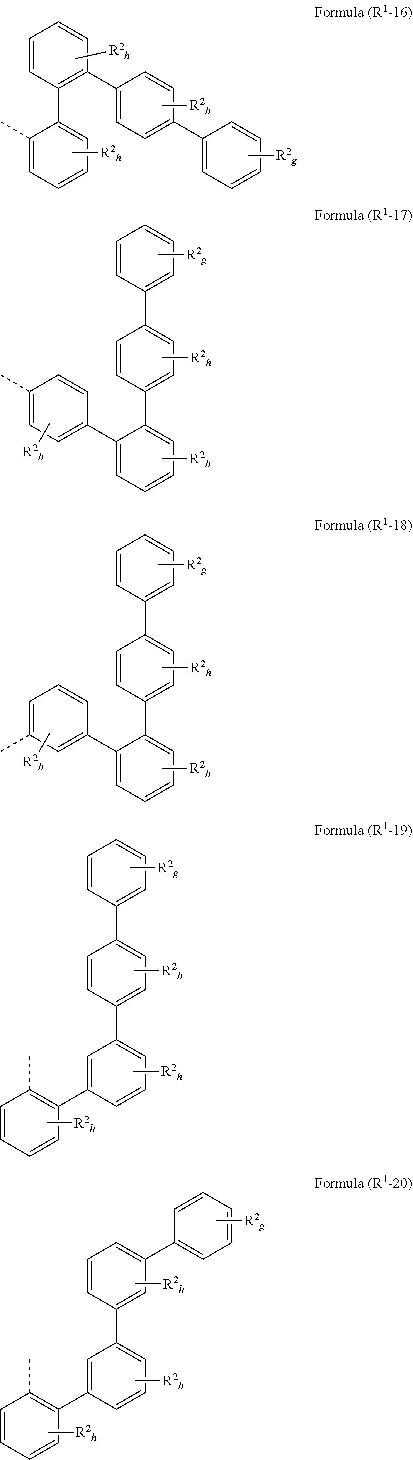

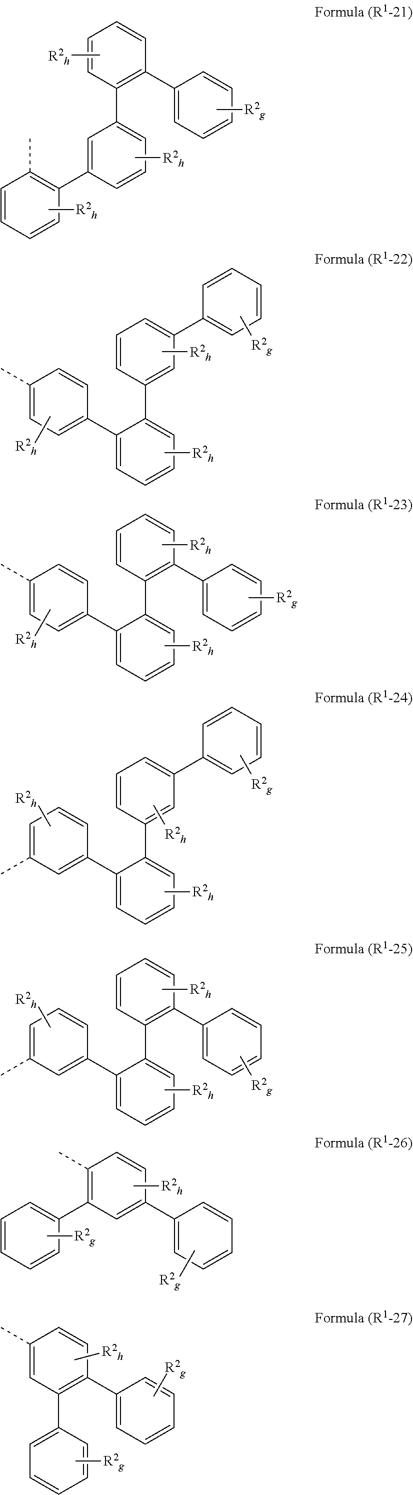

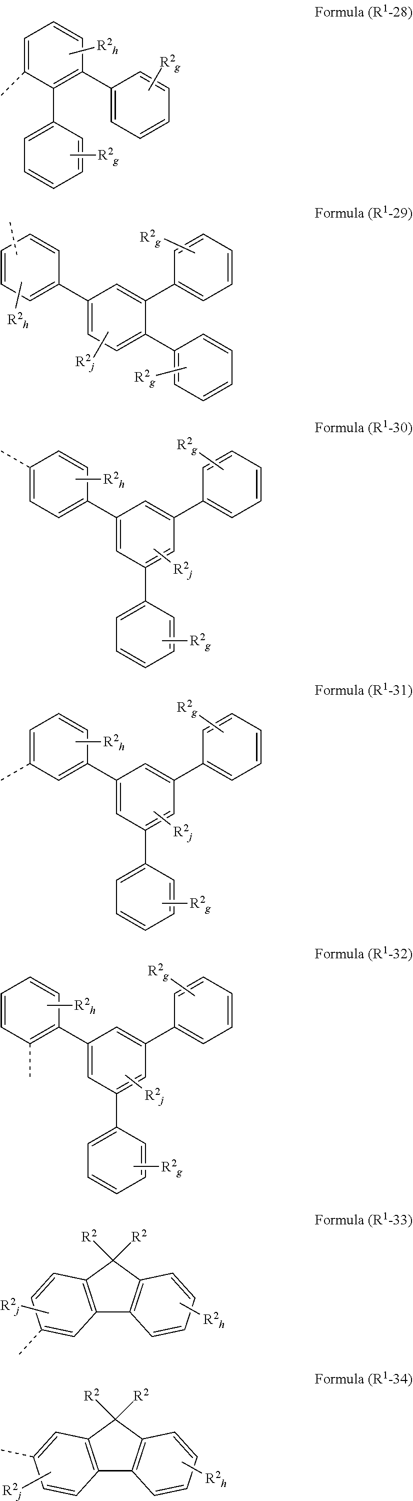

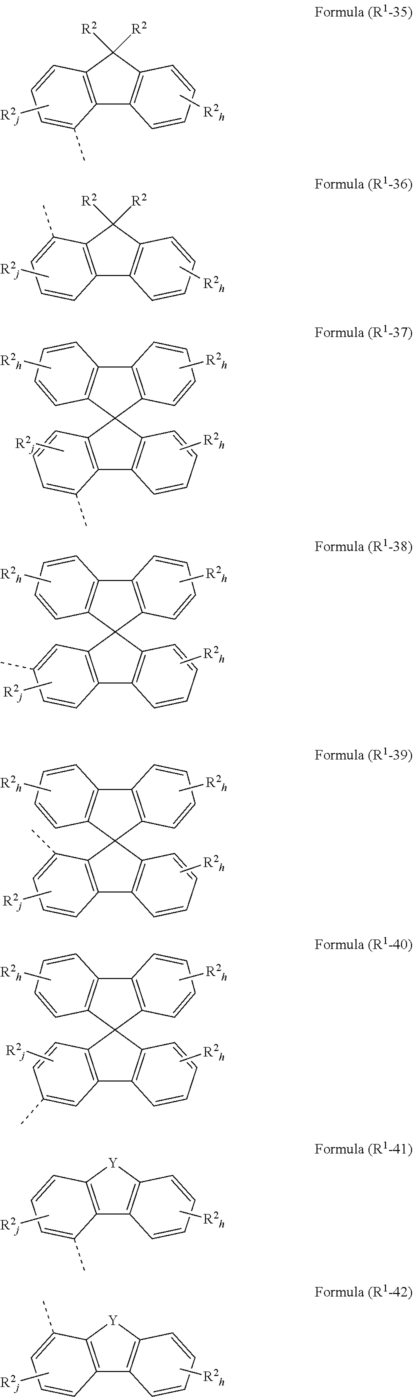

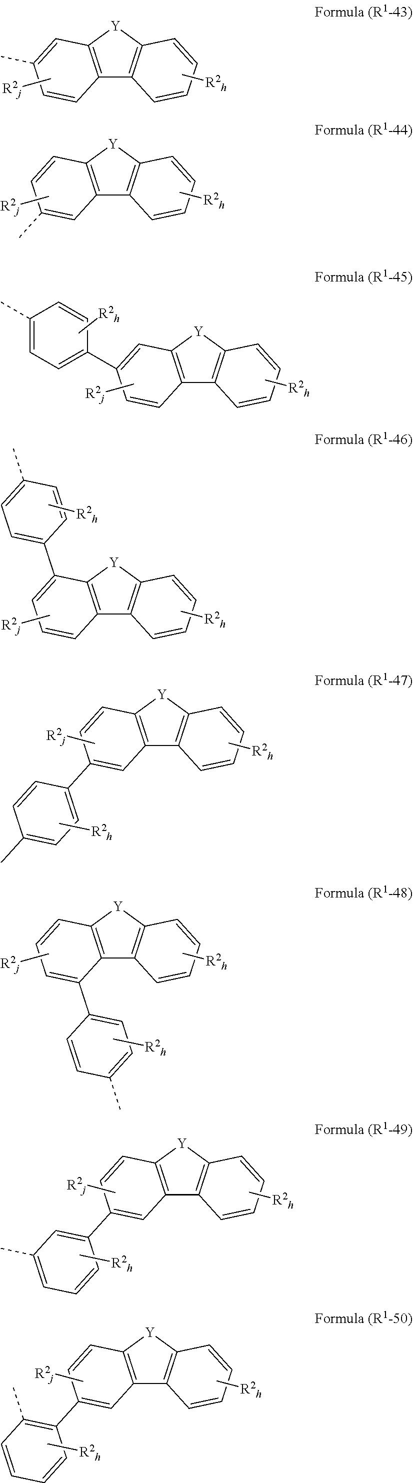

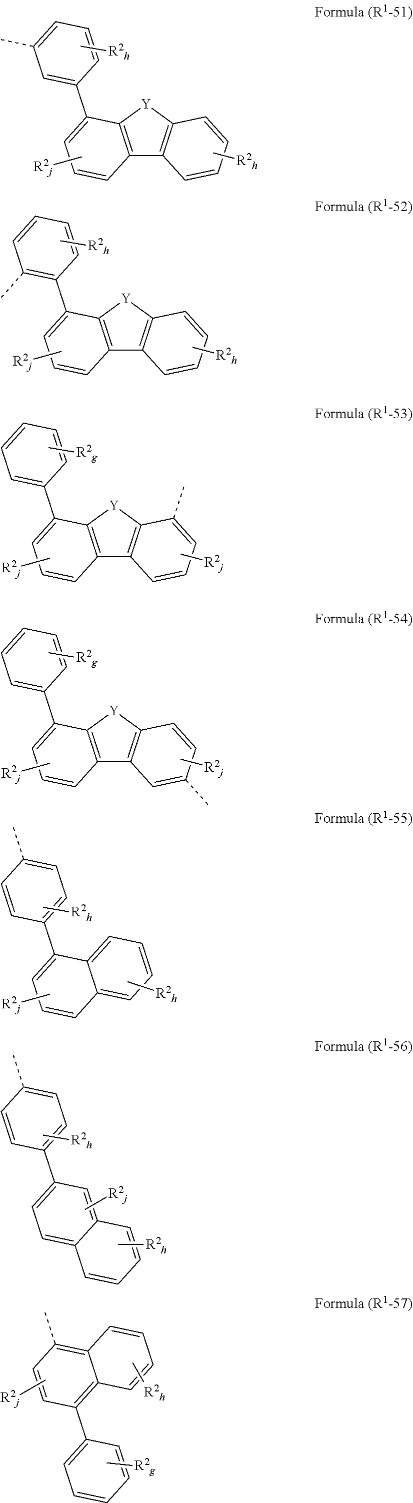

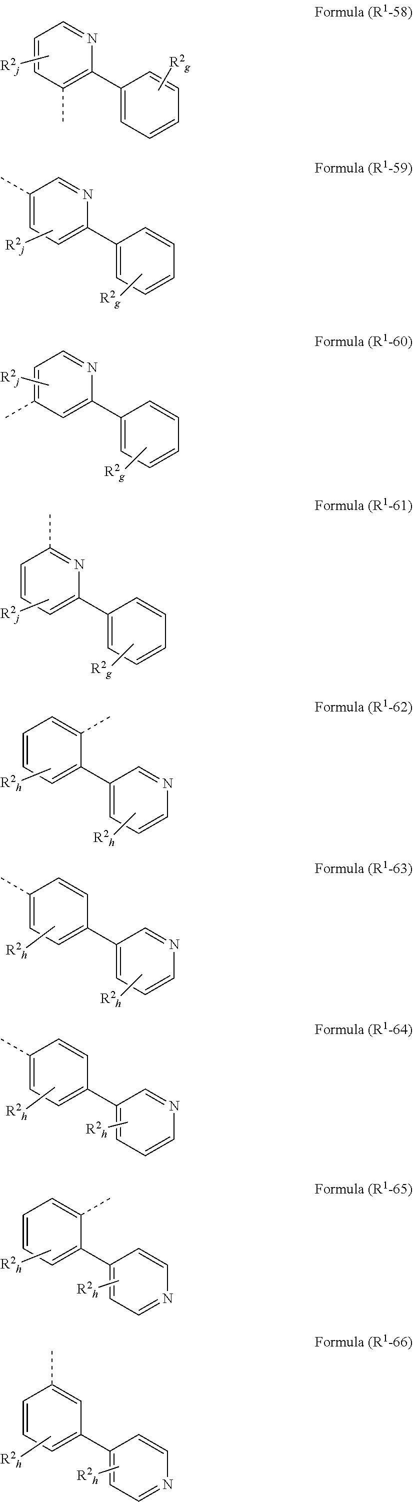

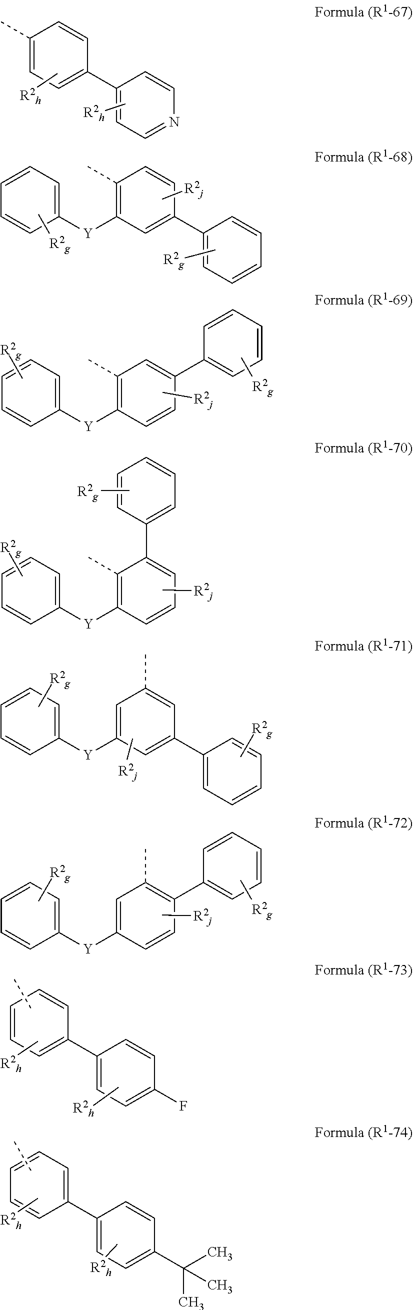

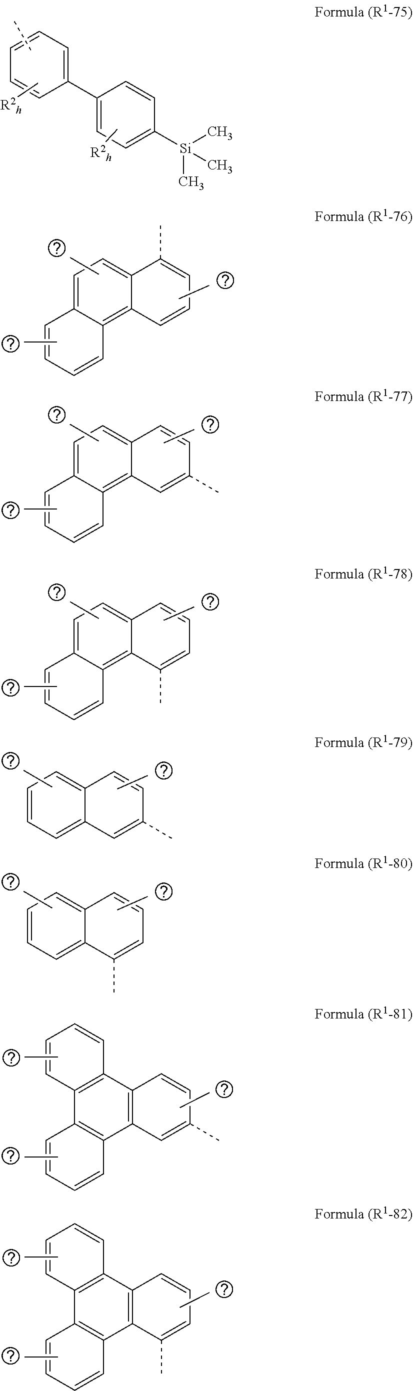

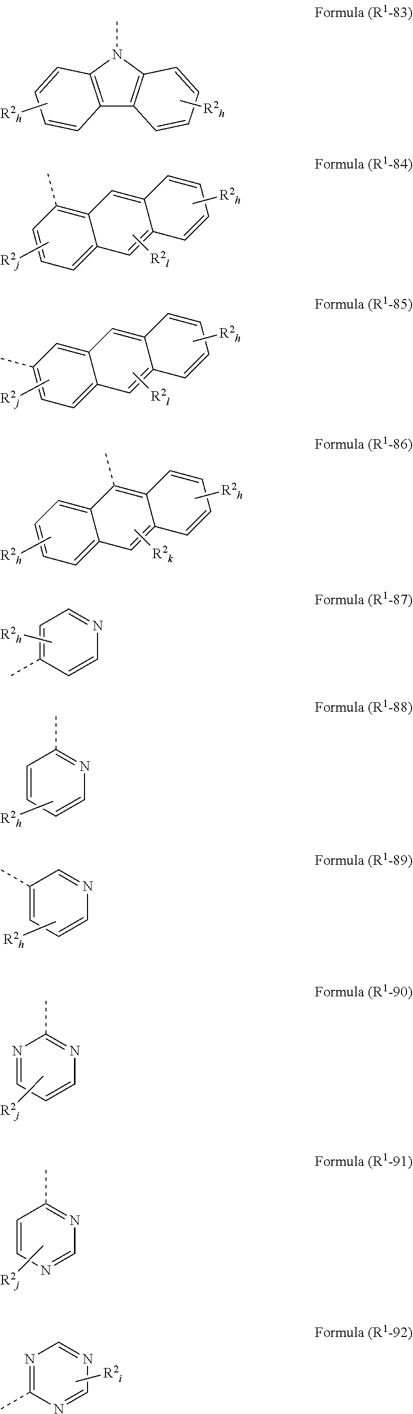

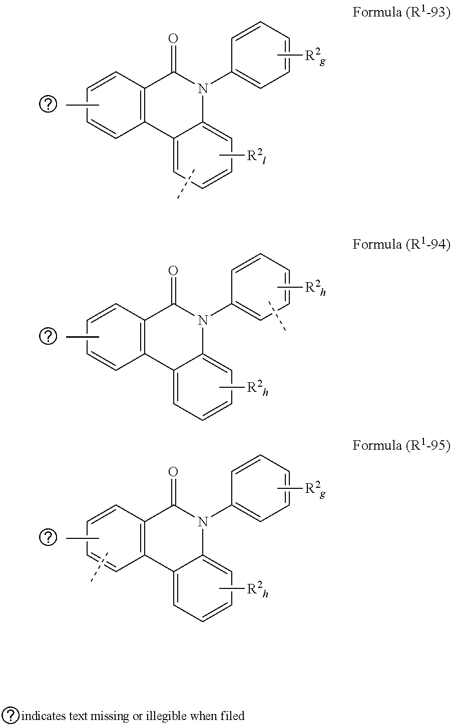

where the symbols used are as follows:

Y is O, S or NR², preferably O or S;

i at each instance is independently 0, 1 or 2;

j at each instance is independently 0, 1, 2 or 3;

h at each instance is independently 0, 1, 2, 3 or 4;

g at each instance is independently 0, 1, 2, 3, 4 or 5;

R² may have the definition given above, especially for formula (II), and the dotted bond marks the attachment position.

It may preferably be the case that the sum total of the indices i, j, h and g in the structures of the formula (R¹-1) to (R¹-95) is not more than 3 in each case, preferably not more than 2 and more preferably not more than 1.

Preferably, the R² radicals in the formulae (R¹-1) to (R¹-95) do not form a fused aromatic or heteroaromatic ring system, and preferably do not form any fused ring system, with the ring atoms of the aryl group or heteroaryl group to which the R² radicals are bonded. This includes the formation of a fused ring system with possible R³ substituents which may be bonded to the R² radicals.

It may further be the case that the constitutionally isomeric compounds OSM1 and OSM2 comprise at least one connecting group, such that at least one functional structural element is bonded to a further structural element; preferably, the connecting group is an aromatic or heteroaromatic ring system which in each case has 5 to 40 ring atoms and may be substituted, for example, by R¹ groups as described above. Preferably, the further structural element may be a hole transport group, an electron transport group, a solubilizing structural element, a crosslinkable group or a group which leads to host materials or to materials having wide band gap properties.

In addition, the constitutional isomers OSM1 and OSM2 may comprise at least one connecting group, such that at least one solubilizing structural element is bonded to a functional structural element; preferably, the connecting group is an aromatic or heteroaromatic ring system which in each case has 5 to 40 ring atoms and may be substituted, for example, by R¹ groups as described above.

Preferred connecting groups that may be encompassed by the constitutional isomers OSM1 and OSM2 are detailed by way of example hereinafter in connection with the L¹ group present in formula (QL) shown above. Preferably, the L¹ group may form through-conjugation with the Q group and the aromatic or heteroaromatic radical or the nitrogen atom to which the L¹ group of formula (QL) is bonded. Through-conjugation of the aromatic or heteroaromatic systems is formed as soon as direct bonds are formed between adjacent aromatic or heteroaromatic rings. A further bond between the aforementioned conjugated groups, for example via a sulfur, nitrogen or oxygen atom or a carbonyl group, is not detrimental to conjugation. In the case of a fluorene system, the two aromatic rings are bonded directly, where the sp³-hybridized carbon atom in position 9 does prevent fusion of these rings, but conjugation is possible, since this sp³-hybridized carbon atom in position 9 does not necessarily lie between the electron-transporting Q group and the fluorene structure. In contrast, in the case of a second spirobifluorene structure, through-conjugation can be formed if the bond between the Q group and the aromatic or heteroaromatic radical to which the L¹ group of formula (QL) is bonded is via the same phenyl group in the spirobifluorene structure or via phenyl groups in the spirobifluorene structure that are bonded directly to one another and are in one plane. If the bond between the Q group and the aromatic or heteroaromatic radical to which the L¹ group of formula (QL) is bonded is via different phenyl groups in the second spirobifluorene structure bonded via the sp³-hybridized carbon atom in position 9, the conjugation is interrupted.

In a further preferred embodiment of the invention, L¹ is a bond or an aromatic or heteroaromatic ring system which has 5 to 14 aromatic or heteroaromatic ring atoms, preferably an aromatic ring system which has 6 to 12 carbon atoms, and which may be substituted by one or more R¹ radicals, but is preferably unsubstituted, where R¹ may have the definition given above, especially for formula (II). More preferably, L¹ is an aromatic ring system having 6 to 10 aromatic ring atoms or a heteroaromatic ring system having 6 to 13 heteroaromatic ring atoms, each of which may be substituted by one or more R² radicals, but is preferably unsubstituted, where R² may have the definition given above, especially for formula (II).

Further preferably, the symbol L¹ shown in formula (QL) inter alia is the same or different at each instance and is a bond or an aryl or heteroaryl radical having 5 to 24 ring atoms, preferably 6 to 13 ring atoms, more preferably 6 to 10 ring atoms, such that an aromatic or heteroaromatic group of an aromatic or heteroaromatic ring system is bonded to the respective atom of the further group directly, i.e. via an atom of the aromatic or heteroaromatic group.

It may additionally be the case that the L¹ group shown in formula (QL) comprises an aromatic ring system having not more than two fused aromatic and/or heteroaromatic rings, preferably does not comprise any fused aromatic or heteroaromatic ring system. Accordingly, naphthyl structures are preferred over anthracene structures. In addition, fluorenyl, spirobifluorenyl, dibenzofuranyl and/or dibenzothienyl structures are preferred over naphthyl structures.

Particular preference is given to structures having no fusion, for example phenyl, biphenyl, terphenyl and/or quaterphenyl structures.

Examples of suitable aromatic or heteroaromatic ring systems L¹ are selected from the group consisting of ortho-, meta- or para-phenylene, ortho-, meta- or para-biphenylene, terphenylene, especially branched terphenylene, quaterphenylene, especially branched quaterphenylene, fluorenylene, spirobifluorenylene, dibenzofuranylene, dibenzothienylene and carbazolylene, each of which may be substituted by one or more R² radicals, but are preferably unsubstituted.

It may further be the case that the L¹ group shown in formula (QL) inter alia has not more than 1 nitrogen atom, preferably not more than 2 heteroatoms, especially preferably not more than one heteroatom and more preferably no heteroatom.

Preference is given to compounds OSM1 and OSM2 comprising at least one structure of the formulae (H-1) to (H-26) in which the Ar² group is a group selected from the formulae (L¹-1) to (L¹-109) and/or to compounds OSM1 and OSM2 comprising at least one connecting group, and/or to compounds OSM1 and OSM2 comprising structures of the formula (QL) in which the L¹ group is a bond or is a group selected from the formulae (L¹-1) to (L¹-109)

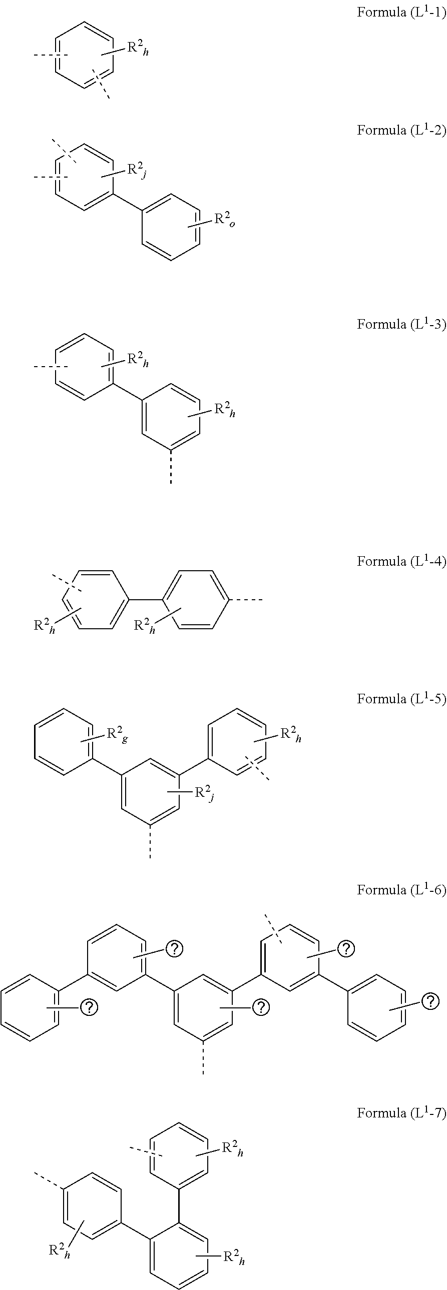

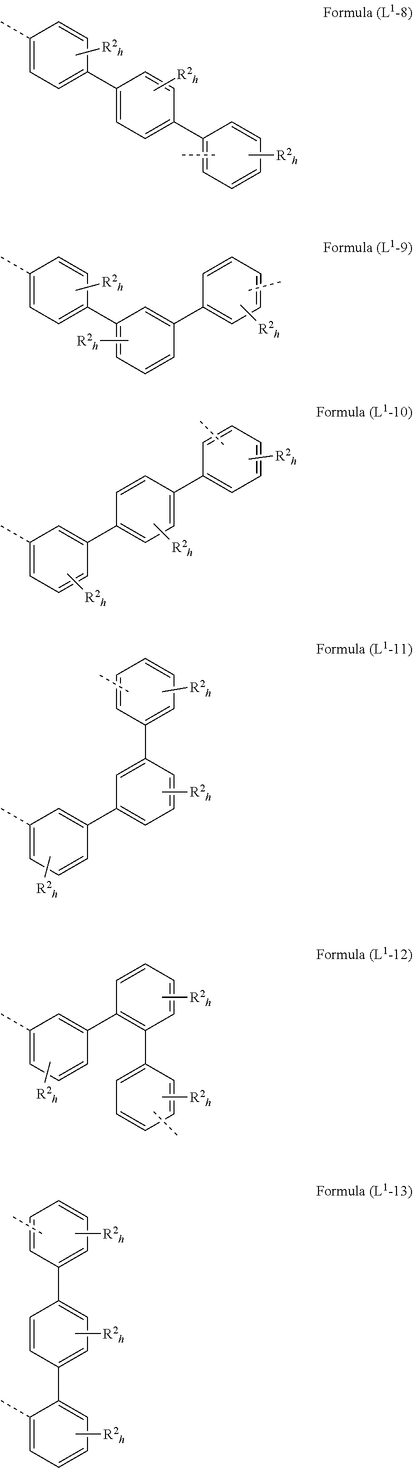

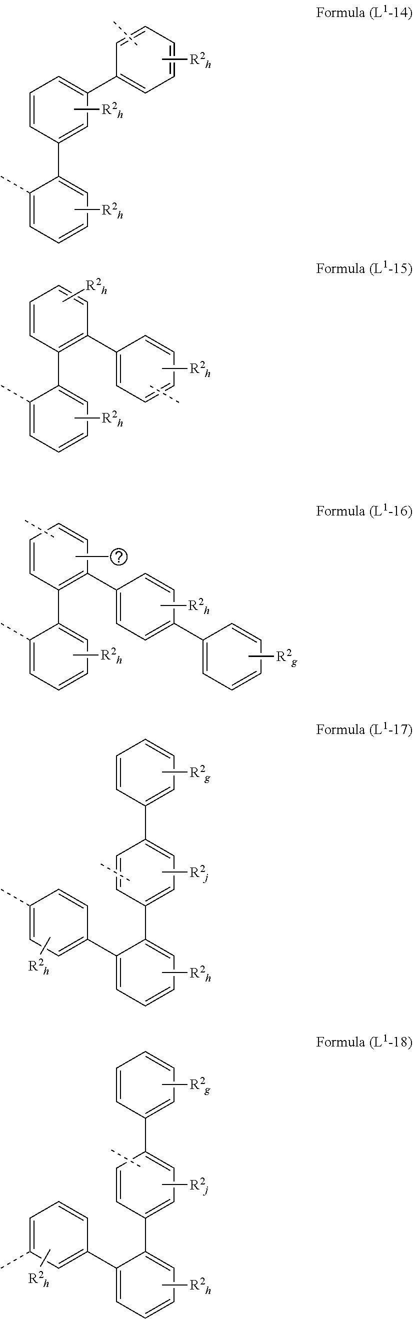

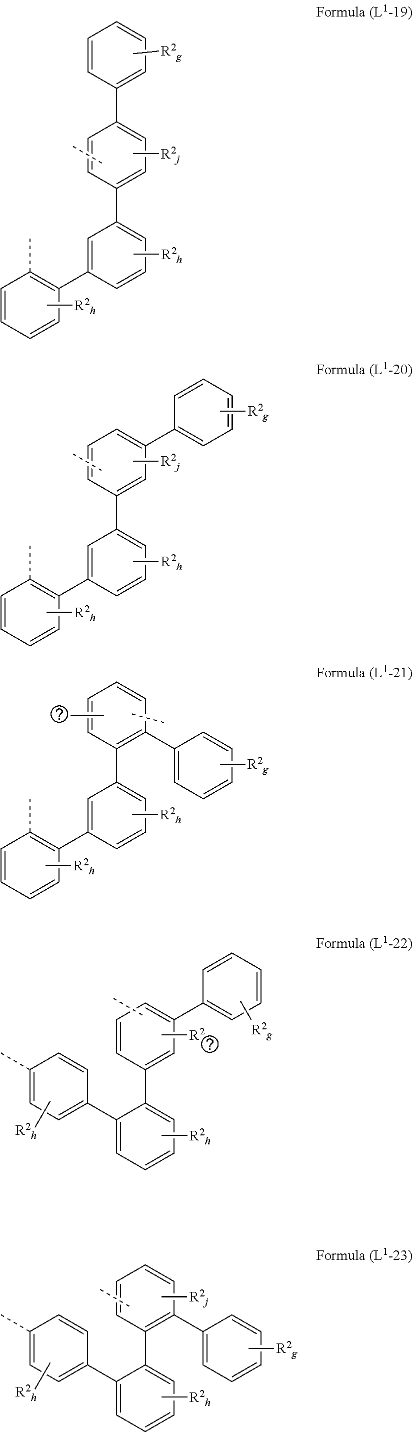

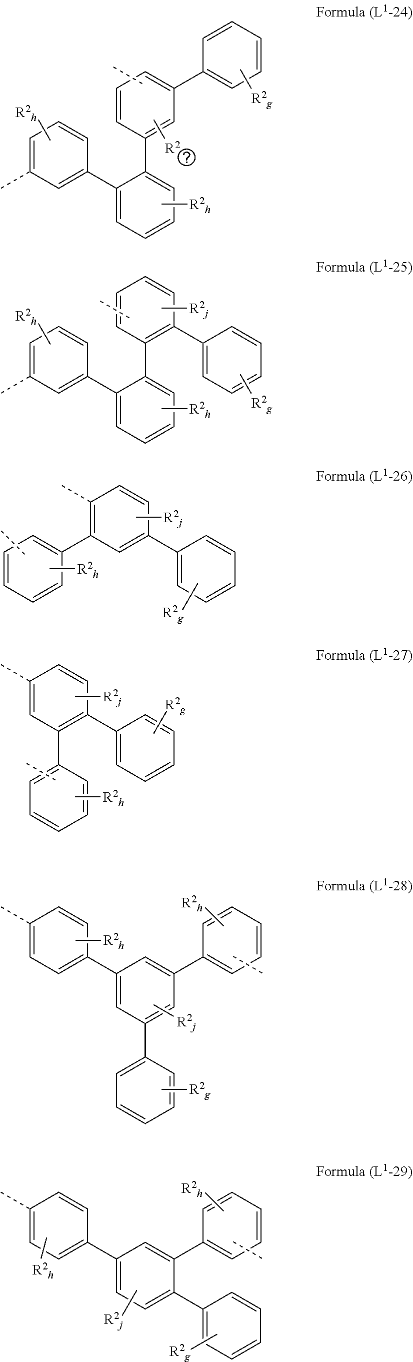

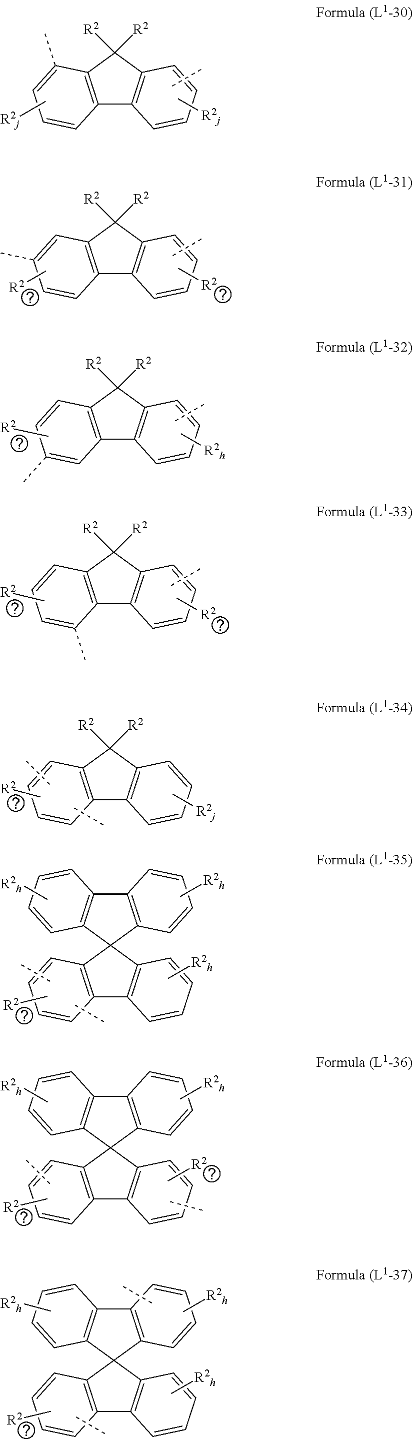

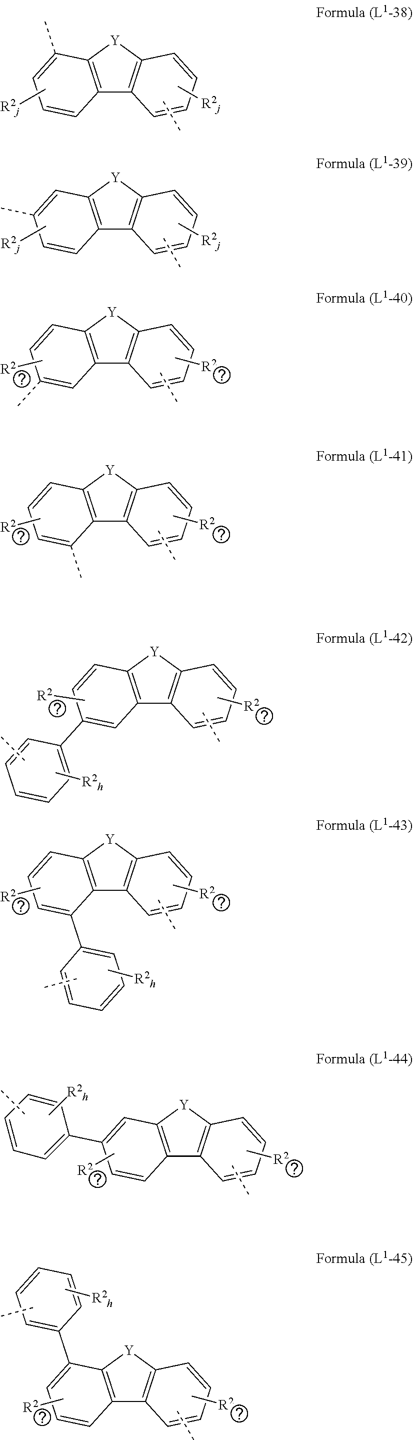

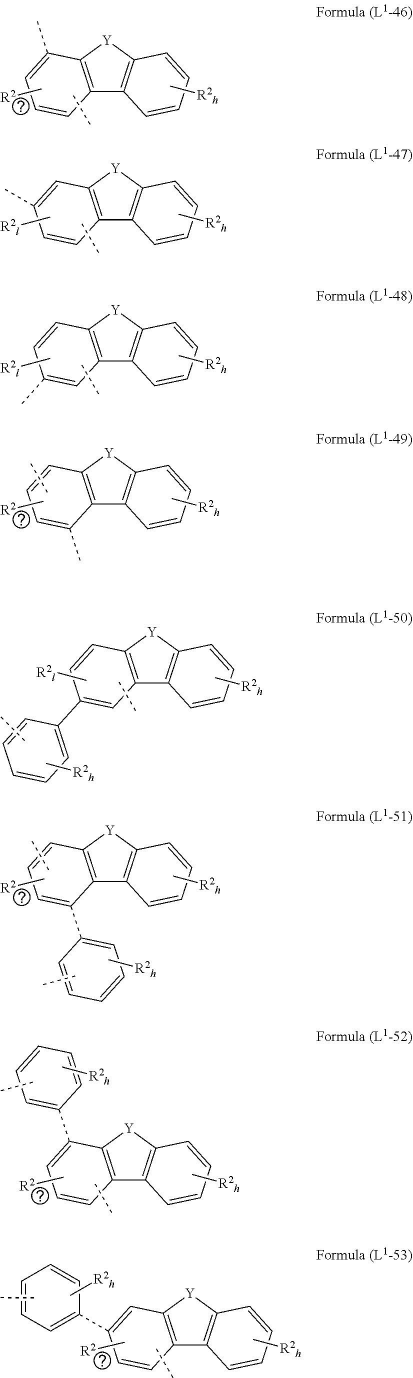

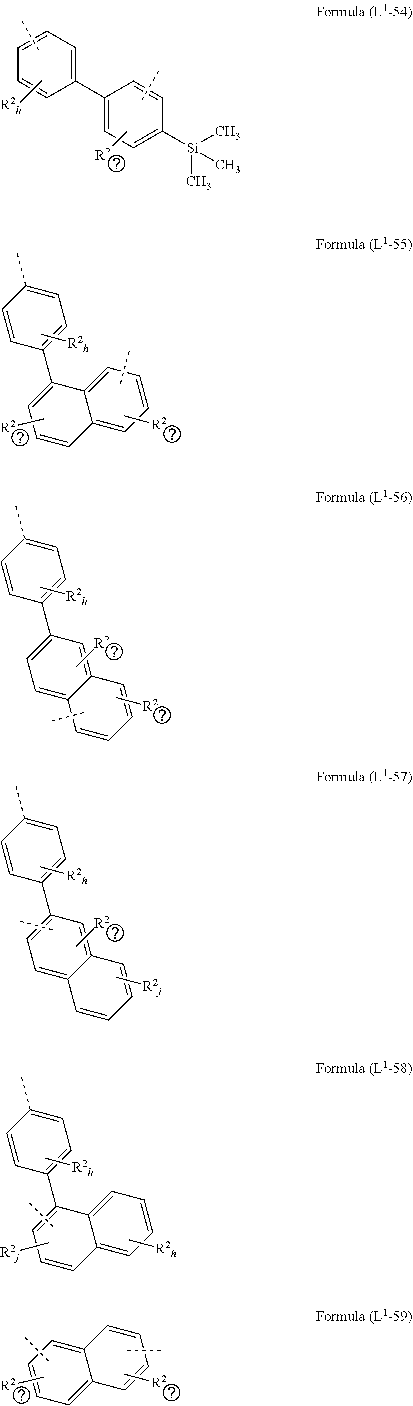

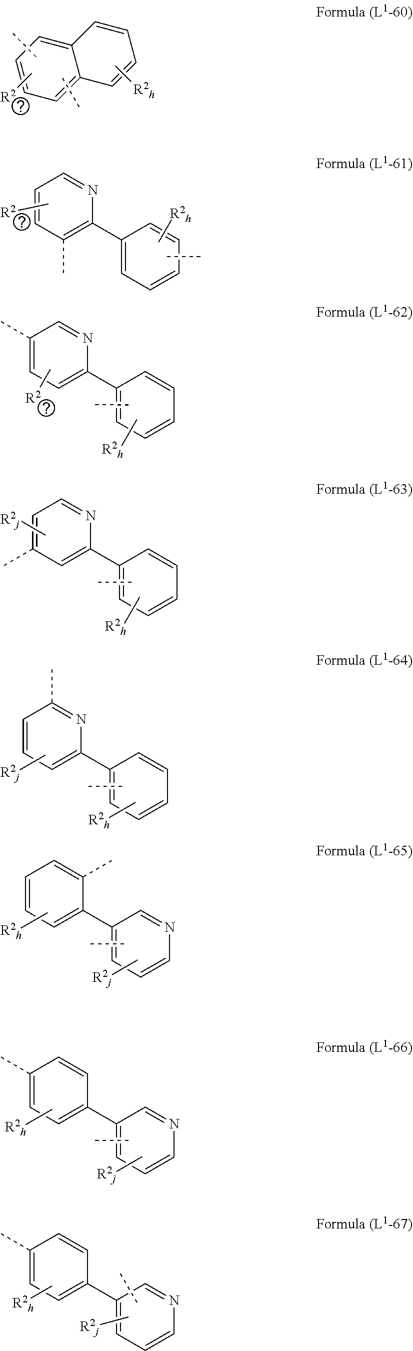

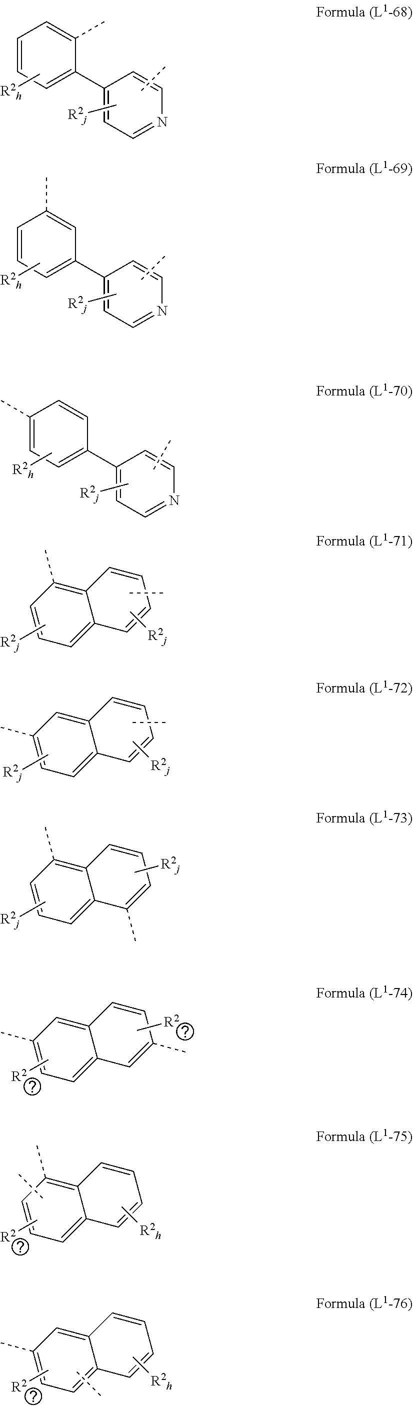

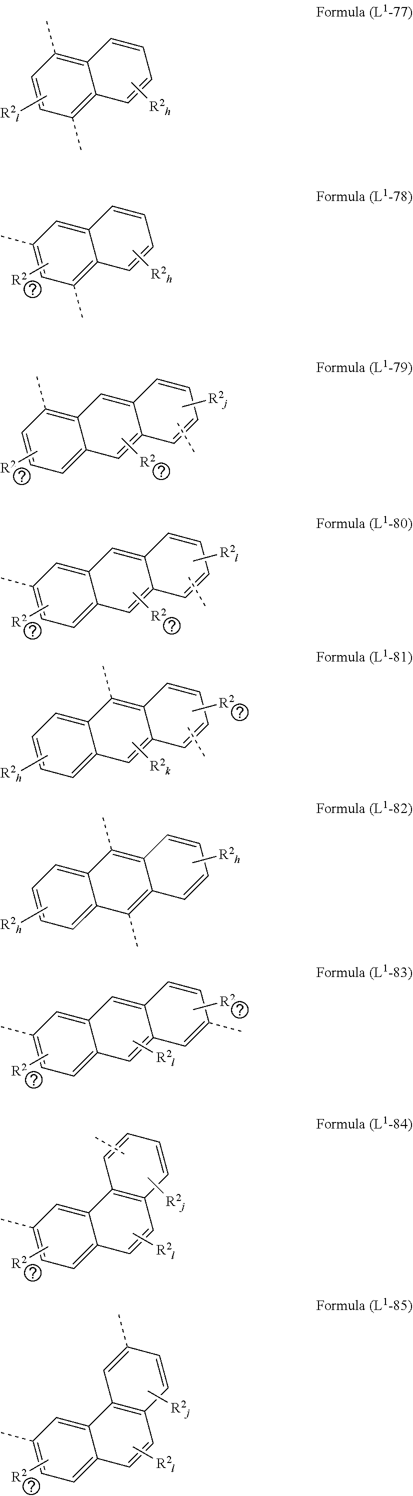

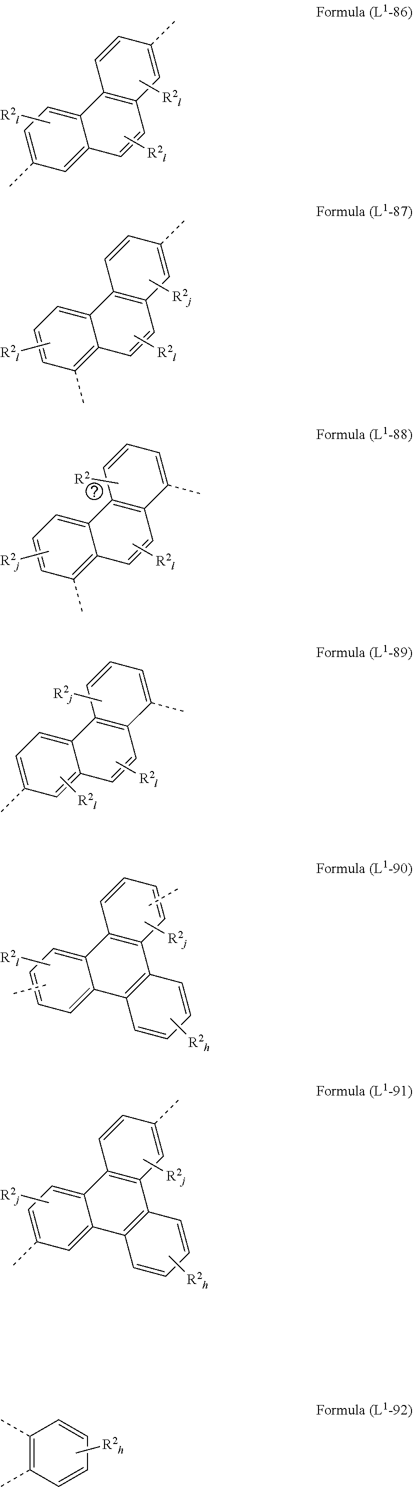

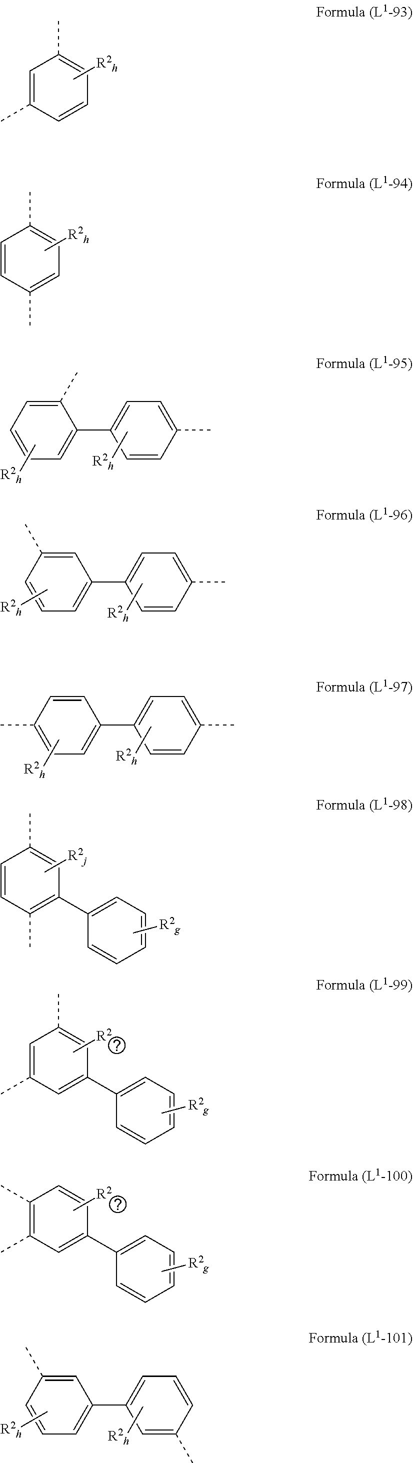

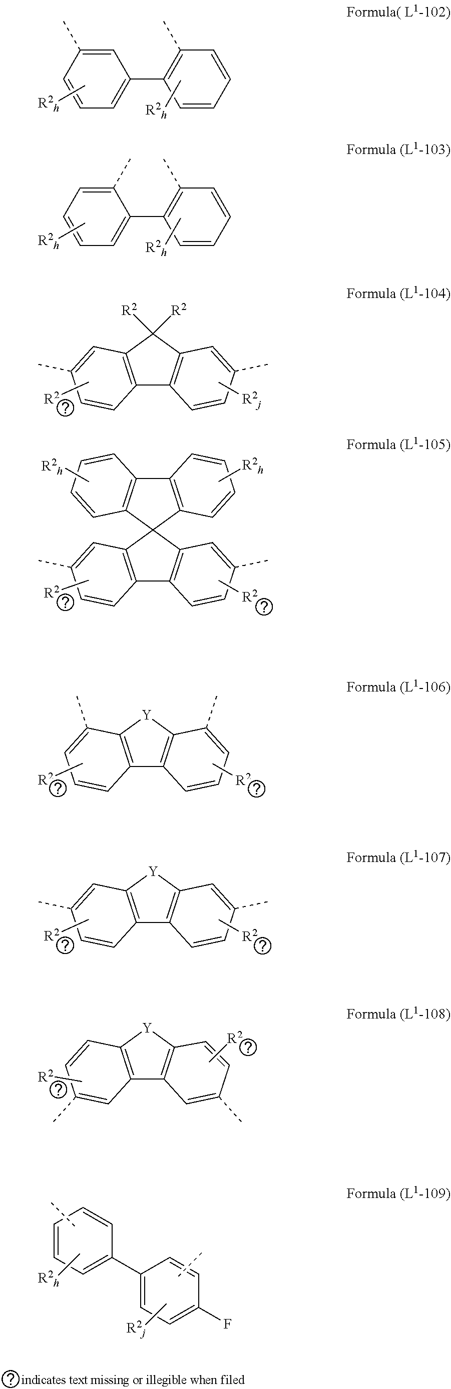

where the dotted bonds in each case mark the attachment positions, the index k is 0 or 1, the index I is 0, 1 or 2, the index j at each instance is independently 0, 1, 2 or 3; the index h at each instance is independently 0, 1, 2, 3 or 4, the index g is 0, 1, 2, 3, 4 or 5; the symbol Y is O, S or NR², preferably O or S; and the symbol R² has the definition given above, especially for formula (II).

It may preferably be the case that the sum total of the indices k, l, g, h and j in the structures of the formula (L¹-1) to (L¹-109) is at most 3 in each case, preferably at most 2 and more preferably at most 1.

Preferred compounds of the invention having a group of the formula (QL) comprise an L group which represents a bond or which is selected from one of the formulae (L¹-1) to (L¹-78) and/or (L¹-92) to (L¹-109), preferably of the formula (L¹-1) to (L¹-54) and/or (L¹-92) to (L¹-108), especially preferably of the formula (L¹-1) to (L¹-29) and/or (L¹-92) to (L¹-103). Advantageously, the sum total of the indices k, l, g, h and j in the structures of the formulae (L¹-1) to (L¹-78) and/or (L¹-92) to (L¹-109), preferably of the formula (L¹-1) to (L¹-54) and/or (L¹-92) to (L¹-109), especially preferably of the formula (L¹-1) to (L¹-29) and/or (L¹-92) to (L¹-103), may in each case be not more than 3, preferably not more than 2 and more preferably not more than 1.

Preferred compounds of the invention having a group of the formulae (H-1) to (H-26) comprise an Ar² group selected from one of the formulae (L¹-1) to (L¹-78) and/or (L¹-92) to (L¹-109), preferably of the formula (L¹-1) to (L¹-54) and/or (L¹-92) to (L¹-108), especially preferably of the formula (L¹-1) to (L¹-29) and/or (L¹-92) to (L¹-103). Advantageously, the sum total of the indices k, l, g, h and j in the structures of the formulae (L¹-1) to (L¹-78) and/or (L¹-92) to (L¹-109), preferably of the formula (L¹-1) to (L¹-54) and/or (L¹-92) to (L¹-108), especially preferably of the formula (L¹-1) to (L¹-29) and/or (L¹-92) to (L¹-103), may in each case be not more than 3, preferably not more than 2 and more preferably not more than 1.

Preferably, the R² radicals in the formulae (L¹-1) to (L¹-109) do not form a fused aromatic or heteroaromatic ring system, and preferably do not form any fused ring system, with the ring atoms of the aryl group or heteroaryl group to which the R² radicals are bonded. This includes the formation of a fused ring system with possible R³ substituents which may be bonded to the R² radicals.

When the compounds OSM1 and OSM2 usable in accordance with the invention are substituted by aromatic or heteroaromatic R¹ or R² groups, especially in the case of configuration thereof as host material, electron transport material or hole transport material for green or red OLEDs, it is preferable when they do not have any aryl or heteroaryl groups having more than two aromatic six-membered rings fused directly to one another. More preferably, the substituents do not have any aryl or heteroaryl groups having six-membered rings fused directly to one another at all. The reason for this preference is the low triplet energy of such structures. Fused aryl groups which have more than two aromatic six-membered rings fused directly to one another but are nevertheless also suitable in accordance with the invention are phenanthrene and triphenylene, since these also have a high triplet level.

In the case of configuration of the compounds OSM1 and OSM2 usable in accordance with the invention for use as fluorescent emitters or as blue OLED materials, preferred compounds may contain corresponding groups, for example fluorene, anthracene and/or pyrene groups which may be substituted by R² groups or which are formed by corresponding substitution of the (R¹-1) to (R¹-95) groups, preferably (R¹-33) to (R¹-57) and (R¹-76) to (R¹-86), or (L¹-1) to (L¹-109), preferably (L¹-30) to (R¹-60) and (R¹-71) to (R¹-91), by the R² substituents.

In a further preferred embodiment of the invention, R², for example in a structure of formula (II) and preferred embodiments of this structure or the structures where reference is made to these formulae, is the same or different at each instance and is selected from the group consisting of H, D, an aliphatic hydrocarbyl radical having 1 to 10 carbon atoms, preferably having 1, 2, 3 or 4 carbon atoms, or an aromatic or heteroaromatic ring system which has 5 to 30 aromatic ring atoms, preferably 5 to 24 aromatic ring atoms, more preferably 5 to 13 aromatic ring atoms, and may be substituted by one or more alkyl groups each having 1 to 4 carbon atoms, but is preferably unsubstituted.

In a further preferred embodiment of the invention, R³, for example in a structure of formula (II) and preferred embodiments of this structure or the structures where reference is made to these formulae, is the same or different at each instance and is selected from the group consisting of H, D, F, CN, an aliphatic hydrocarbyl radical having 1 to 10 carbon atoms, preferably having 1, 2, 3 or 4 carbon atoms, or an aromatic or heteroaromatic ring system which has 5 to 30 aromatic ring atoms, preferably 5 to 24 aromatic ring atoms, more preferably 5 to 13 aromatic ring atoms, and may be substituted by one or more alkyl groups each having 1 to 4 carbon atoms, but is preferably unsubstituted.

In a further configuration, it may be the case that the compounds OSM1 and OSM2 for use in accordance with the invention each have at least one solubilizing group. Therefore, in the configurations detailed above, the substituent S1, the substituent S2 and/or the group B may comprise, preferably constitute, a solubilizing structural element.

Preference is given, inter alia, to mixtures according to the present invention in which the organic-functional compounds OSM1 and OSM2 each comprise at least one solubilizing group, where the organic-functional compounds OSM1 and OSM2 differ in that the solubilizing groups of the organic-functional compounds OSM1 and OSM2 are constitutional isomers of one another which preferably contain the same number of aromatic or heteroaromatic ring systems and have essentially the same substituents.

Preferably, a solubilizing group or solubilizing structural element may comprise, preferably constitute, a relatively long alkyl group (about 4 to 20 carbon atoms), especially a branched alkyl group, or an optionally substituted aryl group. The preferred aryl groups include a xylyl, mesityl, terphenyl or quaterphenyl group, particular preference being given to branched terphenyl or quaterphenyl groups.

In a further configuration, it may be the case that the compounds OSM1 and OSM2 for use in accordance with the invention each have at least one crosslinkable group. Therefore, in the configurations detailed above, the substituent S1, the substituent S2 and/or the group B may comprise, preferably constitute, a crosslinkable group, which can optionally be regarded as a structural element.

The compounds OSM1 and OSM2 usable in accordance with the invention may, as explained above, contain one or more crosslinkable groups. “Crosslinkable group” means a functional group capable of reacting irreversibly. This forms a crosslinked material which is insoluble. The crosslinking can usually be promoted by means of heat or by means of UV radiation, microwave radiation, x-radiation or electron beams. In this case, there is little by-product formation in the crosslinking. In addition, the crosslinkable groups that may be present in the functional compounds crosslink very readily, such that relatively small amounts of energy are required for the crosslinking (for example <200° C. in the case of thermal crosslinking).

Examples of crosslinkable groups are units containing a double bond, a triple bond, a precursor capable of in situ formation of a double or triple bond, or a heterocyclic addition-polymerizable radical. Crosslinkable groups include vinyl, alkenyl, preferably ethenyl and propenyl, C₄₋₂₀-cycloalkenyl, azide, oxirane, oxetane, di(hydrocarbyl)amino, cyanate ester, hydroxyl, glycidyl ether, C₁₋₁₀-alkyl acrylate, C₁₋₁₀-alkyl methacrylate, alkenyloxy, preferably ethenyloxy, perfluoroalkenyloxy, preferably perfluoroethenyloxy, alkynyl, preferably ethynyl, maleimide, cyclobutylphenyl, tri(C₁₋₄)-alkylsiloxy and tri(C₁₋₄)-alkylsilyl. Particular preference is given to cyclobutylphenyl, vinyl and alkenyl.

Preferably, the constitutionally isomeric organic-functional compounds OSM1 and OSM2 may each contain at least one solubilizing structural element or solubilizing group and at least one functional structural element or functional group, the functional structural element or the functional group being selected from hole transport groups, electron transport groups, structural elements or groups which lead to host materials, or structural elements or groups having wide band gap properties.

Preferably, the constitutionally isomeric organic-functional compounds OSM1 and OSM2 may each contain at least one crosslinkable structural element or crosslinkable group and at least one functional structural element or functional group, the functional structural element or the functional group being selected from hole transport groups, electron transport groups, structural elements or groups which lead to host materials, or structural elements or groups having wide band gap properties.

The expression “structural elements or groups having wide band gap properties” sets out that the compounds OSM1 and OSM2 can each be used as wide band gap materials, and so the compounds OSM1 and OSM2 have corresponding groups. The same applies to the expression “structural elements or groups which lead to host materials”. These expressions are widely known in the art and are elucidated in more detail hereinafter, in connection with further materials as well. It should be stated in this regard that the compounds OSM1 and OSM2 are constitutional isomers which differ by their structure. The remarks which follow should accordingly be understood such that the compounds mentioned explicitly are used in combination with a further, constitutionally isomeric compound. In addition, the compounds mentioned explicitly can readily be modified by appropriate substitution, giving two constitutionally isomeric compounds that are used as a mixture. The substituents can in principle be chosen as desired, but they are preferably selected from the above-detailed substituents S1, S2 and/or R¹, preference being given to selecting functional groups, solubilizing groups or crosslinkable groups as substituent, as already described above.

Organic-functional materials are in many cases described in terms of the properties of the interface orbitals which are detailed hereinafter. Molecular orbitals, especially also the highest occupied molecular orbital (HOMO) and the lowest unoccupied molecular orbital (LUMO), the energy levels thereof and the energy of the lowest triplet state T₁ and that of the lowest excited singlet state S₁ of the materials are determined via quantum-chemical calculations. For calculation of organic substances without metals, an optimization of geometry is first conducted by the “Ground State/Semi-empirical/Default Spin/AM1/Charge 0/Spin Singlet” method. Subsequently, an energy calculation is effected on the basis of the optimized geometry. This is done using the “TD-SCF/DFT/Default Spin/B3PW91” method with the “6-31G(d)” basis set (charge 0, spin singlet). For metal-containing compounds, the geometry is optimized via the “Ground State/Hartree-Fock/Default Spin/LanL2 MB/Charge 0/Spin Singlet” method. The energy calculation is effected analogously to the above-described method for the organic substances, except that the “LanL2DZ” basis set is used for the metal atom and the “6-31G(d)” basis set for the ligands. The HOMO energy level HEh or LUMO energy level LEh is obtained from the energy calculation in Hartree units. This is used to determine the HOMO and LUMO energy levels in electron volts, calibrated by cyclic voltammetry measurements, as follows:

HOMO(eV)=((HEh*27.212)−0.9899)/1.1206

LUMO(eV)=((LEh*27.212)−2.0041)/1.385

These values are to be regarded as HOMO and LUMO energy levels of the materials in the context of this application.

The lowest triplet state T₁ is defined as the energy of the triplet state having the lowest energy, which is apparent from the quantum-chemical calculation described.

The lowest excited singlet state S₁ is defined as the energy of the excited singlet state having the lowest energy, which is apparent from the quantum-chemical calculation described.

The method described herein is independent of the software package used and always gives the same results. Examples of frequently utilized programs for this purpose are “Gaussian09 W” (Gaussian Inc.) and Q-Chem 4.1 (Q-Chem, Inc.).

Compounds, or groups or structural elements, having hole injection properties, also called hole injection materials herein, facilitate or enable the transfer of holes, i.e. positive charges, from the anode into an organic layer. In general, a hole injection material has a HOMO level which is in the region of the level of the anode or higher, i.e. generally at least −5.3 eV. Compounds, or groups or structural elements, having hole transport properties, also called hole transport materials herein, are capable of transporting holes, i.e. positive charges, which are generally injected from the anode or an adjoining layer, for example a hole injection layer. A hole transport material generally has a high HOMO level of preferably at least −5.4 eV. According to the construction of an electronic device, it is also possible to use a hole transport material as hole injection material.

The preferred compounds, or groups or structural elements, having hole injection and/or hole transport properties include, for example, triarylamine, benzidine, tetraaryl-para-phenylenediamine, triarylphosphine, phenothiazine, phenoxazine, dihydrophenazine, thianthrene, dibenzo-para-dioxin, phenoxathiine, carbazole, azulene, thiophene, pyrrole and furan derivatives and further O-, S- or N-containing heterocycles with a high-lying HOMO (HOMO=highest occupied molecular orbital).

Particular mention should be made of the following compounds, or groups or structural elements, having hole injection and/or hole transport properties: phenylenediamine derivatives (U.S. Pat. No. 3,615,404), arylamine derivatives (U.S. Pat. No. 3,567,450), amino-substituted chalcone derivatives (U.S. Pat. No. 3,526,501), styrylanthracene derivatives (JP-A-56-46234), polycyclic aromatic compounds (EP 1009041), polyarylalkane derivatives (U.S. Pat. No. 3,615,402), fluorenone derivatives (JP-A-54-110837), hydrazone derivatives (U.S. Pat. No. 3,717,462), acylhydrazones, stilbene derivatives (JP-A-61-210363), silazane derivatives (U.S. Pat. No. 4,950,950), polysilanes (JP-A-2-204996), aniline copolymers (JP-A-2-282263), thiophene oligomers (JP Heisei 1 (1989) 211399), polythiophenes, poly(N-vinylcarbazole) (PVK), polypyrroles, polyanilines and other electrically conductive macromolecules, porphyrin compounds (JP-A-63-2956965, U.S. Pat. No. 4,720,432), aromatic dimethylidene-type compounds, carbazole compounds, for example CDBP, CBP, mCP, aromatic tertiary amine and styrylamine compounds (U.S. Pat. No. 4,127,412), for example triphenylamines of the benzidine type, triphenylamines of the styrylamine type and triphenylamines of the diamine type. It is also possible to use arylamine dendrimers (JP Heisei 8 (1996) 193191), monomeric triarylamines (U.S. Pat. No. 3,180,730), triarylamines having one or more vinyl radicals and/or at least one functional group having active hydrogen (U.S. Pat. Nos. 3,567,450 and 3,658,520) or tetraaryldiamines (the two tertiary amine units are joined via an aryl group). It is also possible for even more triarylamino groups to be present in the molecule. Also suitable are phthalocyanine derivatives, naphthalocyanine derivatives, butadiene derivatives and quinoline derivatives, for example dipyrazino[2,3-f:2′,3′-h]quinoxalinehexacarbonitrile.

Preference is given to aromatic tertiary amines having at least two tertiary amine units (US 2008/0102311 A1, U.S. Pat. Nos. 4,720,432 and 5,061,569), for example NPD (α-NPD=4,4′-bis[N-(1-naphthyl)-N-phenylamino]biphenyl) (U.S. Pat. No. 5,061,569), TPD 232 (=N,N′-bis(N,N′-diphenyl-4-aminophenyl)-N,N-diphenyl-4,4′-diamino-1,1′-biphenyl) or MTDATA (MTDATA or m-MTDATA=4,4′,4″-tris[3-(methylphenyl)phenylamino]triphenylamine) (JP-A-4-308688), TBDB (=N,N,N′,N′-tetra(4-biphenyl)diaminobiphenylene), TAPC(═1,1-bis(4-di-p-tolylaminophenyl)cyclohexane), TAPPP (═1,1-bis(4-di-p-tolylaminophenyl)-3-phenylpropane), BDTAPVB (═1,4-bis[2-[4-[N, N-di(p-tolyl)amino]phenyl]vinyl]benzene), TTB (=N,N,N′,N′-tetra-p-tolyl-4,4′-diaminobiphenyl), TPD (═4,4′-bis[N-3-methylphenyl]-N-phenylamino)biphenyl), N,N,N′,N′-tetraphenyl-4,4′″-diamino-1,1′,4′,1″,4″,1′″-quaterphenyl, and likewise tertiary amines having carbazole units, for example TCTA (═4-(9H-carbazol-9-yl)-N,N-bis[4-(9H-carbazol-9-yl)phenyl]benzeneamine). Likewise preferred are hexaazatriphenylene compounds according to US 2007/0092755 A1 and phthalocyanine derivatives (e.g. H₂Pc, CuPc (═copper phthalocyanine), CoPc, NiPc, ZnPc, PdPc, FePc, MnPc, CIAlPc, CIGaPc, CllnPc, CISnPc, Cl₂SiPc, (HO)AlPc, (HO)GaPc, VOPc, TiOPc, MoOPc, GaPc-O-GaPc).

Particular preference is given to the following triarylamine compounds of the formulae (TA-1) to (TA-6), which are disclosed in documents EP 1162193 B1, EP 650 955 B1, Synth. Metals 1997, 91(1-3), 209, DE 19646119 A1, WO 2006/122630 A1, EP 1 860 097 A1, EP 1834945 A1, JP 08053397 A, U.S. Pat. No. 6,251,531 B, US 2005/0221124, JP 08292586 A, U.S. Pat. No. 7,399,537 B2, US 2006/0061265 A1, EP 1 661 888 and WO 2009/041635. Said compounds of the formulae (TA-1) to (TA-6) may also be substituted:

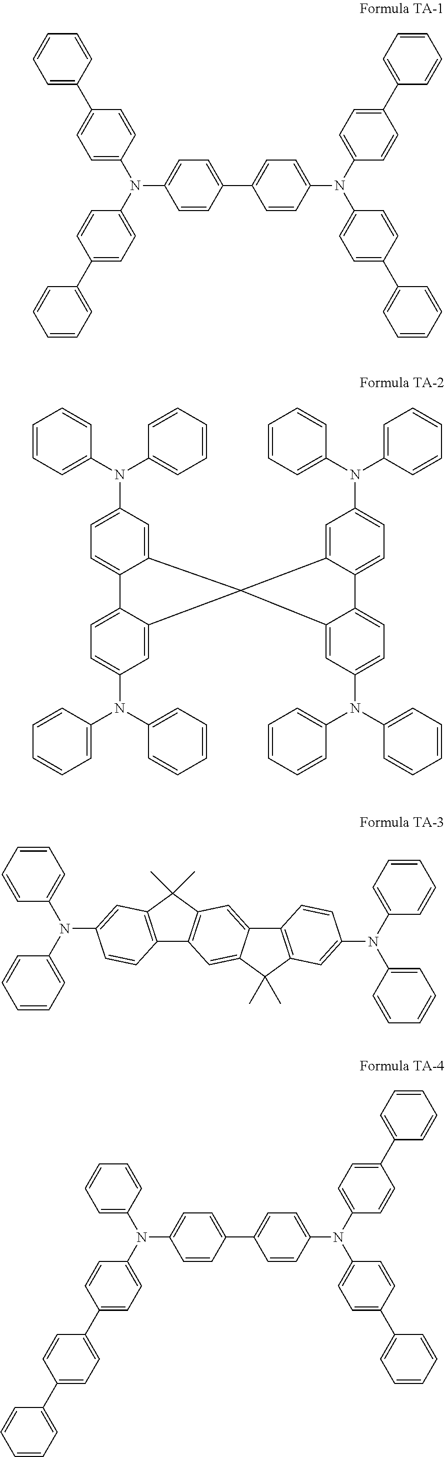 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccccc2)c2ccc3c(c2)C2(c4cc(N(c5ccccc5)c5ccccc5)ccc4-3)c3cc(N(c4ccccc4)c4ccccc4)ccc3-c3ccc(N(c4ccccc4)c4ccccc4)cc32)cc1 ; CC1(C)c2cc(N(c3ccccc3)c3ccccc3)ccc2-c2cc3c(cc21)-c1ccc(N(c2ccccc2)c2ccccc2)cc1C3(C)C ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

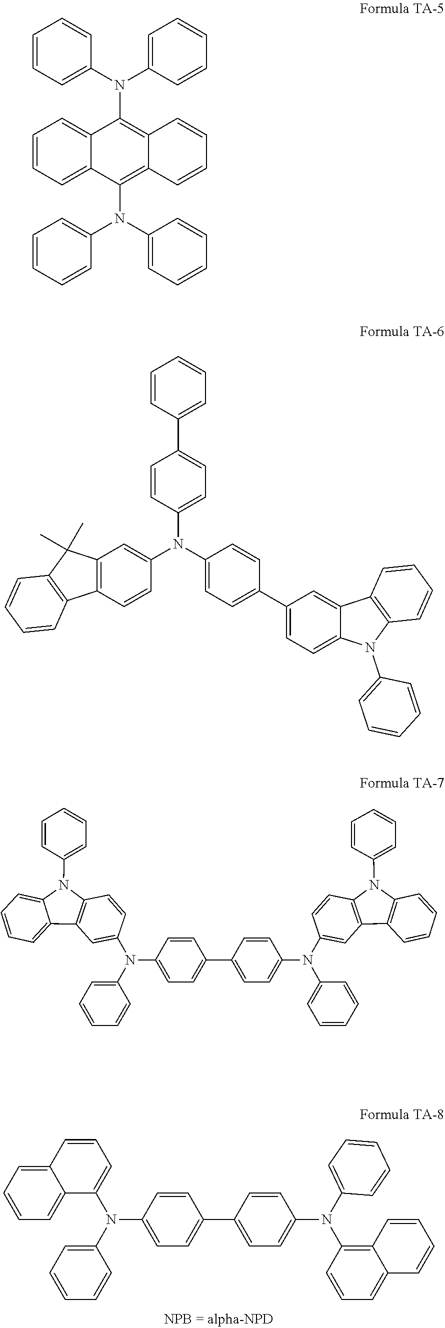 [SMILES: c1ccc(N(c2ccccc2)c2c3ccccc3c(N(c3ccccc3)c3ccccc3)c3ccccc23)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; c1ccc(N(c2ccc(-c3ccc(N(c4ccccc4)c4cccc5ccccc45)cc3)cc2)c2cccc3ccccc23)cc1]

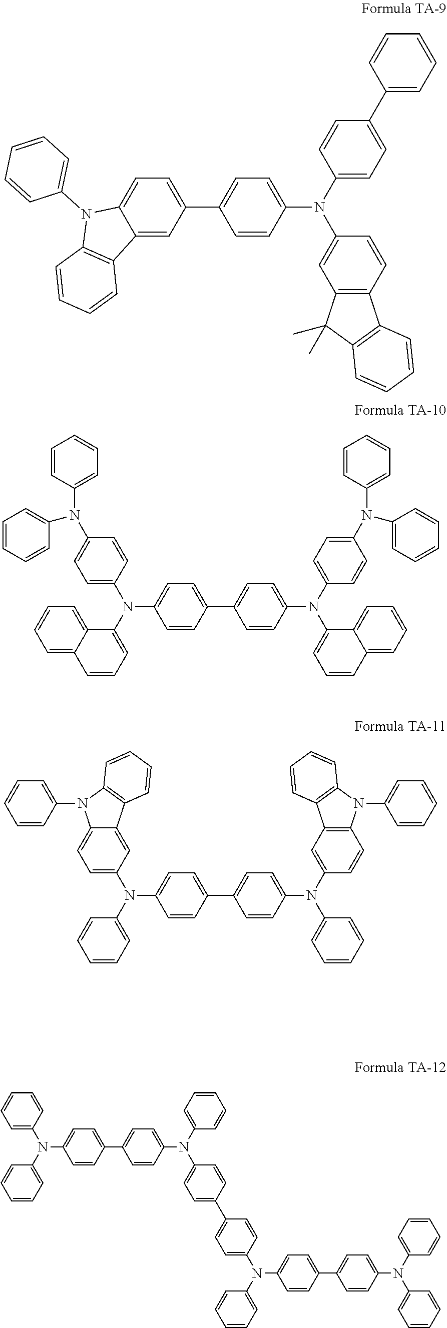 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(N(c2ccccc2)c2ccc(N(c3ccc(-c4ccc(N(c5ccc(N(c6ccccc6)c6ccccc6)cc5)c5cccc6ccccc56)cc4)cc3)c3cccc4ccccc34)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; c1ccc(N(c2ccccc2)c2ccc(-c3ccc(N(c4ccccc4)c4ccc(-c5ccc(N(c6ccccc6)c6ccc(-c7ccc(N(c8ccccc8)c8ccccc8)cc7)cc6)cc5)cc4)cc3)cc2)cc1]

Further compounds, or groups or structural elements, which can be used as hole injection materials are described in EP 0891121 A1 and EP 1029909 A1, and injection layers in general terms in US 2004/0174116 A1,

Preferably, these arylamines and heterocycles, which are generally used as hole injection and/or hole transport materials, lead to a HOMO of more than −5.8 eV (versus vacuum level), more preferably of more than −5.5 eV.

Compounds, or groups or structural elements, having electron injection and/or electron transport properties are, for example, pyridine, pyrimidine, pyridazine, pyrazine, oxadiazole, quinoline, quinoxaline, anthracene, benzanthracene, pyrene, perylene, benzimidazole, triazine, ketone, phosphine oxide and phenazine derivatives, but also triarylboranes and further O-, S- or N-containing heterocycles which a low-lying LUMO (LUMO=lowest unoccupied molecular orbital).

Particularly suitable compounds, or groups or structural elements, for electron-transporting and electron-injecting layers are metal chelates of 8-hydroxyquinoline (e.g. LiQ, AlQ₃, GaQ₃, MgQ₂, ZnQ₂, InQ₃, ZrQ₄), BAlQ, Ga oxinoid complexes, 4-azaphenanthren-5-ol Be complexes (U.S. Pat. No. 5,529,853 A, cf. formula ET-1), butadiene derivatives (U.S. Pat. No. 4,356,429), heterocyclic A, cf. formula ET-1), buatadiene derivatives (U.S. Pat. No. 4,356,429), heterocyclic optical brighteners (U.S. Pat. No. 4,539,507), benzimidazole derivatives (US 2007/0273272 A1), for example TPBI (U.S. Pat. No. 5,766,779, cf. formula ET-2), 1,3,5-triazines, e.g. spirobifluorene-triazine derivatives (for example according to DE 102008064200), pyrenes, anthracenes, tetracenes, fluorenes, spirofluorenes, dendrimers, tetracenes (e.g. rubrene derivatives), 1,10-phenanthroline derivatives (JP 2003-115387, JP 2004-311184, JP-2001-267080, WO 2002/043449), silacyclopentadiene derivatives (EP 1480280, EP 1478032, EP 1469533), borane derivatives, for example triarylborane derivatives with Si (US 2007/0087219 A1, cf. formula ET-3), pyridine derivatives (JP 2004-200162), phenanthrolines, in particular 1,10-phenanthroline derivatives, for example BCP and Bphen, including multiple phenanthrolines joined via biphenyl or other aromatic groups (US-2007-0252517 A1) or phenanthrolines joined by anthracene (US 2007-0122656 A1, cf. formulae ET-4 and ET-5).

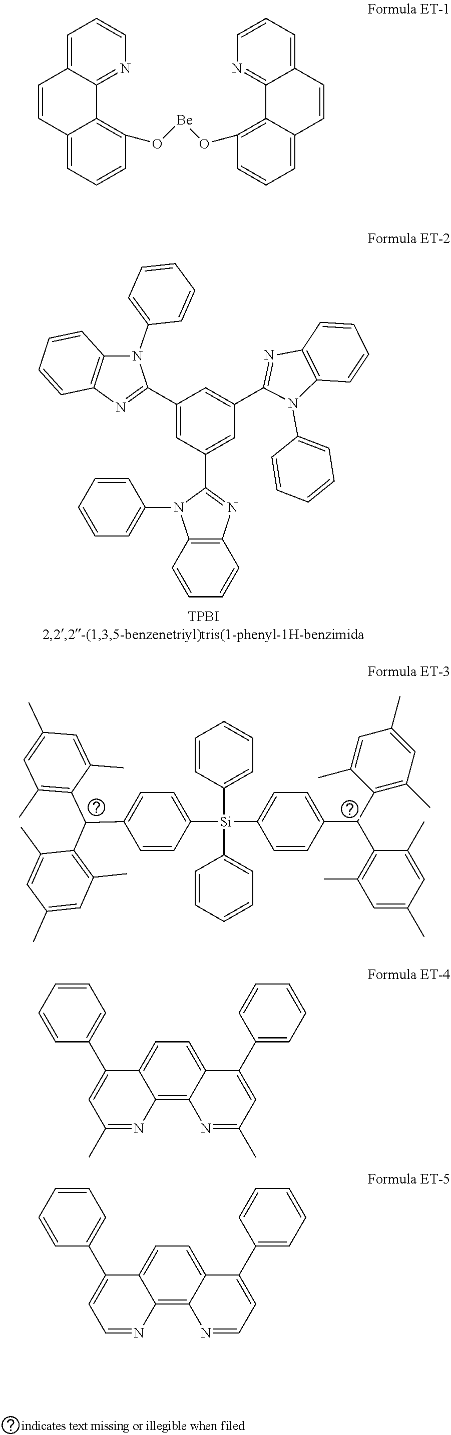

Likewise suitable are heterocyclic organic compounds, or groups or structural elements, for example thiopyran dioxides, oxazoles, triazoles, imidazoles or oxadiazoles. Examples of the use of five-membered rings including N, for example oxazoles, preferably 1,3,4-oxadiazoles, for example compounds of formulae ET-6, ET-7, ET-8 and ET-9, which are detailed inter alia in US 2007/0273272 A1; thiazoles, oxadiazoles, thiadiazoles, triazoles, inter alia, see US 2008/0102311 A1 and Y. A. Levin, M. S. Skorobogatova, Khimiya Geterotsiklicheskikh Soedinenii 1967 (2), 339-341, preferably compounds of formula ET-10, silacyclopentadiene derivatives. Preferred compounds are the following of the formulae (ET-6) to (ET-10):

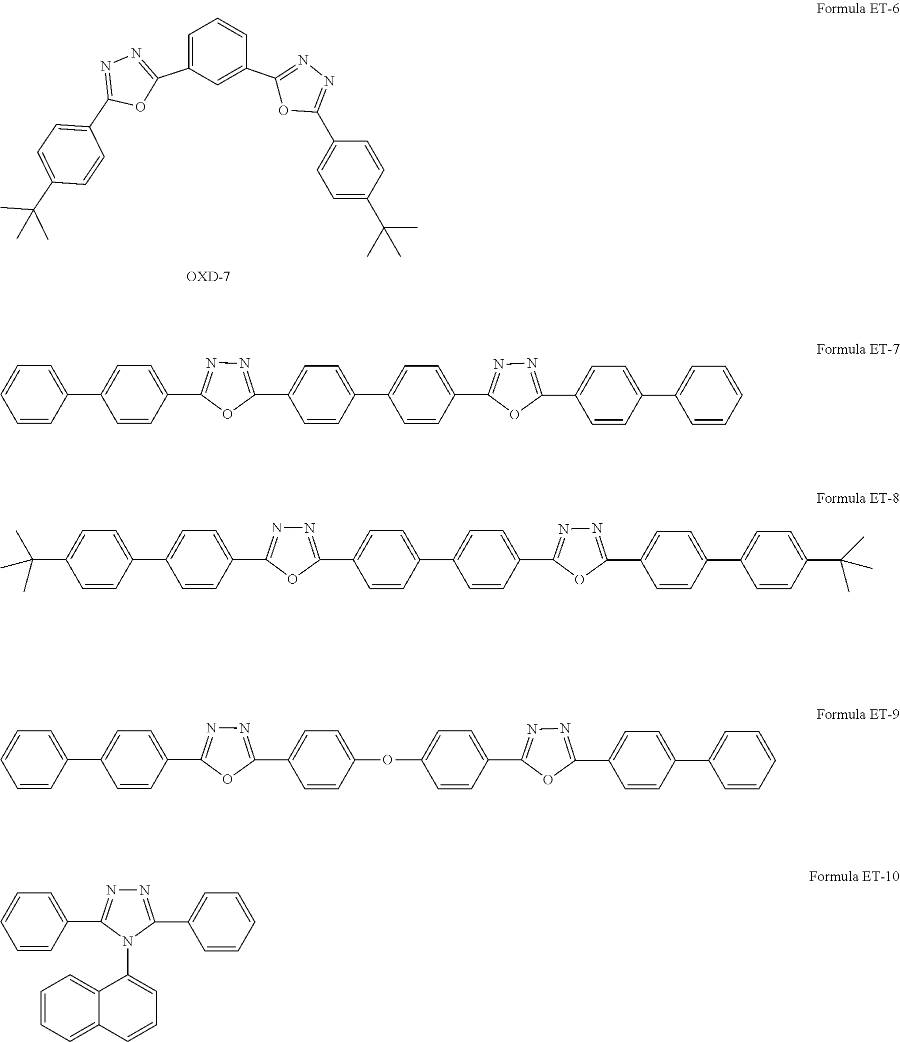 [SMILES: CC(C)(C)c1ccc(-c2nnc(-c3cccc(-c4nnc(-c5ccc(C(C)(C)C)cc5)o4)c3)o2)cc1 ; c1ccc(-c2ccc(-c3nnc(-c4ccc(-c5ccc(-c6nnc(-c7ccc(-c8ccccc8)cc7)o6)cc5)cc4)o3)cc2)cc1 ; CC(C)(C)c1ccc(-c2ccc(-c3nnc(-c4ccc(-c5ccc(-c6nnc(-c7ccc(-c8ccc(C(C)(C)C)cc8)cc7)o6)cc5)cc4)o3)cc2)cc1 ; c1ccc(-c2ccc(-c3nnc(-c4ccc(Oc5ccc(-c6nnc(-c7ccc(-c8ccccc8)cc7)o6)cc5)cc4)o3)cc2)cc1 ; c1ccc(-c2nnc(-c3ccccc3)n2-c2cccc3ccccc23)cc1]

It is also possible to use organic compounds, or groups or structural elements, such as derivatives of fluorenone, fluorenylidenemethane, perylenetetracarbonic acid, anthraquinonedimethane, diphenoquinone, anthrone and anthraquinonediethylenediamine.

Preference is given to 2,9,10-substituted anthracenes (by 1- or 2-naphthyl and 4- or 3-biphenyl) or molecules containing two anthracene units (US2008/0193796 A1, cf. formula ET-11). Also very advantageous is the compound of 9,10-substituted anthracene units with benzimidazole derivatives (US 2006 147747 A and EP 1551206 A1, cf. formulae ET-12 and ET-13).

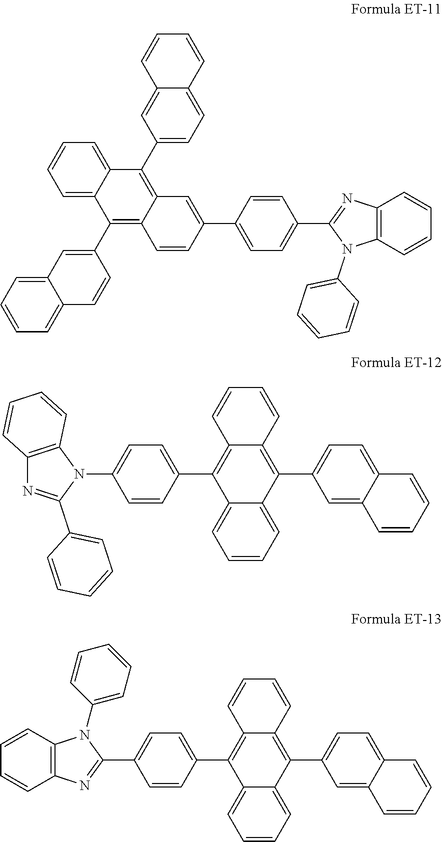 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2nc3ccccc3n2-c2ccc(-c3c4ccccc4c(-c4ccc5ccccc5c4)c4ccccc34)cc2)cc1 ; c1ccc(-n2c(-c3ccc(-c4c5ccccc5c(-c5ccc6ccccc6c5)c5ccccc45)cc3)nc3ccccc32)cc1]

Preferably, the compounds, or groups or structural elements, that can generate the electron injection and/or electron transport properties lead to a LUMO of less than −2.5 eV (versus vacuum level), more preferably of less than −2.7 eV.

The mixtures of the present invention may comprise emitters, in which case the compounds OSM1 and OSM2 usable in accordance with the invention may be configured as emitters. The term “emitter” refers to a material which, after excitation, which can be effected by transfer of any kind of energy, allows a radiative transition with emission of light to a ground state. In general, there are two known classes of emitters: fluorescent and phosphorescent emitters. The term “fluorescent emitter” refers to materials or compounds where there is a radiative transition from an excited singlet state to the ground state. The term “phosphorescent emitter” refers preferably to luminescent materials or compounds comprising transition metals.

Emitters are frequently also referred to as dopants if the dopants cause the properties detailed above in a system. A dopant in a system comprising a matrix material and a dopant is understood to mean that component having the smaller proportion in the mixture. Correspondingly, a matrix material in a system comprising a matrix material and a dopant is understood to mean that component having the greater proportion in the mixture. The term “phosphorescent emitter” can accordingly, for example, also be understood to mean phosphorescent dopants.

Compounds, or groups or structural elements, which can emit light include fluorescent emitters and phosphorescent emitters. These include compounds having stilbene, stilbeneamine, styrylamine, coumarin, rubrene, rhodamine, thiazole, thiadiazole, cyanine, thiophene, paraphenylene, perylene, phthalocyanine, porphyrin, ketone, quinoline, imine, anthracene and/or pyrene structures. Particular preference is given to compounds which can emit light with high efficiency from the triplet state even at room temperature, i.e. exhibit electrophosphorescence rather than electrofluorescence, which frequently brings about an increase in energy efficiency. Suitable for this purpose, first of all, are compounds containing heavy atoms having an atomic number of more than 36. Preferred compounds are those which contain d or f transition metals, which fulfil the abovementioned condition. Particular preference is given here to corresponding compounds containing elements of groups 8 to 10 (Ru, Os, Rh, Ir, Pd, Pt). Useful functional compounds here include, for example, various complexes as described, for example, in WO 02/068435 A1, WO 02/081488 A1, EP 1239526 A2 and WO 04/026886 A2.

Detailed hereinafter by way of example are preferred compounds which can serve as fluorescent emitters. Preferred fluorescent emitters are selected from the class of the monostyrylamines, the distyrylamines, the tristyrylamines, the tetrastyrylamines, the styrylphosphines, the styryl ethers and the arylamines.

A monostyrylamine is understood to mean a compound containing one substituted or unsubstituted styryl group and at least one preferably aromatic amine. A distyrylamine is understood to mean a compound containing two substituted or unsubstituted styryl groups and at least one preferably aromatic amine. A tristyrylamine is understood to mean a compound containing three substituted or unsubstituted styryl groups and at least one preferably aromatic amine. A tetrastyrylamine is understood to mean a compound containing four substituted or unsubstituted styryl groups and at least one preferably aromatic amine. The styryl groups are more preferably stilbenes which may also have still further substitution. Corresponding phosphines and ethers are defined in analogy to the amines. An arylamine or an aromatic amine in the context of the present invention is understood to mean a compound containing three substituted or unsubstituted aromatic or heteroaromatic ring systems bonded directly to the nitrogen. Preferably, at least one of these aromatic or heteroaromatic ring systems is a fused ring system, preferably having at least 14 aromatic ring atoms. Preferred examples of these are aromatic anthraceneamines, aromatic anthracenediamines, aromatic pyreneamines, aromatic pyrenediamines, aromatic chryseneamines or aromatic chrysenediamines. An aromatic anthraceneamine is understood to mean a compound in which a diarylamino group is bonded directly to an anthracene group, preferably in the 9 position. An aromatic anthracenediamine is understood to mean a compound in which two diarylamino groups are bonded directly to an anthracene group, preferably in the 2,6 or 9,10 positions. Aromatic pyreneamines, pyrenediamines, chryseneamines and chrysenediamines are defined analogously thereto, where the diarylamino groups are bonded to the pyrene preferably in the 1 position or 1,6 positions.

Further preferred fluorescent emitters are selected from indenofluoreneamines or -diamines detailed inter alia in document WO 06/122630; benzoindenofluoreneamines or -diamines detailed inter alia in document WO 2008/006449; and dibenzoindenofluoreneamines or -diamines detailed inter alia in document WO 2007/140847.

Examples of compounds, or groups or structural elements, which can be used as fluorescent emitters from the class of the styrylamines are substituted or unsubstituted tristilbeneamines or the dopants described in WO 06/000388, WO 06/058737, WO 06/000389, WO 07/065549 and WO 07/115610. Distyrylbenzene and distyrylbiphenyl derivatives are described in U.S. Pat. No. 5,121,029. Further styrylamines are to be found in US 2007/0122656 A1.

Particularly preferred styrylamine compounds are the compounds of the formula EM-1 described in U.S. Pat. No. 7,250,532 B2 and the compounds of the formula EM-2 detailed in DE 10 2005 058557 A1:

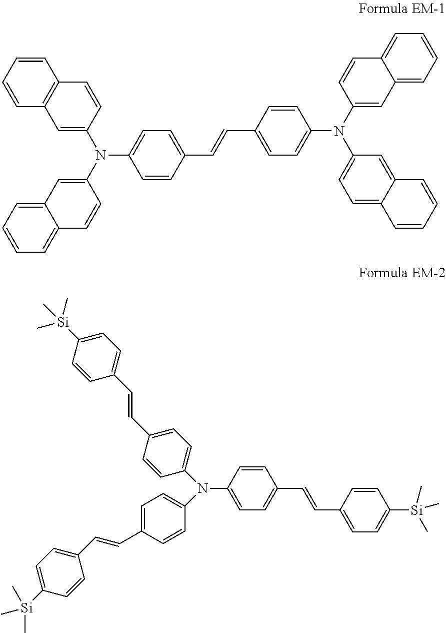

Particularly preferred triarylamine compounds, or groups or structural elements, are the compounds of the formulae EM-3 to EM-15 detailed in documents CN 1583691 A, JP 08/053397 A and U.S. Pat. No. 6,251,531 B1, EP 1957606 A1, US 2008/0113101 A1, US 2006/210830 A, WO 08/006449 and DE 102008035413 and the derivatives thereof:

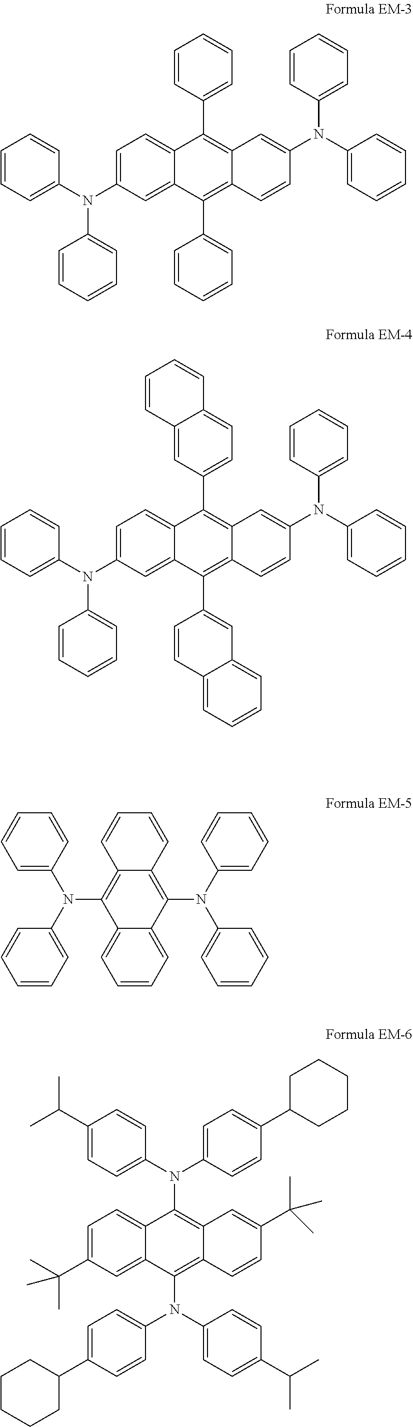 [SMILES: c1ccc(-c2c3ccc(N(c4ccccc4)c4ccccc4)cc3c(-c3ccccc3)c3ccc(N(c4ccccc4)c4ccccc4)cc23)cc1 ; c1ccc(N(c2ccccc2)c2ccc3c(-c4ccc5ccccc5c4)c4cc(N(c5ccccc5)c5ccccc5)ccc4c(-c4ccc5ccccc5c4)c3c2)cc1 ; c1ccc(N(c2ccccc2)c2c3ccccc3c(N(c3ccccc3)c3ccccc3)c3ccccc23)cc1 ; CC(C)c1ccc(N(c2ccc(C3CCCCC3)cc2)c2c3ccc(C(C)(C)C)cc3c(N(c3ccc(C(C)C)cc3)c3ccc(C4CCCCC4)cc3)c3ccc(C(C)(C)C)cc23)cc1]

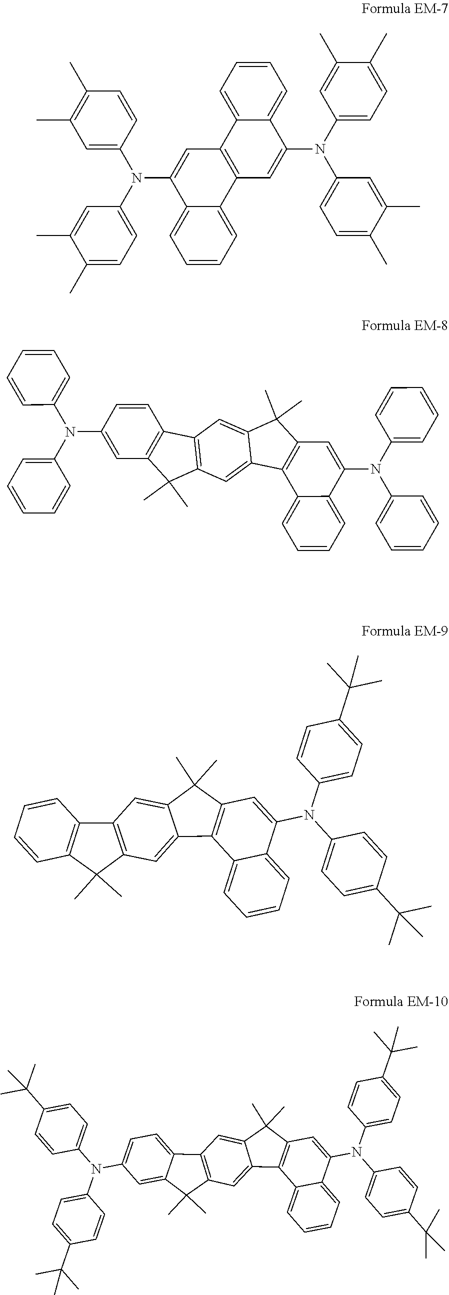

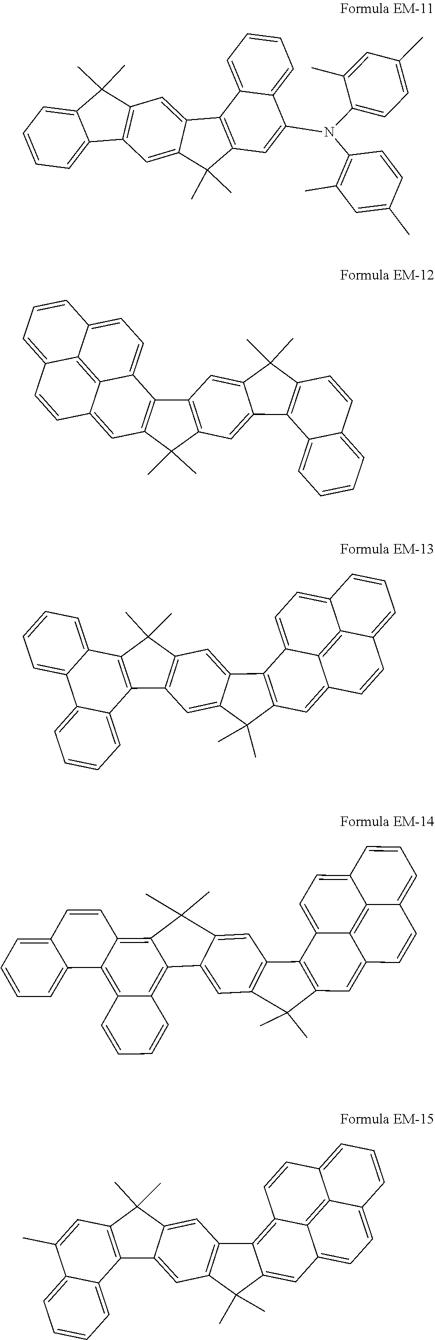

Further preferred compounds, or groups or structural elements, which can be used as fluorescent emitters are selected from derivatives of naphthalene, anthracene, tetracene, benzanthracene, benzophenanthrene (DE 10 2009 005746), fluorene, fluoranthene, periflanthene, indenoperylene, phenanthrene, perylene (US 2007/0252517 A1), pyrene, chrysene, decacyclene, coronene, tetraphenylcyclopentadiene, pentaphenylcyclopentadiene, fluorene, spirofluorene, rubrene, coumarin (U.S. Pat. Nos. 4,769,292, 6,020,078, US 2007/0252517 A1), pyran, oxazole, benzoxazole, benzothiazole, benzimidazole, pyrazine, cinnamic esters, diketopyrrolopyrrole, acridone and quinacridone (US 2007/0252517 A1).

Among the anthracene compounds, particular preference is given to anthracenes substituted in the 9,10 positions, for example 9,10-diphenylanthracene and 9,10-bis(phenylethynyl)anthracene. 1,4-Bis(9′-ethynylanthracenyl)benzene is also a preferred dopant.

Likewise preferred are derivatives of rubrene, coumarin, rhodamine, quinacridone, for example DMQA (=N,N′-dimethylquinacridone), dicyanomethylenepyran, for example DCM (═4-(dicyanoethylene)-6-(4-dimethylamino-styryl-2-methyl)-4H-pyran), thiopyran, polymethine, pyrylium and thiapyrylium salts, periflanthene and indenoperylene.

Blue fluorescence emitters are preferably polyaromatics, for example 9,10-di(2-naphthylanthracene) and other anthracene derivatives, derivatives of tetracene, xanthene, perylene, for example 2,5,8,11-tetra-t-butyl-perylene, phenylene, e.g. 4,4′-(bis(9-ethyl-3-carbazovinylene)-1,1′-biphenyl, fluorene, fluoranthene, arylpyrenes (US 2006/0222886 A1), arylenevinylenes (U.S. Pat. Nos. 5,121,029, 5,130,603), bis(azinyl)imineboron compounds (US 2007/0092753 A1), bis(azinyl)methene compounds and carbostyryl compounds.

Further preferred blue fluorescence emitters are described in C. H. Chen et al.: “Recent developments in organic electroluminescent materials” Macromol. Symp. 125, (1997), 1-48 and “Recent progress of molecular organic electroluminescent materials and devices” Mat. Sci. and Eng. R, 39 (2002), 143-222.

Further preferred blue-fluorescing emitters are the hydrocarbons disclosed in DE 102008035413. Particular preference is further given to the compounds detailed in WO 2014/111269, especially compounds having a bis(indenofluorene) base skeleton. The above-cited documents DE 102008035413 and WO 2014/111269 A2 are incorporated into the present application by reference for the purposes of disclosure.

Detailed hereinafter by way of example are preferred compounds, or groups or structural elements, which can serve as phosphorescent emitters.

Examples of phosphorescent emitters can be found in WO 00/70655, WO 01/41512, WO 02/02714, WO 02/15645, EP 1191613, EP 1191612, EP 1191614 and WO 05/033244. In general, all phosphorescent complexes as used for phosphorescent OLEDs according to the prior art and as known to those skilled in the art in the field of organic electroluminescence are suitable, and the person skilled in the art will be able to use further phosphorescent complexes without exercising inventive skill.

Phosphorescent metal complexes preferably contain Ir, Ru, Pd, Pt, Os or Re.

Preferred ligands are 2-phenylpyridine derivatives, 7,8-benzoquinoline derivatives, 2-(2-thienyl)pyridine derivatives, 2-(1-naphthyl)pyridine derivatives, 1-phenylisoquinoline derivatives, 3-phenylisoquinoline derivatives or 2-phenylquinoline derivatives. All these compounds may be substituted, for example for blue by fluorine, cyano and/or trifluoromethyl substituents. Auxiliary ligands are preferably acetylacetonate or picolinic acid.

Especially suitable as emitters are complexes of Pt or Pd with tetradentate ligands of formula EM-16.

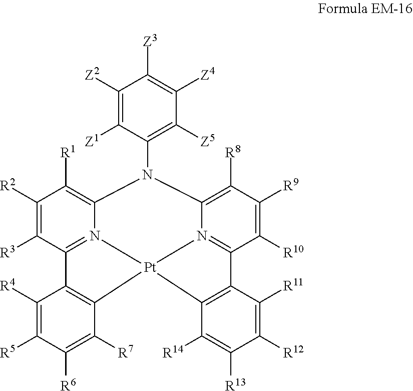

The compounds of formula EM-16 are described in more detail in US 2007/0087219 A1, reference being made to this document for the purposes of disclosure for elucidation of the substituents and indices in the above formula.

Additionally suitable are Pt-porphyrin complexes having an enlarged ring system (US 2009/0061681 A1) and Ir complexes, for example 2,3,7,8,12,13,17,18-octaethyl-21H,23H-porphyrin-Pt(II), tetraphenyl-Pt(I)-tetrabenzoporphyrin (US 2009/0061681 A1), cis-bis(2-phenylpyridinato-N,C^{2′})Pt(II), cis-bis(2-(2′-thienyl)pyridinato-N,C^{3′})Pt(II), cis-bis(2-(2′-thienyl)quinolinato-N,C^{5′})Pt(III), (2-(4,6-difluorophenyl)pyridinato-N,C^{2′})Pt(II) acetylacetonate or tris(2-phenylpyridinato-N,C^{2′})Ir(III) (=Ir(ppy)₃, green), bis(2-phenylpyridinato-N,C²)Ir(II) acetylacetonate (=Ir(ppy)₂ acetylacetonate, green, US 2001/0053462 A1, Baldo, Thompson et al. Nature 403, (2000), 750-753), bis(1-phenylisoquinolinato-N,C^{2′})(2-phenylpyridinato-N,C^{2′})iridium(III), bis(2-phenylpyridinato-N,C^{2′})(1-phenylisoquinolinato-N,C^{2′})iridium(IIII), bis(2-(2′-benzothienyl)pyridinato-N,C^{3′})iridium(III) acetylacetonate, bis(2-(4′,6′-difluorophenyl)pyridinato-N,C^{2′})iridium(III) picolinate (Flrpic, blue), bis(2-(4′,6′-difluorophenyl)pyridinato-N,C^{2′})Ir(III) tetrakis(1-pyrazolyl)borate, tris(2-(biphenyl-3-yl)-4-tert-butylpyridine)iridium(III), (ppz)₂Ir(5phdpym) (US 2009/0061681 A1), (45ooppz)₂Ir(5phdpym) (US 2009/0061681 A1), derivatives of 2-phenylpyridine-Ir complexes, for example PQIr (═iridium(III) bis(2-phenylquinolyl-N,C^{2′}) acetylacetonate), tris(2-phenylisoquinolinato-N,C)Ir(IIII) (red), bis(2-(2′-benzo[4,5-a]thienyl)pyridinato-N,C³)Ir acetylacetonate ([Btp₂Ir(acac)], red, Adachi et al. Appl. Phys. Lett. 78 (2001), 1622-1624). Also particularly suitable are the complexes detailed in WO 2016/124304. The above-cited documents, especially WO 2016/124304 A1, are incorporated into the present application by reference for the purposes of disclosure.

Likewise suitable are complexes of trivalent lanthanides, for example Tb³⁺ and Eu³⁺ (J. Kido et al. Appl. Phys. Lett. 65 (1994), 2124, Kido et al. Chem. Lett. 657, 1990, US 2007/0252517 A1) or phosphorescent complexes of Pt(II), Ir(I), Rh(I) with maleonitrile dithiolate (Johnson et al., JACS 105, 1983, 1795), Re(i)-tricarbonyldiimine complexes (inter alia Wrighton, JACS 96, 1974, 998), Os(II) complexes with cyano ligands and bipyridyl or phenanthroline ligands (Ma et al., Synth. Metals 94, 1998, 245).

Further phosphorescent emitters having tridentate ligands are described in U.S. Pat. No. 6,824,895 and U.S. Ser. No. 10/729,238. Red-emitting phosphorescent complexes are disclosed in U.S. Pat. Nos. 6,835,469 and 6,830,828.

Particularly preferred compounds, or groups or structural elements, which can be used as phosphorescent dopants include the compounds of formula EM-17 described in US 2001/0053462 A1 and Inorg. Chem. 2001, 40(7), 1704-1711, JACS 2001, 123(18), 4304-4312 and derivatives thereof.

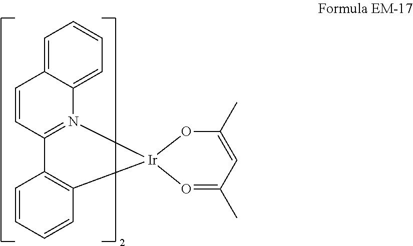

Derivatives are described in U.S. Pat. No. 7,378,162 B2, U.S. Pat. No. 6,835,469 B2 and JP 2003/253145 A.

In addition, it is possible to use the compounds of formulae EM-18 to EM-21 described in U.S. Pat. No. 7,238,437 B2, US 2009/008607 A1 and EP 1348711 and derivatives thereof as emitters.

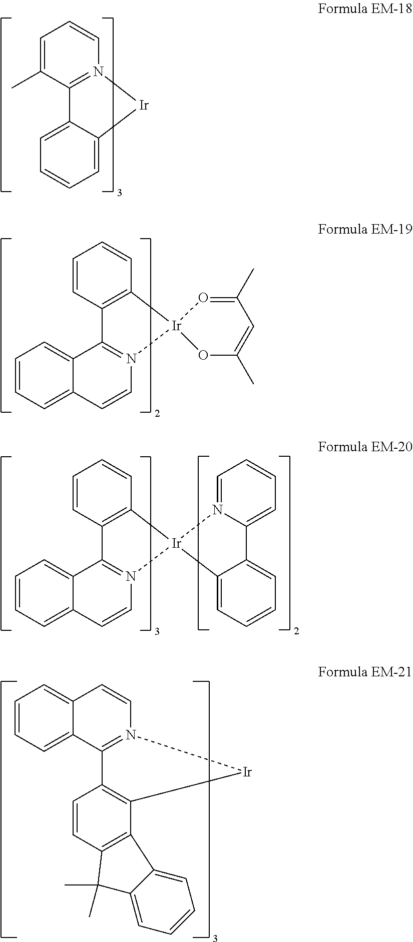

Quantum dots can likewise be used as emitters, these materials being disclosed in detail in WO 2011/076314 A1.

Compounds, or groups or structural elements, which are used as host materials, especially together with emitting compounds, include materials of various classes.

Host materials generally have greater band gaps between the HOMO and LUMO than the emitter materials used. In addition, preferred host materials exhibit properties either of a hole or electron transport material. Moreover, host materials may have either electron or hole transport properties.

Host materials are in some cases also referred to as matrix material, especially if the host material is used in combination with a phosphorescent emitter in an OLED.

Preferred host materials or co-host materials which are especially used together with fluorescent dopants are selected from the classes of the oligoarylenes (e.g. 2,2′,7,7′-tetraphenylspirobifluorene according to EP 676461 or dinaphthylanthracene), especially of the oligoarylenes containing fused aromatic groups, for example anthracene, benzanthracene, benzophenanthrene (DE 10 2009 005746, WO 09/069566), phenanthrene, tetracene, coronene, chrysene, fluorene, spirobifluorene, perylene, phthaloperylene, naphthaloperylene, decacyclene, rubrene, the oligoarylenevinylenes (e.g. DPVBi=4,4′-bis(2,2-diphenylethenyl)-1,1′-biphenyl or spiro-DPVBi according to EP 676461), the polypodal metal complexes (for example according to WO 04/081017), especially metal complexes of 8-hydroxyquinoline, e.g. AlQ₃ (═aluminium(III) tris(8-hydroxyquinoline)) or bis(2-methyl-8-quinolinolato)-4-(phenylphenolinolato)aluminium, including with imidazole chelate (US 2007/0092753 A1), and the quinoline-metal complexes, aminoquinoline metal complexes, benzoquinoline metal complexes, the hole-conducting compounds (for example according to WO 04/058911), the electron-conducting compounds, especially ketones, phosphine oxides, sulfoxides, carbazoles, spiro-carbazoles, indenocarbazoles, etc. (for example according to WO 05/084081 and WO 05/084082), the atropisomers (for example according to WO 06/048268), the boronic acid derivatives (for example according to WO 06/117052) or the benzanthracenes (for example according to WO 08/145239).

Particularly preferred compounds, or groups or structural elements, which can serve as host materials or co-host materials are selected from the classes of the oligoarylenes containing anthracene, benzanthracene and/or pyrene or atropisomers of these compounds. An oligoarylene in the context of the present invention shall be understood to mean a compound in which at least three aryl or arylene groups are bonded to one another.

Preferred host materials are especially selected from compounds of the formula (H-100)

Ar⁵—(Ar⁶)ₚ—Ar⁷ (H-100)

where Ar⁵, Ar⁶, Ar⁷ is the same or different at each instance and is an aryl or heteroaryl group which has 5 to 30 aromatic ring atoms and may optionally be substituted, and p is an integer in the range from 1 to 5; at the same time, the sum of the r electrons in Ar⁵, Ar⁶ and Ar⁷ is at least 30 when p=1, and is at least 36 when p=2, and is at least 42 when p=3.

More preferably, in the compounds of the formula (H-100), the Ar⁶ group is anthracene and the Ar⁵ and Ar⁷ groups are bonded in the 9 and 10 positions, where these groups may optionally be substituted. Most preferably, at least one of the Ar⁵ and/or Ar⁷ groups is a fused aryl group selected from 1- or 2-naphthyl, 2-, 3- or 9-phenanthrenyl or 2-, 3-, 4-, 5-, 6- or 7-benzanthracenyl. Anthracene-based compounds are described in US 2007/0092753 A1 and US 2007/0252517 A1, for example 2-(4-methylphenyl)-9,10-di(2-naphthyl)anthracene, 9-(2-naphthyl)-10-(1,1′-biphenyl)anthracene and 9,10-bis[4-(2,2-diphenylethenyl)phenyl]anthracene, 9,10-diphenylanthracene, 9,10-bis(phenylethynyl)anthracene and 1,4-bis(9′-ethynylanthracenyl)benzene. Preference is also given to compounds having two anthracene units (US 2008/0193796 A1), e.g. 10,10′-bis[1,1′,4′,1″]terphenyl-2-yl-9,9′-bisanthracenyl.

Further preferred compounds are derivatives of arylamine, styrylamine, fluorescein, diphenylbutadiene, tetraphenylbutadiene, cyclopentadienes, tetraphenylcyclopentadiene, pentaphenylcyclopentadiene, coumarin, oxadiazole, bisbenzoxazoline, oxazole, pyridine, pyrazine, imine, benzothiazole, benzoxazole, benzimidazole (US 2007/0092753 A1), e.g. 2,2′,2″-(1,3,5-phenylene)tris[1-phenyl-1H-benzimidazole], aldazine, stilbene, styrylarylene derivatives, e.g. 9,10-bis[4-(2,2-diphenylethenyl)phenyl]anthracene and distyrylarylene derivatives (U.S. Pat. No. 5,121,029), diphenylethylene, vinylanthracene, diaminocarbazole, pyran, thiopyran, diketopyrrolopyrrole, polymethine, cinnamic esters and fluorescent dyes.

Particular preference is given to derivatives of arylamine and styrylamine, e.g. TNB (═4,4′-bis[N-(1-naphthyl)-N-(2-naphthyl)amino]biphenyl). Metal oxinoid complexes such as LiQ or AlQ₃ can be used as co-hosts.

Preferred compounds, or groups or structural elements, with oligoarylene as the matrix are detailed in US 2003/0027016 A1, U.S. Pat. No. 7,326,371 B2, US 2006/043858 A, WO 2007/114358, WO 08/145239, JP 3148176 B2, EP 1009044, US 2004/018383, WO 2005/061656 A1, EP 0681019B1, WO 2004/013073A1, U.S. Pat. No. 5,077,142, WO 2007/065678 and DE 102009005746, particularly preferred compounds being described by the formulae H-102 to H-108.

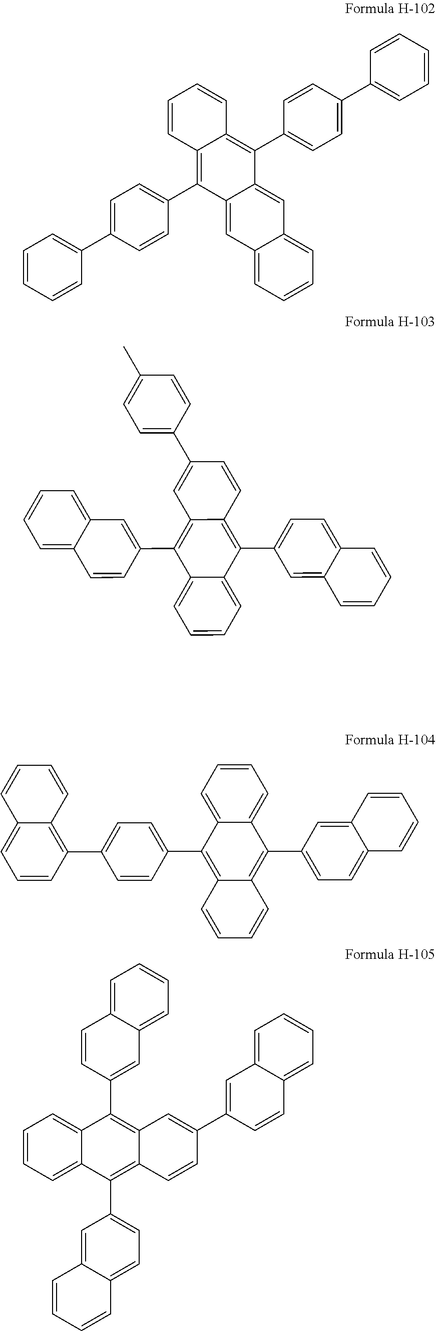

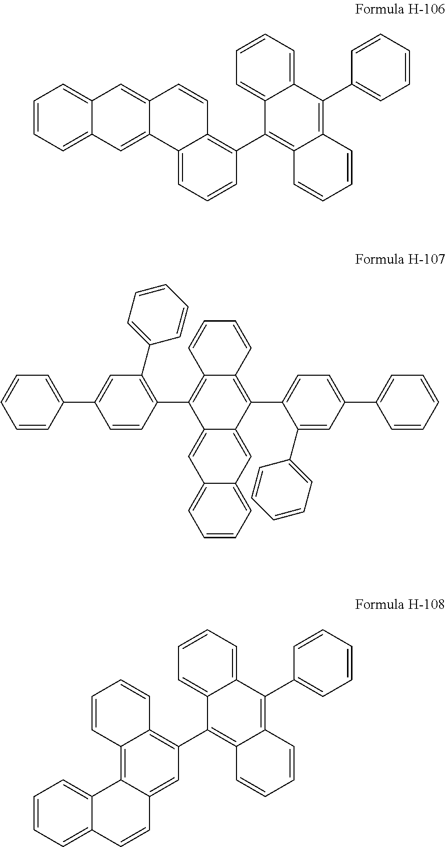

In addition, compounds, or groups or structural elements, which can be used as host or matrix include materials which are used together with phosphorescent emitters. These compounds, or groups or structural elements, which can also be used as structural elements in polymers, include CBP (N,N-biscarbazolylbiphenyl), carbazole derivatives (for example according to WO 05/039246, US 2005/0069729, JP 2004/288381, EP 1205527 or WO 08/086851), azacarbazoles (for example according to EP 1617710, EP 1617711, EP 1731584 or JP 2005/347160), ketones (for example according to WO 04/093207 or according to DE 102008033943), phosphine oxides, sulfoxides and sulfones (for example according to WO 05/003253), oligophenylenes, aromatic amines (for example according to US 2005/0069729), bipolar matrix materials (for example according to WO 07/137725), silanes (for example according to WO 05/111172), 9,9-diarylfluorene derivatives (for example according to DE 102008017591), azaboroles or boronic esters (for example according to WO 06/117052), triazine derivatives (for example according to DE 102008036982), indolocarbazole derivatives (for example according to WO 07/063754 or WO 08/056746), indenocarbazole derivatives (for example according to DE 102009023155 and DE 102009031021), diazaphosphole derivatives (for example according to DE 102009022858), triazole derivatives, oxazoles and oxazole derivatives, imidazole derivatives, polyarylalkane derivatives, pyrazoline derivatives, pyrazolone derivatives, distyrylpyrazine derivatives, thiopyran dioxide derivatives, phenylenediamine derivatives, tertiary aromatic amines, styrylamines, amino-substituted chalcone derivatives, indoles, hydrazone derivatives, stilbene derivatives, silazane derivatives, aromatic dimethylidene compounds, carbodiimide derivatives, metal complexes of 8-hydroxyquinoline derivatives, for example AlQ₃, the 8-hydroxyquinoline complexes may also contain triarylaminophenol ligands (US 2007/0134514 A1), metal complex polysilane compounds and thiophene, benzothiophene and dibenzothiophene derivatives.

Examples of preferred carbazole derivatives are mCP (═1,3-N,N-dicarbazolebenzene (═9,9′-(1,3-phenylene)bis-9H-carbazole)) (formula H-9), CDBP (═9,9′-(2,2′-dimethyl[1,1′-biphenyl]-4,4′-diyl)bis-9H-carbazole), 1,3-bis(N,N′-dicarbazole)benzene (═1,3-bis(carbazol-9-yl)benzene), PVK (polyvinylcarbazole), 3,5-di(9H-carbazol-9-yl)biphenyl and CMTTP (formula H10). Particularly preferred compounds are detailed in US 2007/0128467 A1 and US 2005/0249976 A1 (formulae H-111 to H-113).

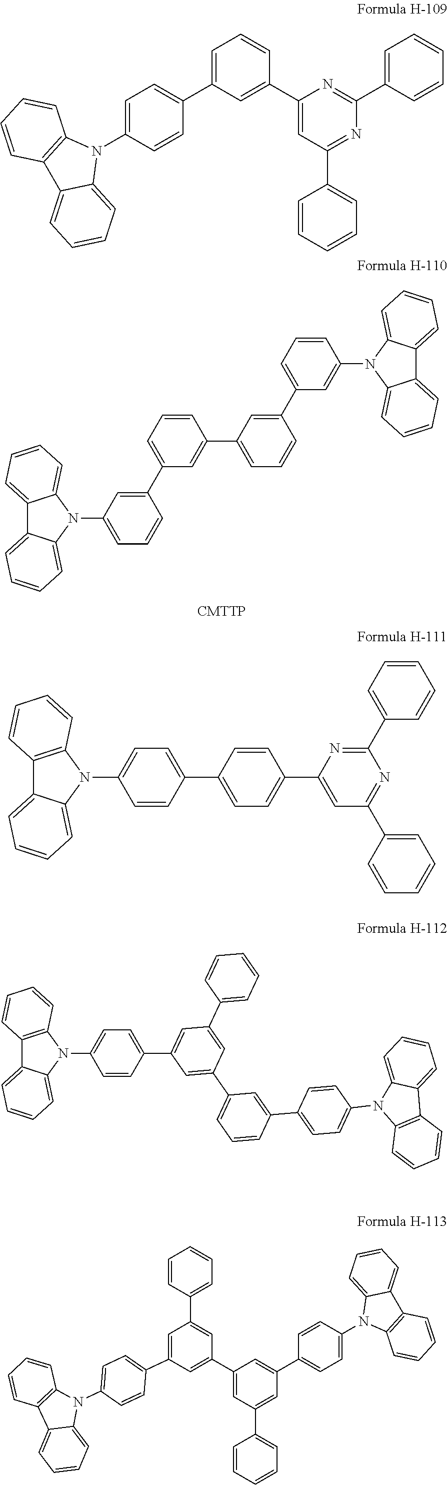 [SMILES: c1ccc(-c2cc(-c3cccc(-c4ccc(-n5c6ccccc6c6ccccc65)cc4)c3)nc(-c3ccccc3)n2)cc1 ; c1cc(-c2cccc(-c3cccc(-n4c5ccccc5c5ccccc54)c3)c2)cc(-c2cccc(-n3c4ccccc4c4ccccc43)c2)c1 ; c1ccc(-c2cc(-c3ccc(-c4ccc(-n5c6ccccc6c6ccccc65)cc4)cc3)nc(-c3ccccc3)n2)cc1 ; c1ccc(-c2cc(-c3ccc(-n4c5ccccc5c5ccccc54)cc3)cc(-c3cccc(-c4ccc(-n5c6ccccc6c6ccccc65)cc4)c3)c2)cc1 ; c1ccc(-c2cc(-c3ccc(-n4c5ccccc5c5ccccc54)cc3)cc(-c3cc(-c4ccccc4)cc(-c4ccc(-n5c6ccccc6c6ccccc65)cc4)c3)c2)cc1]

Preferred Si-tetraaryls are detailed, for example, in documents US 2004/0209115, US 2004/0209116, US 2007/0087219 A1 and in H. Gilman, E. A. Zuech, Chemistry & Industry (London, United Kingdom), 1960, 120. Particularly preferred Si-tetraaryls are described by the formulae H-114 to H-120.

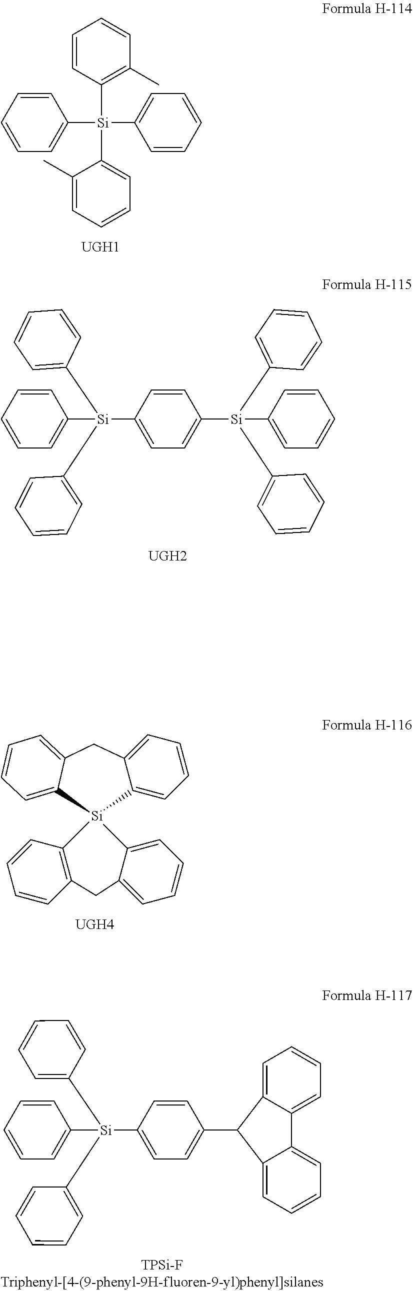

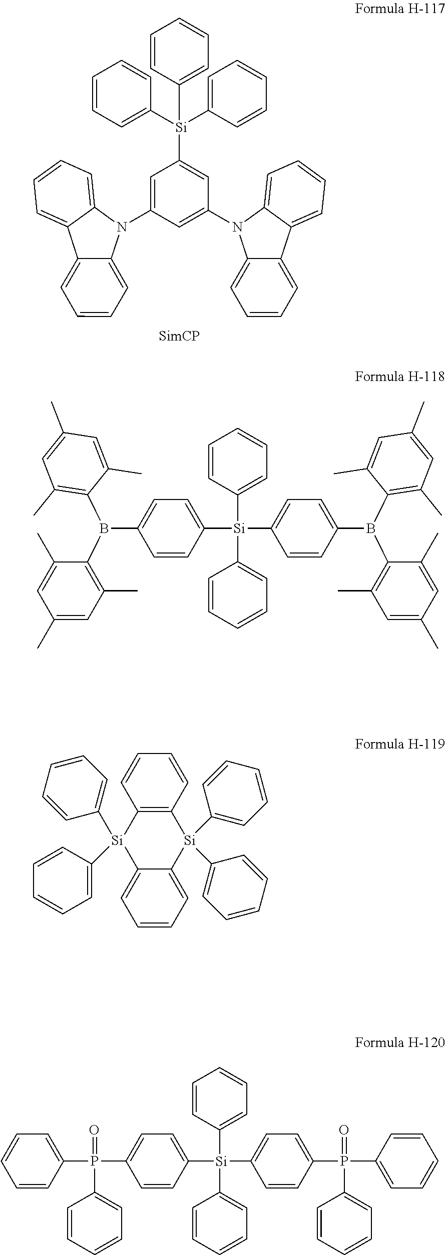

Particularly preferred compounds, or groups or structural elements, for production of the matrix for phosphorescent dopants are detailed inter alia in DE 102009022858, DE 102009023155, EP 652273 B1, WO 07/063754 and WO 08/056746, particularly preferred compounds being described by the formulae H-121 to H-124.

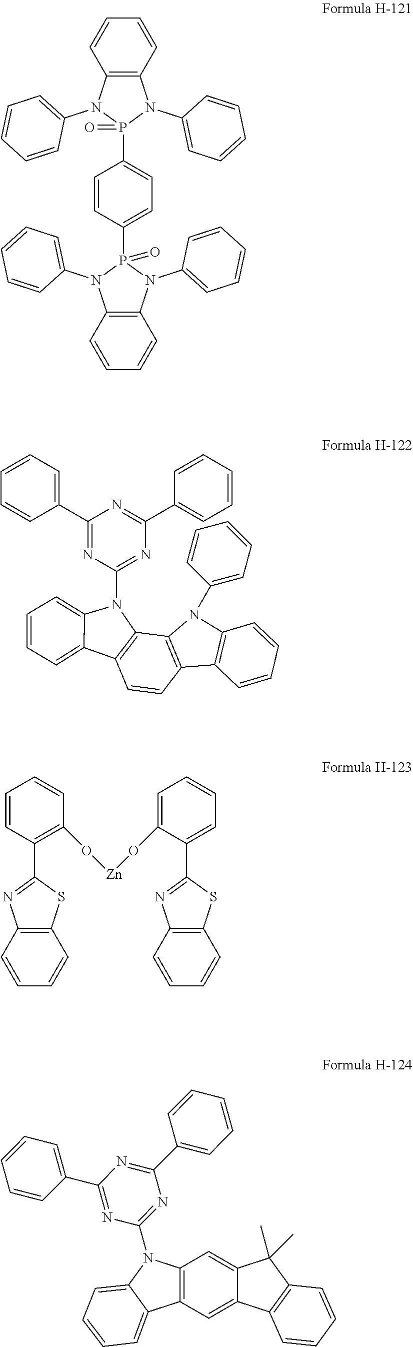

With regard to the functional compounds, or groups or structural elements, usable in accordance with the invention that can serve as host material, preference is given especially to substances having at least one nitrogen atom. These preferably include aromatic amines, triazine derivatives and carbazole derivatives. For instance, carbazole derivatives in particular exhibit a surprisingly high efficiency. Triazine derivatives unexpectedly lead to long lifetimes of the electronic devices comprising the compounds mentioned.

It may also be preferable to use a plurality of different matrix materials as a mixture, especially at least one electron-conducting matrix material and at least one hole-conducting matrix material. Preference is likewise given to the use of a mixture of a charge-transporting matrix material and an electrically inert matrix material having no significant involvement, if any, in the charge transport, as described, for example, in WO 2010/108579.

In addition, it is possible to use compounds, or groups or structural elements, which improve the transition from the singlet to the triplet state and which, used in support of the functional compounds having emitter properties, improve the phosphorescence properties of these compounds. Useful units for this purpose are especially carbazole and bridged carbazole dimer units, as described, for example, in WO 04/70772 A2 and WO 04/113468 A1. Additionally useful for this purpose are ketones, phosphine oxides, sulfoxides, sulfones, silane derivatives and similar compounds, as described, for example, in WO 05/040302 A1.

n-Dopants are understood herein to mean reducing agents, i.e. electron donors. Preferred examples of n-dopants are W(hpp)₄ and further electron-rich metal complexes according to WO 2005/086251 A2, P═N compounds (e.g. WO 2012/175535 A1, WO 2012/175219 A1), naphthylenecarbodiimides (e.g. WO 2012/168358 A1), fluorenes (e.g. WO 2012/031735 A1), radicals and diradicals (e.g. EP 1837926 A1, WO 2007/107306 A1), pyridines (e.g. EP 2452946 A1, EP 2463927 A1), N-heterocyclic compounds (e.g. WO 2009/000237 A1) and acridines and phenazines (e.g. US 2007/145355 A1).

In addition, the compounds OSM1 and OSM2 usable in accordance with the invention may be configured as wide band gap materials. A wide band gap material is understood to mean a material in the sense of the disclosure of U.S. Pat. No. 7,294,849. These systems exhibit exceptional advantageous performance data in electroluminescent devices.

Preferably, the compound used as wide band gap material may have a band gap of 2.5 eV or more, preferably 3.0 eV or more, very preferably of 3.5 eV or more. One way of calculating the band gap is via the energy levels of the highest occupied molecular orbital (HOMO) and the lowest unoccupied molecular orbital (LUMO).

In addition, the compounds OSM1 and OSM2 usable in accordance with the invention may be configured as hole blocker materials (HBMs). A hole blocker material refers to a material which prevents or minimizes the conduction of holes (positive charges) in a multilayer composite, especially if this material is arranged in the form of a layer adjacent to an emission layer or a hole-conducting layer. In general, a hole blocker material has a lower HOMO level than the hole transport material in the adjacent layer. Hole blocker layers are frequently arranged between the light-emitting layer and the electron transport layer in OLEDs.

In principle, it is possible to use any known hole blocker material. In addition to further hole blocker materials detailed elsewhere in the present application, appropriate hole blocker materials are metal complexes (US 2003/0068528), for example bis(2-methyl-8-quinolinolato)(4-phenylphenolato)aluminium(III) (BAlQ). Fac-tris(1-phenylpyrazolato-N,C2)iridium(III) (Ir(ppz)3) is likewise used for these purposes (US 2003/0175553 A1). Phenanthroline derivatives, for example BCP, or phthalimides, for example TMPP, may likewise be used.

In addition, appropriate hole blocker materials are described in WO 00/70655 A2, WO 01/41512 and WO 01/93642 A1.

In addition, the compounds OSM1 and OSM2 usable in accordance with the invention may be configured as electron blocker materials (EBMs). An electron blocker material refers to a material which prevents or minimizes the conduction of electrons in a multilayer composite, especially if this material is arranged in the form of a layer adjacent to an emission layer or an electron-conducting layer. In general, an electron blocker material has a higher LUMO level than the electron transport material in the adjacent layer.

In principle, it is possible to use any known electron blocker material. In addition to further electron blocker materials described elsewhere in the present application, appropriate electron blocker materials are transition metal complexes, for example Ir(ppz)3 (US 2003/0175553).

Examples of suitable mixtures of the invention are the compositions detailed hereinafter, comprising two, three or four compounds having structures of the following formulae:

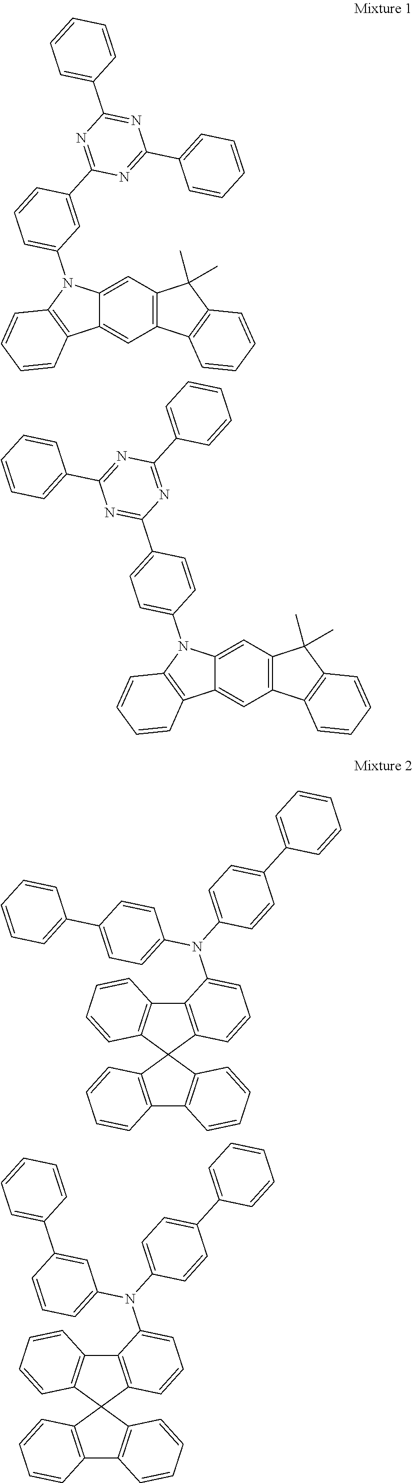

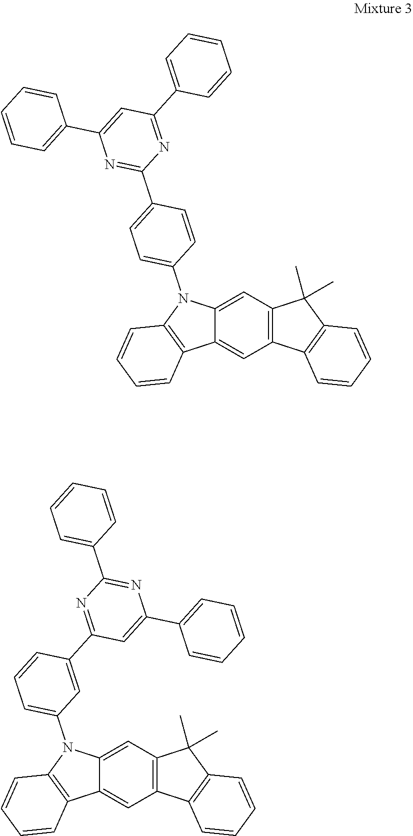 [SMILES: CC1(C)c2ccccc2-c2cc3c4ccccc4n(-c4ccc(-c5nc(-c6ccccc6)cc(-c6ccccc6)n5)cc4)c3cc21 ; CC1(C)c2ccccc2-c2cc3c4ccccc4n(-c4cccc(-c5cc(-c6ccccc6)nc(-c6ccccc6)n5)c4)c3cc21]

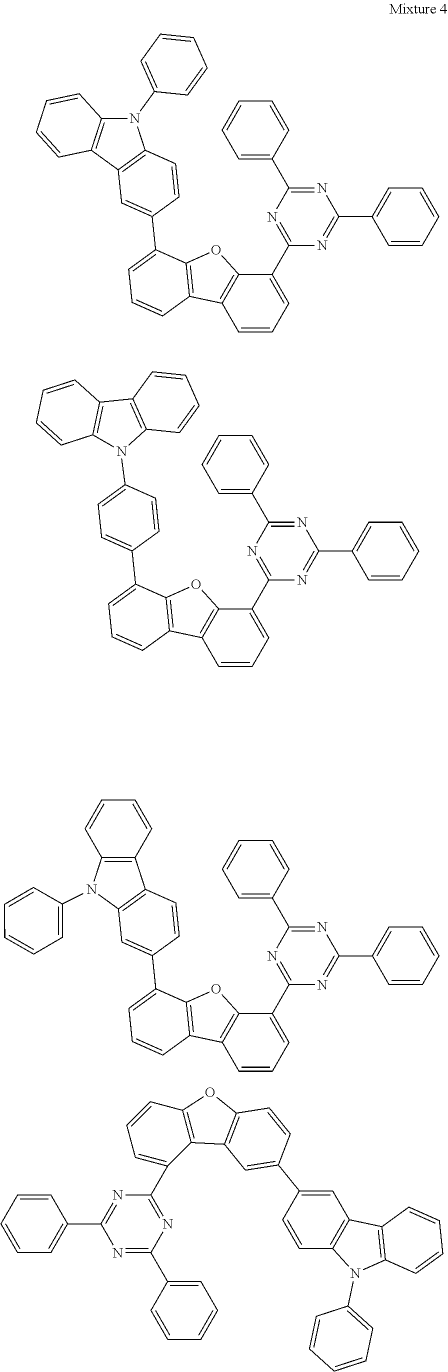

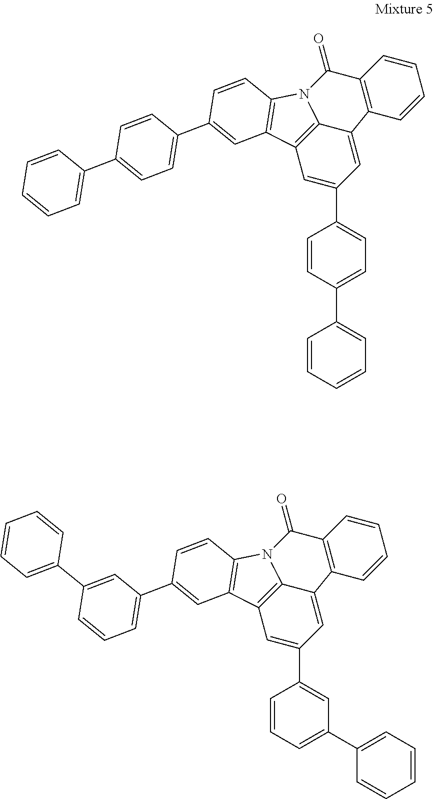 [SMILES: O=c1c2ccccc2c2cc(-c3ccc(-c4ccccc4)cc3)cc3c4cc(-c5ccc(-c6ccccc6)cc5)ccc4n1c23 ; O=c1c2ccccc2c2cc(-c3cccc(-c4ccccc4)c3)cc3c4cc(-c5cccc(-c6ccccc6)c5)ccc4n1c23]

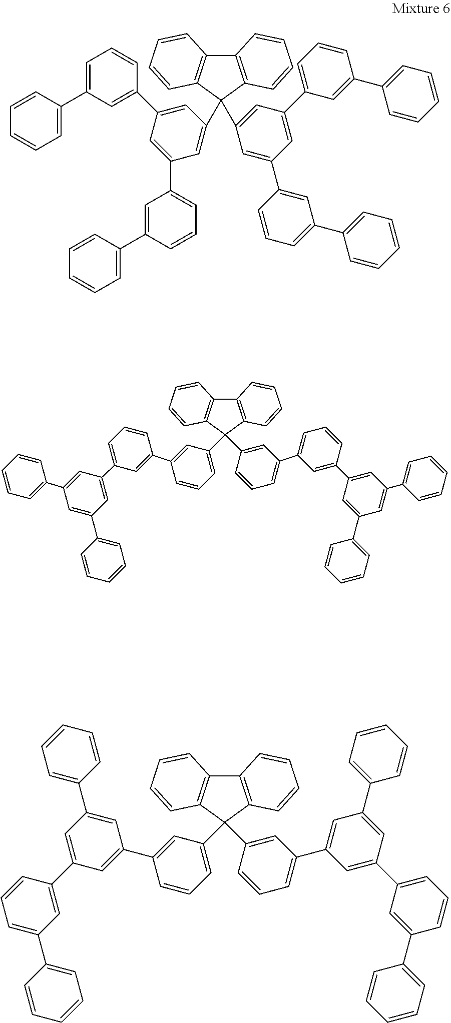

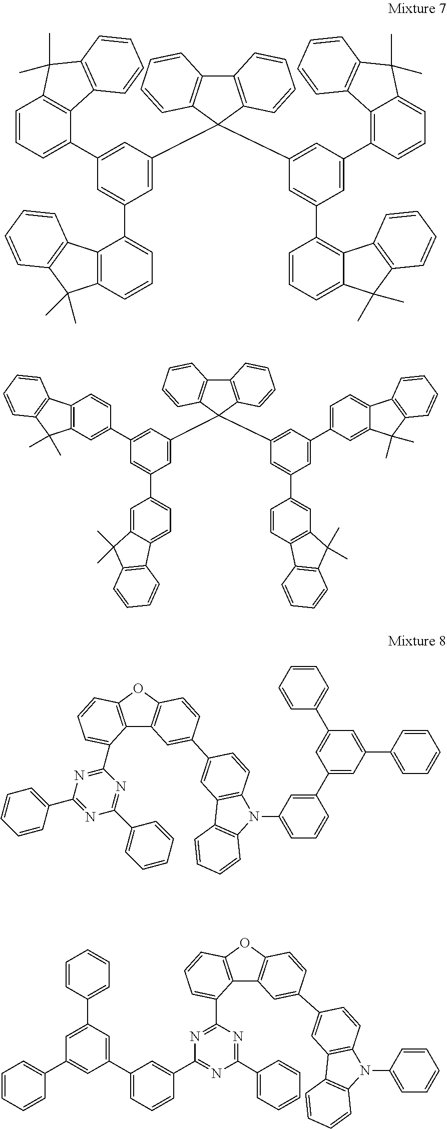

It may preferably be the case that the at least two organic-functional compounds OSM1 and OSM2 are used in a weight ratio in the range from 1:1 to 100:1, preferably 1:1 to 10:1, employing the ratio of the compounds that are constitutional isomers of one another with the highest and the lowest proportion.

Preferably, the at least two organic-functional compounds OSM1 and OSM2 have a similarity calculated according to Tanimoto in the range from 80% to less than 100%, preferably 90% to 99.9% and more preferably 95% to 99.5%.

Preferred embodiments of mixtures of the invention are recited specifically in the examples, these mixtures being usable alone or in combination with further compounds for all purposes of the invention.

Provided that the conditions specified in Claim 1 are complied with, the abovementioned preferred embodiments can be combined with one another as desired. In a particularly preferred embodiment of the invention, the abovementioned preferred embodiments apply simultaneously.

The compounds of the invention are preparable in principle by various processes. However, the processes described hereinafter have been found to be particularly suitable.

Therefore, the present invention further provides a process for preparing the mixtures comprising at least two organic-functional compounds OSM1 and OSM2, in which two organic-functional compounds OSM1 and OSM2 are prepared and mixed or a mixture comprising at least two organic-functional compounds OSM1 and OSM2 is prepared by a coupling reaction.

Suitable compounds OSM1 and OSM2 can be obtained from known precursors via coupling reactions by means of which the above-detailed groups, structural elements and/or substituents S1 or S2 are bonded.

Particularly suitable and preferred coupling reactions which all lead to C—C bond formation and/or C—N bond formation are those according to BUCHWALD, SUZUKI, YAMAMOTO, STILLE, HECK, NEGISHI, SONOGASHIRA and HIYAMA. These reactions are widely known, and the examples will provide the person skilled in the art with further pointers.

The principles of the preparation processes detailed above are known in principle from the literature for similar compounds and can be adapted easily by the person skilled in the art to the preparation of the compounds of the invention. Further information can be found in the examples.

It is possible by these processes, if necessary followed by purification, for example recrystallization or sublimation, to obtain the compounds of the invention comprising structures of formula (I) in high purity, preferably more than 99% (determined by means of ¹H NMR and/or HPLC).

The inventive compounds OSM1 and OSM2 may also have suitable substituents, for example relatively long alkyl groups (about 4 to 20 carbon atoms), especially branched alkyl groups, or optionally substituted aryl groups, for example xylyl, mesityl or branched terphenyl or quaterphenyl groups, which bring about solubility in standard organic solvents, for example butyl benzoate, 3-phenoxytoluene, toluene or xylene, at room temperature in a sufficient concentration, in order to be able to process the compounds from solution. These soluble compounds are of particularly good suitability for processing from solution, for example by printing methods.

The compounds OSM1 and OSM2 usable in accordance with the invention can also be mixed with a polymer. It is likewise possible to incorporate these compounds covalently into a polymer. This is especially possible with compounds substituted by reactive leaving groups such as bromine, iodine, chlorine, boronic acid or boronic ester, or by reactive polymerizable groups such as olefins or oxetanes. These may find use as monomers for production of corresponding oligomers, dendrimers or polymers. The oligomerization or polymerization is preferably effected via the halogen functionality or the boronic acid functionality or via the polymerizable group. It is additionally possible to crosslink the polymers via groups of this kind. The compounds and polymers of the invention may be used in the form of a crosslinked or uncrosslinked layer.

The invention therefore further provides mixtures of oligomers, polymers or dendrimers comprising one or more constitutional isomers, wherein there are one or more bonds in the compounds OSM1 and OSM2 usable in accordance with the invention to the polymer, oligomer or dendrimer. According to the linkage of the structures of the compounds, these therefore form a side chain of the oligomer or polymer or are bonded within the main chain. The polymers, oligomers or dendrimers may be conjugated, partly conjugated or nonconjugated. The oligomers or polymers may be linear, branched or dendritic. For the repeat units of the compounds of the invention in oligomers, dendrimers and polymers, the same preferences apply as described above.

In this context, compounds OSM1 usable in accordance with the invention can be polymerized to give a polymer and the compounds OSM2 to give a polymer, the respective polymers being mixed. In addition, the compounds OSM1 and OSM2 can be polymerized to give a polymer. In addition, various mixtures of compounds OSM1 and OSM2 usable in accordance with the invention can be polymerized, the various polymers subsequently being mixed. Preferably, the polymers, oligomers or dendrimers of the invention comprise at least two different components which differ in terms of their monomer composition with regard to the constituents OSM1 and OSM2.

For preparation of the oligomers or polymers, the monomers of the invention are homopolymerized or copolymerized with further monomers. Preference is given to copolymers wherein the units of formula (I) and/or (II) or the preferred embodiments recited above and hereinafter are present to an extent of 0.01 to 99.9 mol %, preferably 5 to 90 mol %, more preferably 20 to 80 mol %. Suitable and preferred comonomers which form the polymer base skeleton are chosen from fluorenes (for example according to EP 842208 or WO 2000/022026), spirobifluorenes (for example according to EP 707020, EP 894107 or WO 2006/061181), paraphenylenes (for example according to WO 92/18552), carbazoles (for example according to WO 2004/070772 or WO 2004/113468), thiophenes (for example according to EP 1028136), dihydrophenanthrenes (for example according to WO 2005/014689), cis- and trans-indenofluorenes (for example according to WO 2004/041901 or WO 2004/113412), ketones (for example according to WO 2005/040302), phenanthrenes (for example according to WO 2005/104264 or WO 2007/017066) or else a plurality of these units. The polymers, oligomers and dendrimers may contain still further units, for example hole transport units, especially those based on triarylamines, and/or electron transport units.

Additionally of particular interest are compounds usable in accordance with the invention which feature a high glass transition temperature. In this connection, preference is given especially to compounds usable in accordance with the invention comprising structures of the general formula (I) and/or (II) or the preferred embodiments recited above and hereinafter which have a glass transition temperature of at least 70° C., more preferably of at least 110° C., even more preferably of at least 125° C. and especially preferably of at least 150° C., determined in accordance with DIN 51005 (2005-08 version).

For the processing of the compounds usable in accordance with the invention from a liquid phase, for example by spin-coating or by printing methods, formulations of the compounds of the invention are required. These formulations may, for example, be solutions, dispersions or emulsions. For this purpose, it may be preferable to use mixtures of two or more solvents. Suitable and preferred solvents are, for example, toluene, anisole, o-, m- or p-xylene, methyl benzoate, mesitylene, tetralin, veratrole, THF, methyl-THF, THP, chlorobenzene, dioxane, phenoxytoluene, especially 3-phenoxytoluene, (−)-fenchone, 1,2,3,5-tetramethylbenzene, 1,2,4,5-tetramethylbenzene, 1-methylnaphthalene, 2-methylbenzothiazole, 2-phenoxyethanol, 2-pyrrolidinone, 3-methylanisole, 4-methylanisole, 3,4-dimethylanisole, 3,5-dimethylanisole, acetophenone, α-terpineol, benzothiazole, phenyl isovalerate, butyl benzoate, cumene, cyclohexanol, cyclohexanone, cyclohexylbenzene, decalin, dodecylbenzene, ethyl benzoate, indane, methyl benzoate, NMP, p-cymene, phenetole, 1,4-diisopropylbenzene, dibenzyl ether, diethylene glycol butyl methyl ether, triethylene glycol butyl methyl ether, diethylene glycol dibutyl ether, triethylene glycol dimethyl ether, diethylene glycol monobutyl ether, tripropylene glycol dimethyl ether, tetraethylene glycol dimethyl ether, 2-isopropylnaphthalene, pentylbenzene, hexylbenzene, heptylbenzene, octylbenzene, 1,1-bis(3,4-dimethylphenyl)ethane, hexamethylindane or mixtures of these solvents.

The present invention therefore further provides a formulation comprising an inventive mixture of compounds OSM1 and OSM2 usable in accordance with the invention and at least one further compound. The further compound may, for example, be a solvent, especially one of the abovementioned solvents or a mixture of these solvents. The further compound may alternatively be at least one further organic or inorganic compound which is likewise used in the electronic device, for example an emitting compound, especially a phosphorescent dopant, and/or a further matrix material. This further compound may also be polymeric.

The present invention therefore still further provides a composition comprising an inventive mixture of compounds OSM1 and OSM2 usable in accordance with the invention and at least one further organic-functional material. Functional materials are generally the organic or inorganic materials introduced between the anode and cathode. Preferably, the organic-functional material is selected from the group consisting of fluorescent emitters, phosphorescent emitters, emitters that exhibit TADF (thermally activated delayed fluorescence), host materials, electron transport materials, electron injection materials, hole transport materials, hole injection materials, electron blocker materials, hole blocker materials, wide band gap materials, p-dopants and n-dopants.

In a particular aspect of the present invention, the inventive mixtures of compounds OSM1 and OSM2 usable in accordance with the invention can be used as emitter, preferably as fluorescent emitter, emitters in many cases being used in combination with suitable matrix materials. In addition, the inventive mixtures of compounds OSM1 and OSM2 usable in accordance with the invention can be used as matrix material, especially for phosphorescent emitters, matrix materials in many cases being used in combination with further matrix materials.

The present invention therefore also relates to a composition comprising at least one inventive mixture of compounds OSM1 and OSM2 usable in accordance with the invention or the preferred embodiments recited above and hereinafter and at least one further matrix material. According to a particular aspect of the present invention, the further matrix material has electron-transporting properties.

The present invention further provides a composition comprising at least one inventive mixture of compounds OSM1 and OSM2 usable in accordance with the invention or the preferred embodiments recited above and hereinafter and at least one wide band gap material, a wide band gap material being understood to mean a material in the sense of the disclosure of U.S. Pat. No. 7,294,849. These systems exhibit exceptional advantageous performance data in electroluminescent devices.

Preferably, the additional compound may have a band gap of 2.5 eV or more, preferably 3.0 eV or more, very preferably of 3.5 eV or more. One way of calculating the band gap is via the energy levels of the highest occupied molecular orbital (HOMO) and the lowest unoccupied molecular orbital (LUMO).

Molecular orbitals, especially also the highest occupied molecular orbital (HOMO) and the lowest unoccupied molecular orbital (LUMO), the energy levels thereof and the energy of the lowest triplet state T₁ and that of the lowest excited singlet state S₁ of the materials are determined via quantum-chemical calculations. For calculation of organic substances without metals, an optimization of geometry is first conducted by the “Ground State/Semi-empirical/Default Spin/AM1/Charge 0/Spin Singlet” method. Subsequently, an energy calculation is effected on the basis of the optimized geometry. This is done using the “TD-SCF/DFT/Default Spin/B3PW91” method with the “6-31G(d)” basis set (charge 0, spin singlet). For metal-containing compounds, the geometry is optimized via the “Ground State/Hartree-Fock/Default Spin/LanL2 MB/Charge 0/Spin Singlet” method. The energy calculation is effected analogously to the above-described method for the organic substances, except that the “LanL2DZ” basis set is used for the metal atom and the “6-31G(d)” basis set for the ligands. The HOMO energy level HEh or LUMO energy level LEh is obtained from the energy calculation in Hartree units. This is used to determine the HOMO and LUMO energy levels in electron volts, calibrated by cyclic voltammetry measurements, as follows:

HOMO(eV)=((HEh*27.212)−0.9899)/1.1206

LUMO(eV)=((LEh*27.212)−2.0041)/1.385

These values are to be regarded as HOMO and LUMO energy levels of the materials in the context of this application.

The lowest triplet state T₁ is defined as the energy of the triplet state having the lowest energy, which is apparent from the quantum-chemical calculation described.

The lowest excited singlet state S₁ is defined as the energy of the excited singlet state having the lowest energy, which is apparent from the quantum-chemical calculation described.

The method described herein is independent of the software package used and always gives the same results. Examples of frequently utilized programs for this purpose are “Gaussian09 W” (Gaussian Inc.) and Q-Chem 4.1 (Q-Chem, Inc.).

The present invention also relates to a composition comprising at least one inventive mixture of compounds OSM1 and OSM2 usable in accordance with the invention or the preferred embodiments recited above and hereinafter, and at least one emitter preferably selected from fluorescent emitters, phosphorescent emitters and/or emitters that exhibit TADF (thermally activated delayed fluorescence), the mixture preferably comprising at least one phosphorescent emitter present in a stereoisomer mixture, preferably with lambda and delta isomers.

A dopant in a system comprising a matrix material and a dopant is understood to mean that component having the smaller proportion in the mixture. Correspondingly, a matrix material in a system comprising a matrix material and a dopant is understood to mean that component having the greater proportion in the mixture.

Preferred phosphorescent emitters, also referred to herein as phosphorescent dopants, for use in matrix systems, preferably mixed matrix systems, are the preferred phosphorescent dopants specified hereinafter.

The term “phosphorescent dopants” typically encompasses compounds where the emission of light is effected through a spin-forbidden transition, for example a transition from an excited triplet state or a state having a higher spin quantum number, for example a quintet state.

Suitable phosphorescent compounds (═triplet emitters) are especially compounds which, when suitably excited, emit light, preferably in the visible region, and also contain at least one atom of atomic number greater than 20, preferably greater than 38 and less than 84, more preferably greater than 56 and less than 80, especially a metal having this atomic number. Preferred phosphorescence emitters used are compounds containing copper, molybdenum, tungsten, rhenium, ruthenium, osmium, rhodium, iridium, palladium, platinum, silver, gold or europium, especially compounds containing iridium or platinum. In the context of the present invention, all luminescent compounds containing the abovementioned metals are regarded as phosphorescent compounds.

Examples of the above-described emitters can be found in applications WO 00/70655, WO 2001/41512, WO 2002/02714, WO 2002/15645, EP 1191613, EP 1191612, EP 1191614, WO 05/033244, WO 05/019373, US 2005/0258742, WO 2009/146770, WO 2010/015307, WO 2010/031485, WO 2010/054731, WO 2010/054728, WO 2010/086089, WO 2010/099852, WO 2010/102709, WO 2011/032626, WO 2011/066898, WO 2011/157339, WO 2012/007086, WO 2014/008982, WO 2014/023377, WO 2014/094961, WO 2014/094960 and the as yet unpublished applications EP 13004411.8, EP 14000345.0, EP 14000417.7 and EP 14002623.8. In general, all phosphorescent complexes as used for phosphorescent OLEDs according to the prior art and as known to those skilled in the art in the field of organic electroluminescence are suitable, and the person skilled in the art will be able to use further phosphorescent complexes without exercising inventive skill.

Explicit examples of phosphorescent dopants are adduced in the following table:

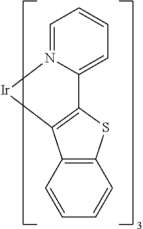

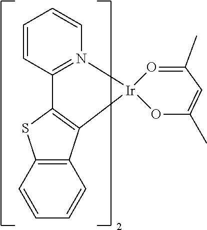

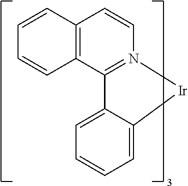

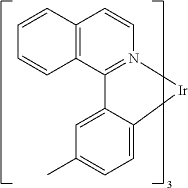

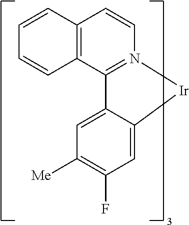

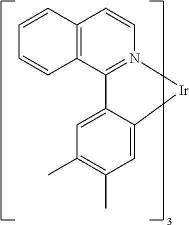

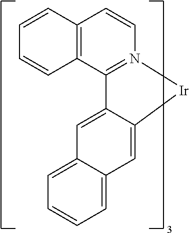

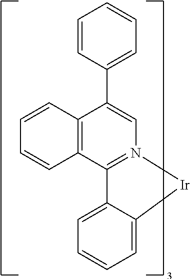

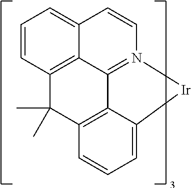

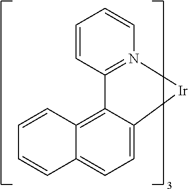

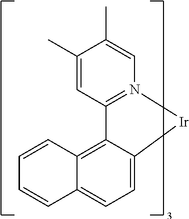

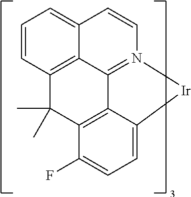

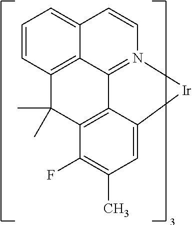

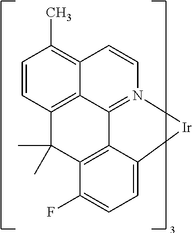

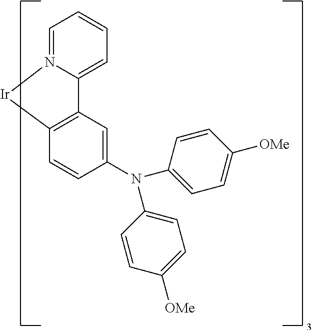

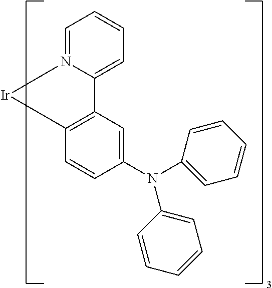

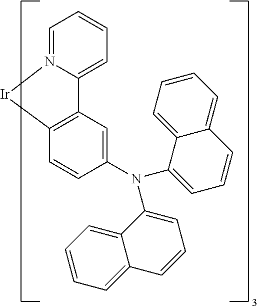

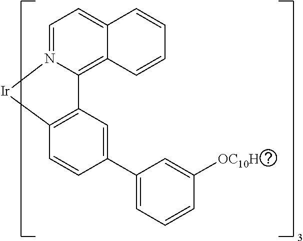

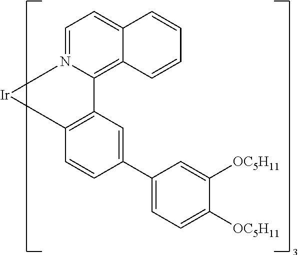

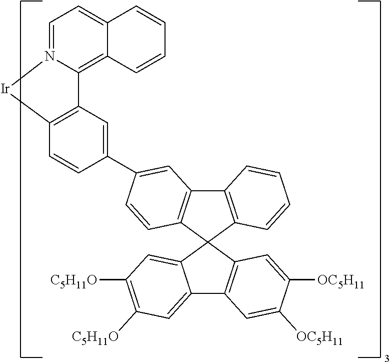

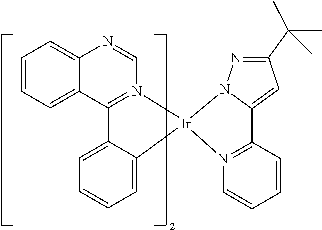

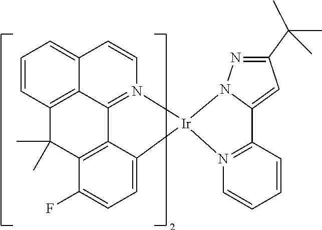

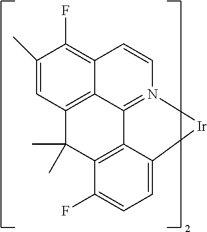

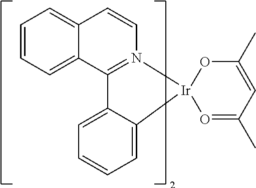

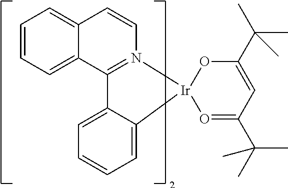

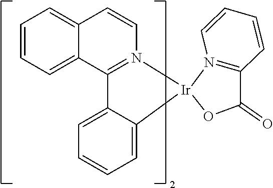

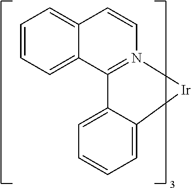

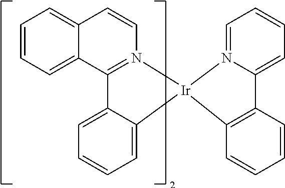

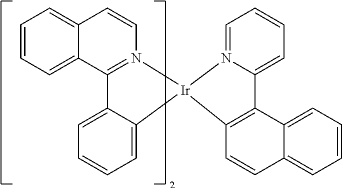

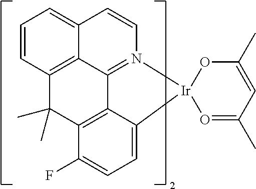

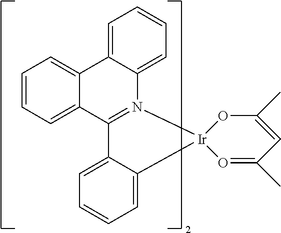

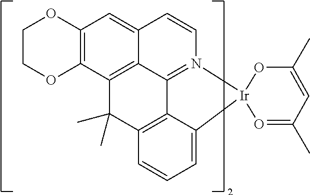

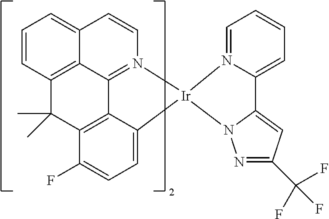

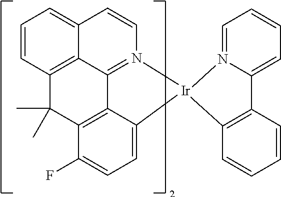

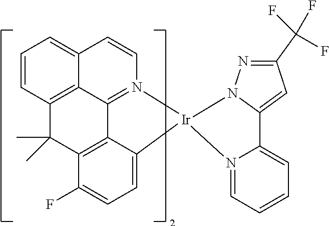

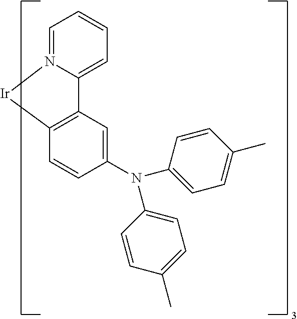

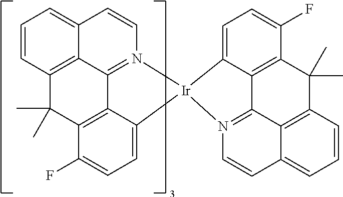

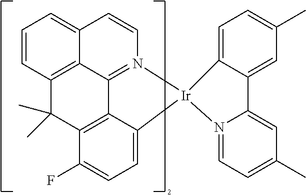

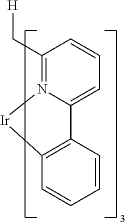

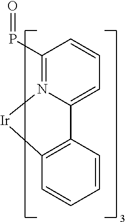

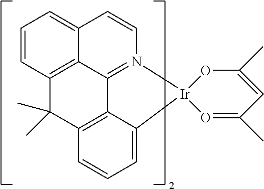

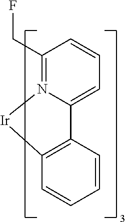

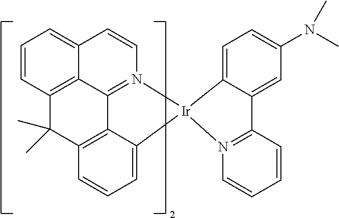

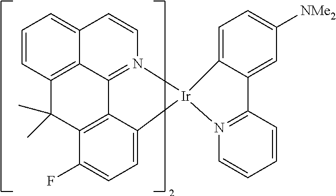

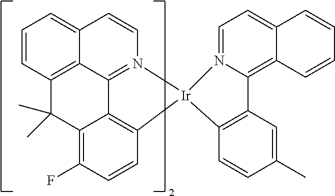

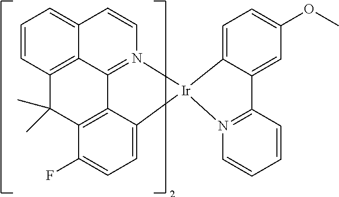

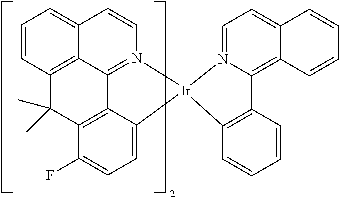

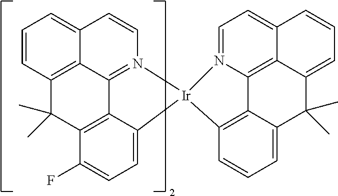

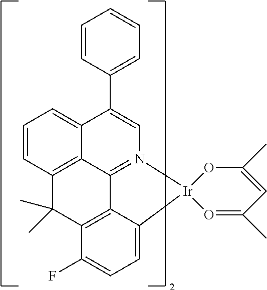

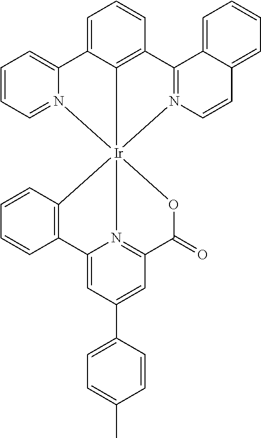

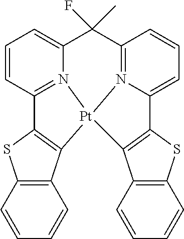

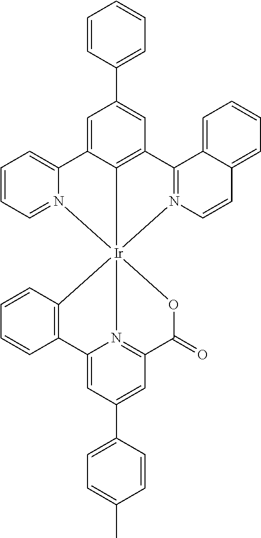

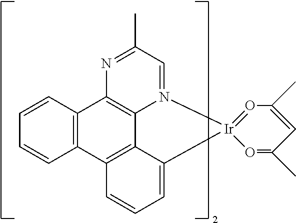

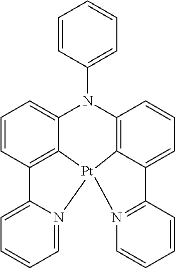

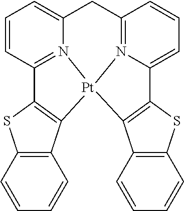

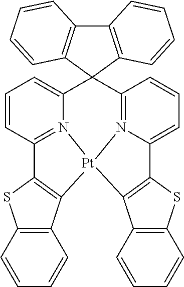

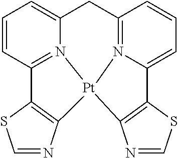

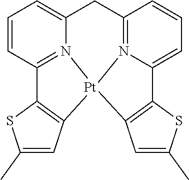

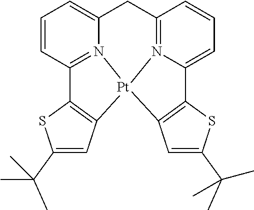

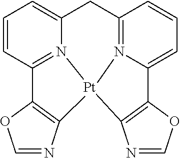

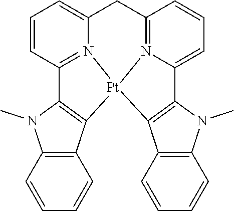

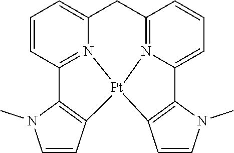

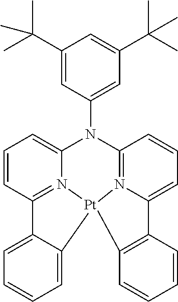

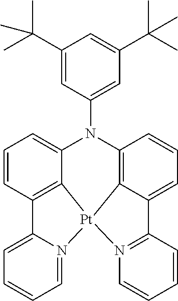

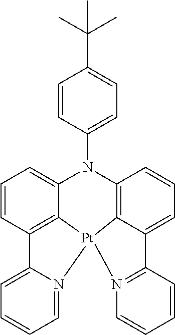

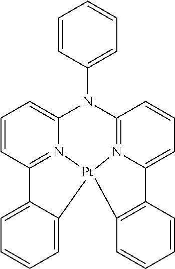

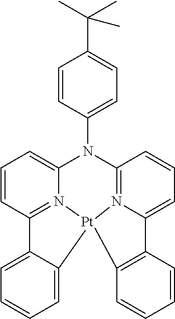

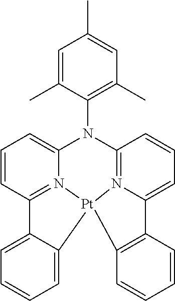

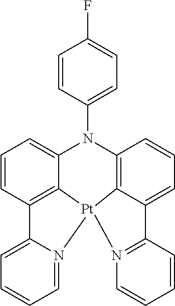

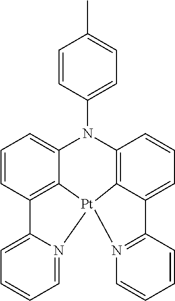

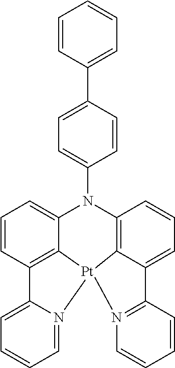

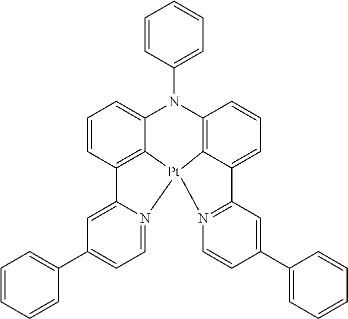

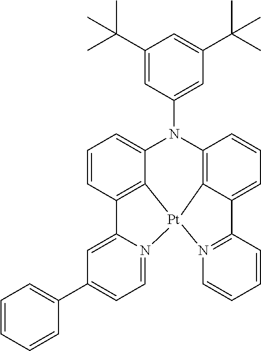

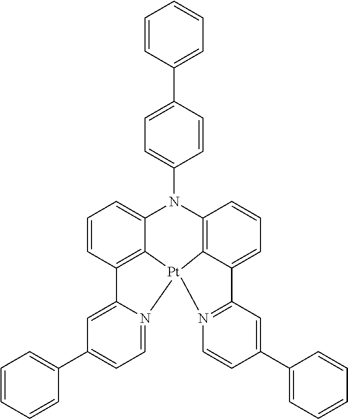

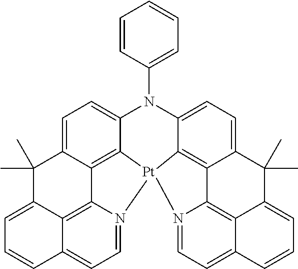

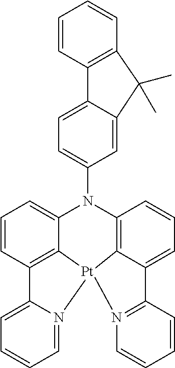

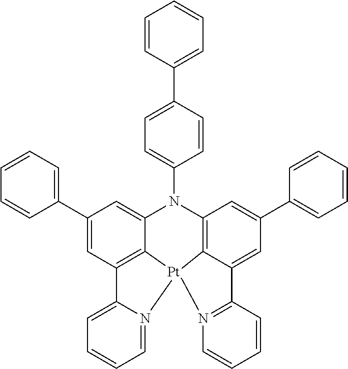

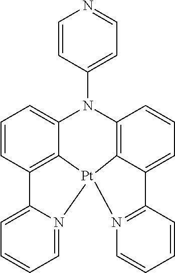

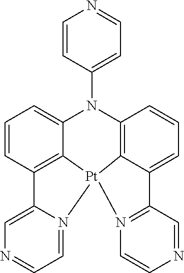

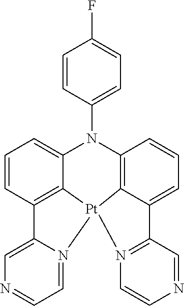

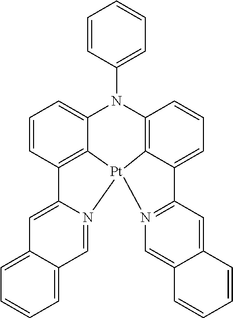

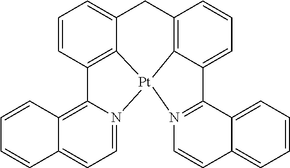

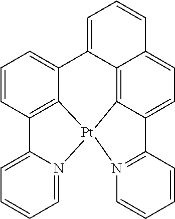

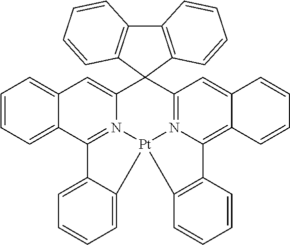

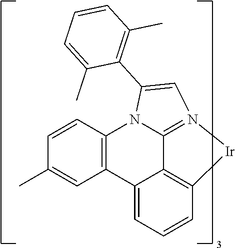

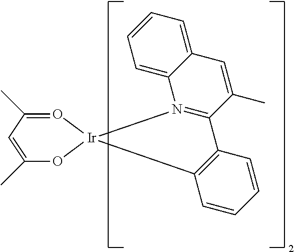

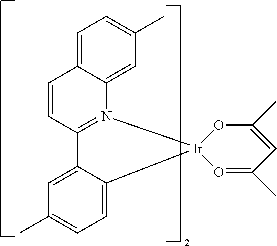

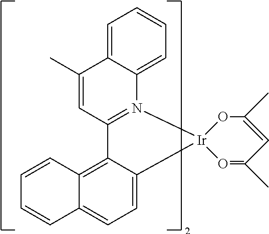

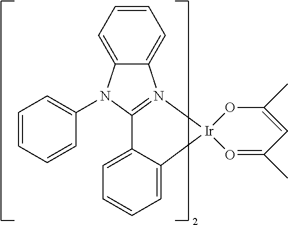

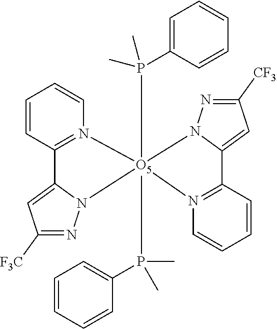

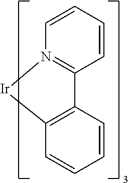

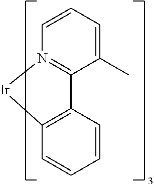

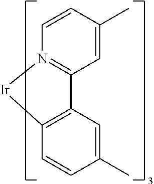

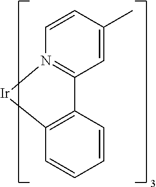

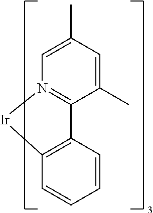

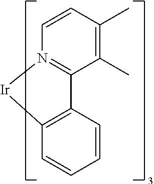

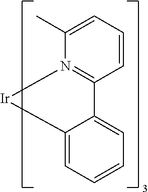

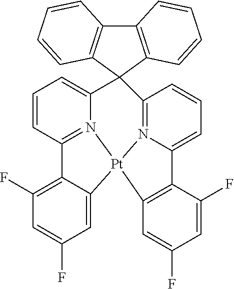

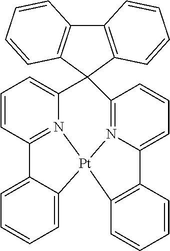

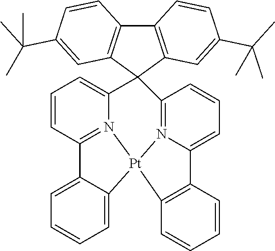

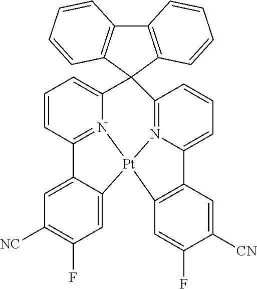

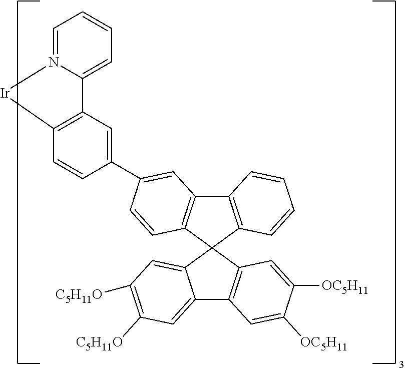

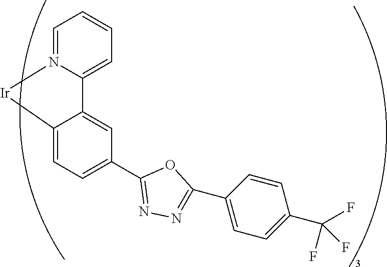

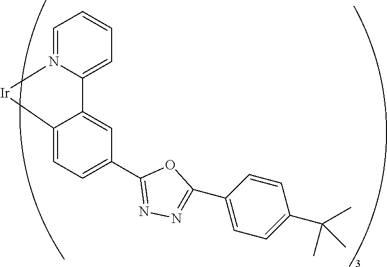

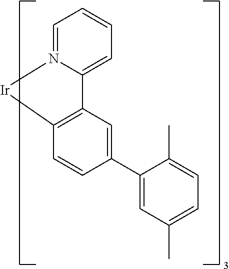

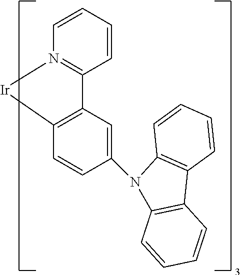

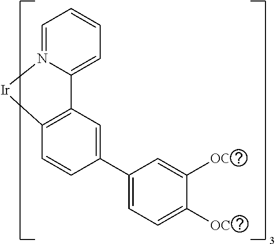

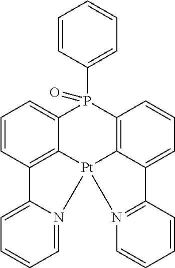

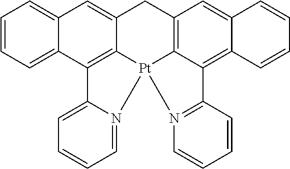

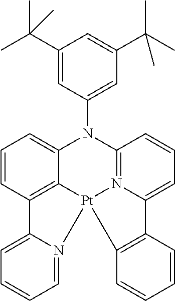

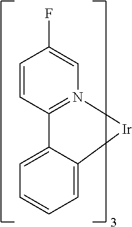

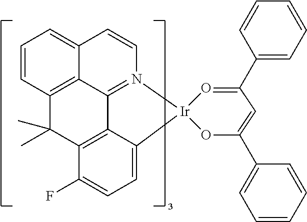

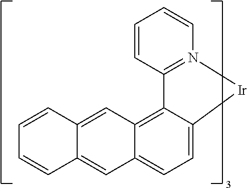

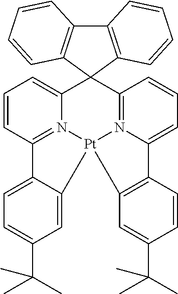

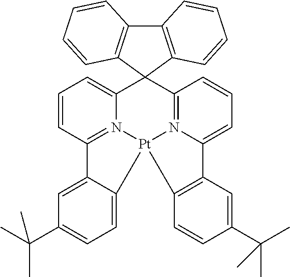

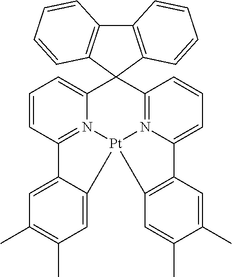

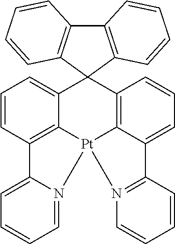

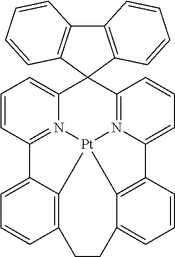

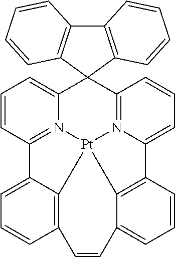

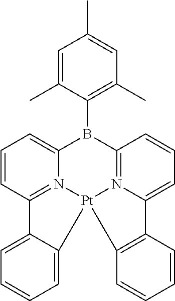

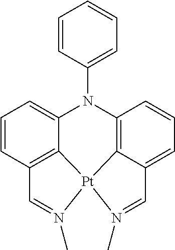

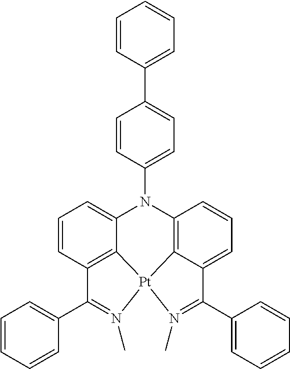

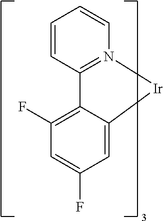

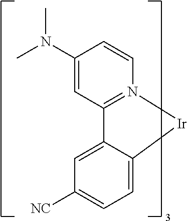

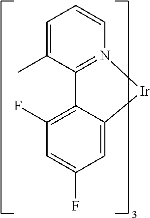

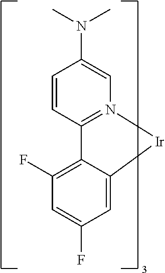

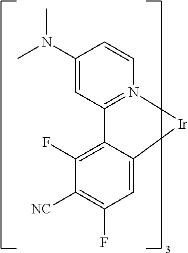

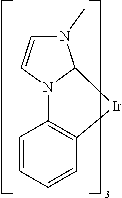

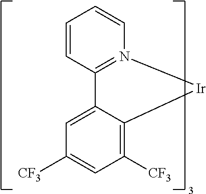

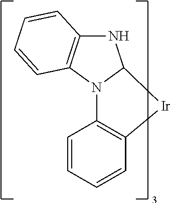

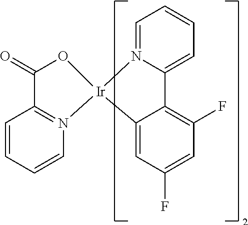

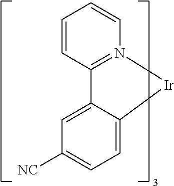

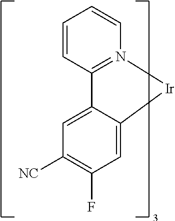

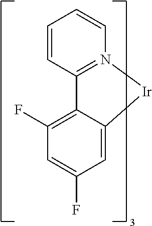

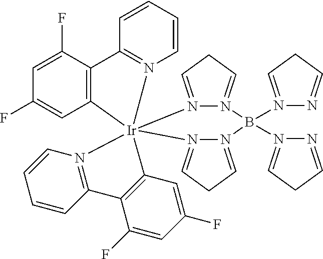

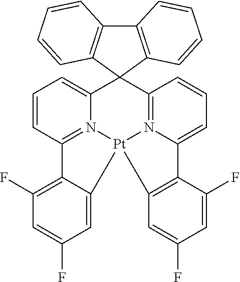

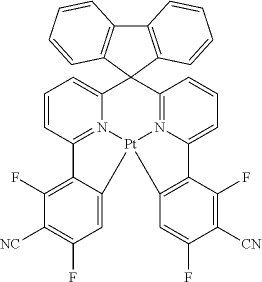

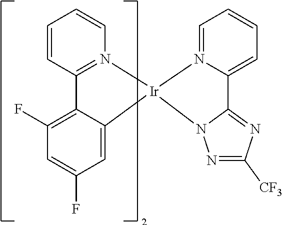

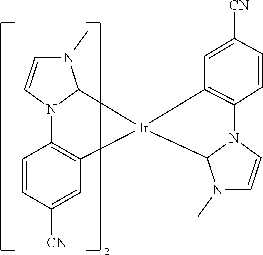

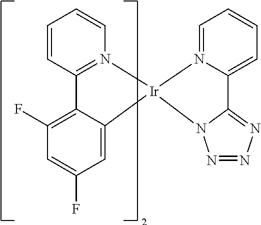

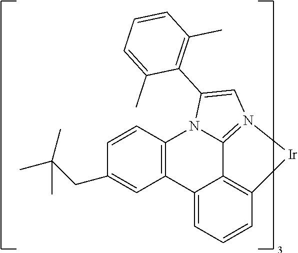

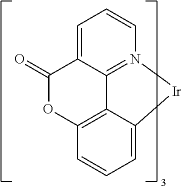

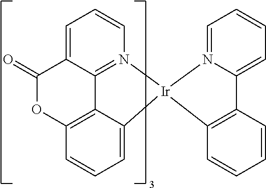

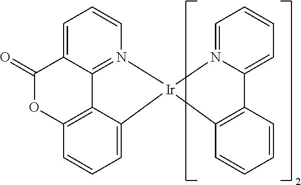

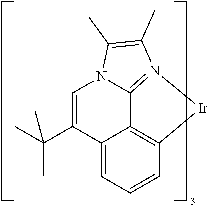

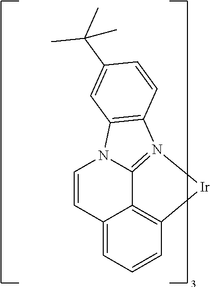

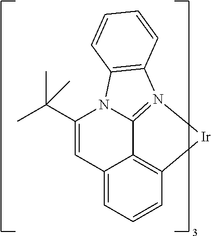

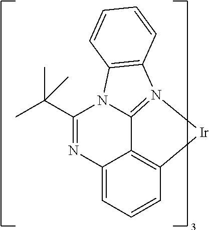

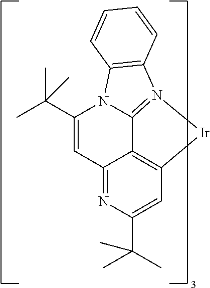

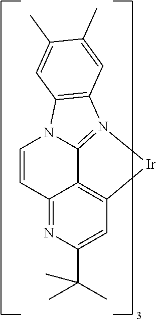

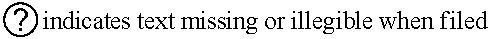

The above-described compound comprising at least one inventive mixture of compounds OSM1 and OSM2 usable in accordance with the invention, or the preferred embodiments detailed above, can preferably be used as active component in an electronic device. An electronic device is understood to mean any device comprising anode, cathode and at least one layer between anode and cathode, said layer comprising at least one organic or organometallic compound. The electronic device of the invention thus comprises anode, cathode and at least one layer in between containing at least one compound comprising structures of the formula (I) and/or (II). Preferred electronic devices here are selected from the group consisting of organic electroluminescent devices (OLEDs, PLEDs), organic integrated circuits (O-ICs), organic field-effect transistors (O-FETs), organic thin-film transistors (O-TFTs), organic light-emitting transistors (O-LETs), organic solar cells (O-SCs), organic optical detectors, organic photoreceptors, organic field-quench devices (O-FQDs), organic electrical sensors, light-emitting electrochemical cells (LECs), organic laser diodes (O-lasers) and organic plasmon emitting devices (D. M. Koller et al., Nature Photonics 2008, 1-4), preferably organic electroluminescent devices (OLEDs, PLEDs), especially phosphorescent OLEDs, containing at least one compound comprising structures of the formula (I) in at least one layer. Particular preference is given to organic electroluminescent devices. Active components are generally the organic or inorganic materials introduced between the anode and cathode, for example charge injection, charge transport or charge blocker materials, but especially emission materials and matrix materials.

A preferred embodiment of the invention is organic electroluminescent devices. The organic electroluminescent device comprises cathode, anode and at least one emitting layer. Apart from these layers, it may comprise still further layers, for example in each case one or more hole injection layers, hole transport layers, hole blocker layers, electron transport layers, electron injection layers, exciton blocker layers, electron blocker layers, charge generation layers and/or organic or inorganic p/n junctions. At the same time, it is possible that one or more hole transport layers are p-doped, for example with metal oxides such as MoO₃ or WO₃ or with (per)fluorinated electron-deficient aromatic systems, and/or that one or more electron transport layers are n-doped. It is likewise possible for interlayers to be introduced between two emitting layers, these having, for example, an exciton-blocking function and/or controlling the charge balance in the electroluminescent device. However, it should be pointed out that not necessarily every one of these layers need be present.

In this case, it is possible for the organic electroluminescent device to contain an emitting layer, or for it to contain a plurality of emitting layers. If a plurality of emission layers are present, these preferably have several emission maxima between 380 nm and 750 nm overall, such that the overall result is white emission; in other words, various emitting compounds which may fluoresce or phosphoresce are used in the emitting layers. Especially preferred are three-layer systems where the three layers exhibit blue, green and orange or red emission (for the basic construction see, for example, WO 2005/011013), or systems having more than three emitting layers. The system may also be a hybrid system wherein one or more layers fluoresce and one or more other layers phosphoresce.

In a preferred embodiment of the invention, the organic electroluminescent device contains the inventive mixture of compounds OSM1 and OSM2 usable in accordance with the invention or the above-detailed preferred embodiments as matrix material, preferably as hole-conducting matrix material, in one or more emitting layers, preferably in combination with a further matrix material, preferably an electron-conducting matrix material. In a further preferred embodiment of the invention, the further matrix material is a hole-transporting compound. In yet a further preferred embodiment, the further matrix material is a compound having a large band gap which is not involved to a significant degree, if at all, in the hole and electron transport in the layer. An emitting layer comprises at least one emitting compound.

Suitable matrix materials which can be used in combination with the inventive mixture of compounds OSM1 and OSM2 usable in accordance with the invention or according to the preferred embodiments are aromatic ketones, aromatic phosphine oxides or aromatic sulfoxides or sulfones, for example according to WO 2004/013080, WO 2004/093207, WO 2006/005627 or WO 2010/006680, triarylamines, especially monoamines, for example according to WO 2014/015935, carbazole derivatives, e.g. CBP (N,N-biscarbazolylbiphenyl) or the carbazole derivatives disclosed in WO 2005/039246, US 2005/0069729, JP 2004/288381, EP 1205527 or WO 2008/086851, indolocarbazole derivatives, for example according to WO 2007/063754 or WO 2008/056746, indenocarbazole derivatives, for example according to WO 2010/136109 and WO 2011/000455, azacarbazole derivatives, for example according to EP 1617710, EP 1617711, EP 1731584, JP 2005/347160, bipolar matrix materials, for example according to WO 2007/137725, silanes, for example according to WO 2005/111172, azaboroles or boronic esters, for example according to WO 2006/117052, triazine derivatives, for example according to WO 2010/015306, WO 2007/063754 or WO 2008/056746, zinc complexes, for example according to EP 652273 or WO 2009/062578, diazasilole or tetraazasilole derivatives, for example according to WO 2010/054729, diazaphosphole derivatives, for example according to WO 2010/054730, bridged carbazole derivatives, for example according to US 2009/0136779, WO 2010/050778, WO 2011/042107, WO 2011/088877 or WO 2012/143080, triphenylene derivatives, for example according to WO 2012/048781, lactams, for example according to WO 2011/116865, WO 2011/137951 or WO 2013/064206, or 4-spirocarbazole derivatives, for example according to WO 2014/094963 or the as yet unpublished application EP 14002104.9. It is likewise possible for a further phosphorescent emitter which emits at a shorter wavelength than the actual emitter to be present as co-host in the mixture.

Preferred co-host materials are triarylamine derivatives, especially monoamines, indenocarbazole derivatives, 4-spirocarbazole derivatives, lactams and carbazole derivatives.

It may also be preferable to use a plurality of different matrix materials as a mixture, especially at least one electron-conducting matrix material and at least one hole-conducting matrix material. Preference is likewise given to the use of a mixture of a charge-transporting matrix material and an electrically inert matrix material having no significant involvement, if any, in the charge transport, as described, for example, in WO 2010/108579.

It is further preferable to use a mixture of two or more triplet emitters together with a matrix. In this case, the triplet emitter having the shorter-wave emission spectrum serves as co-matrix for the triplet emitter having the longer-wave emission spectrum.

More preferably, it is possible to use an inventive mixture of compounds OSM1 and OSM2 usable in accordance with the invention, in a preferred embodiment, as matrix material in an emission layer of an organic electronic device, especially in an organic electroluminescent device, for example in an OLED or OLEC. In this case, the matrix material containing at least one inventive mixture of compounds OSM1 and OSM2 usable in accordance with the invention or the preferred embodiments recited above and hereinafter is present in the electronic device in combination with one or more dopants, preferably phosphorescent dopants.

The proportion of the matrix material in the emitting layer in this case is between 50.0% and 99.9% by volume, preferably between 60.0% and 99.5% by volume and more preferably between 92.0% and 99.5% by volume for fluorescent emitting layers, and between 60.0% and 70.0% by volume for phosphorescent layers that emit in the green or red region and between 90.0% and 97.0% by volume for phosphorescent layers that emit in the blue region.

Correspondingly, the proportion of the dopant is between 0.1% and 50.0% by volume, preferably between 0.5% and 20.0% by volume and more preferably between 0.5% and 8.0% by volume for fluorescent emitting layers, and between 3.0% and 10.0% by volume for phosphorescent emitting layers that emit in the blue region and between 30.0% and 40.0% by volume for phosphorescent emitting layers that emit in the green or red region.

An emitting layer of an organic electroluminescent device may also comprise systems comprising a plurality of matrix materials (mixed matrix systems) and/or a plurality of dopants. In this case too, the dopants are generally those materials having the smaller proportion in the system and the matrix materials are those materials having the greater proportion in the system. In individual cases, however, the proportion of a single matrix material in the system may be less than the proportion of a single dopant.

In a further preferred embodiment of the invention, the inventive mixtures of compounds OSM1 and OSM2 usable in accordance with the invention or the preferred embodiments recited above and hereinafter are used as a component of mixed matrix systems. The mixed matrix systems preferably comprise two or three different matrix materials, more preferably two different matrix materials. Preferably, in this case, one of the two materials is a material having hole-transporting properties and the other material is a material having electron-transporting properties. The desired electron-transporting and hole-transporting properties of the mixed matrix components may, however, also be combined mainly or entirely in a single mixed matrix component, in which case the further mixed matrix component(s) fulfil(s) other functions. The two different matrix materials may be present in a ratio of 1:50 to 1:1, preferably 1:20 to 1:1, more preferably 1:10 to 1:1 and most preferably 1:4 to 1:1. Preference is given to using mixed matrix systems in phosphorescent organic electroluminescent devices. One source of more detailed information about mixed matrix systems is the application WO 2010/108579.

The present invention further provides an electronic device, preferably an organic electroluminescent device, comprising one or more compounds of the invention and/or at least one oligomer, polymer or dendrimer of the invention in one or more hole-conducting layers, as hole-conducting compound.

The present invention additionally provides an electronic device, preferably an organic electroluminescent device, comprising one or more compounds of the invention and/or at least one oligomer, polymer or dendrimer of the invention in emitting layers, as emitting compound, preferably as fluorescent emitter, or as matrix material, preferably in combination with a phosphorescent emitter.

Preferred cathodes are metals having a low work function, metal alloys or multilayer structures composed of various metals, for example alkaline earth metals, alkali metals, main group metals or lanthanoids (e.g. Ca, Ba, Mg, Al, In, Mg, Yb, Sm, etc.). Additionally suitable are alloys composed of an alkali metal or alkaline earth metal and silver, for example an alloy composed of magnesium and silver. In the case of multilayer structures, in addition to the metals mentioned, it is also possible to use further metals having a relatively high work function, for example Ag, in which case combinations of the metals such as Mg/Ag, Ca/Ag or Ba/Ag, for example, are generally used. It may also be preferable to introduce a thin interlayer of a material having a high dielectric constant between a metallic cathode and the organic semiconductor. Examples of useful materials for this purpose are alkali metal or alkaline earth metal fluorides, but also the corresponding oxides or carbonates (e.g. LiF, Li₂O, BaF₂, MgO, NaF, CsF, Cs₂CO₃, etc.). Likewise useful for this purpose are organic alkali metal complexes, e.g. Liq (lithium quinolinate). The layer thickness of this layer is preferably between 0.5 and 5 nm.

Preferred anodes are materials having a high work function. Preferably, the anode has a work function of greater than 4.5 eV versus vacuum. Firstly, metals having a high redox potential are suitable for this purpose, for example Ag, Pt or Au. Secondly, metal/metal oxide electrodes (e.g. Al/Ni/NiOx, Al/PtOx) may also be preferred. For some applications, at least one of the electrodes has to be transparent or partly transparent in order to enable either the irradiation of the organic material (O-SC) or the emission of light (OLED/PLED, O-laser). Preferred anode materials here are conductive mixed metal oxides. Particular preference is given to indium tin oxide (ITO) or indium zinc oxide (IZO). Preference is further given to conductive doped organic materials, especially conductive doped polymers, for example PEDOT, PANI or derivatives of these polymers. It is further preferable when a p-doped hole transport material is applied to the anode as hole injection layer, in which case suitable p-dopants are metal oxides, for example MoO₃ or WO₃, or (per)fluorinated electron-deficient aromatic systems. Further suitable p-dopants are HAT-CN (hexacyanohexaazatriphenylene) or the compound NPD9 from Novaled. Such a layer simplifies hole injection into materials having a low HOMO, i.e. a large HOMO in terms of magnitude.

In the further layers, it is generally possible to use any materials as used according to the prior art for the layers, and the person skilled in the art is able, without exercising inventive skill, to combine any of these materials with the materials of the invention in an electronic device.

The device is correspondingly (according to the application) structured, contact-connected and finally hermetically sealed, since the lifetime of such devices is severely shortened in the presence of water and/or air.

Preference is additionally given to an electronic device, especially an organic electroluminescent device, which is characterized in that one or more layers are produced from solution, for example by spin-coating, or by any printing method, for example screen printing, flexographic printing, offset printing or nozzle printing, but more preferably LITI (light-induced thermal imaging, thermal transfer printing) or inkjet printing. For this purpose, soluble compounds are needed, which are obtained, for example, through suitable substitution.

The above-cited documents for description of the functional compounds are incorporated into the present application by reference for the purposes of disclosure.

These methods are known in general terms to those skilled in the art and can be applied by those skilled in the art without difficulty to electronic devices, especially organic electroluminescent devices comprising compounds of the invention comprising structures of formula (I) and/or (II) or the above-detailed preferred embodiments.

The electronic devices of the invention, especially organic electroluminescent devices, are notable for one or more of the following surprising advantages over the prior art:
1. Mixtures of compounds OSM1 and OSM2 usable in accordance with the invention or oligomers, polymers or dendrimers derived therefrom, or the preferred embodiments recited above and hereinafter, show excellent stability in solution, where the solutions can have a higher concentration than solutions comprising solely compounds OSM1 or OSM2 usable in accordance with the invention.
2, Mixtures of compounds OSM1 and OSM2 usable in accordance with the invention or oligomers, polymers or dendrimers derived therefrom, or the preferred embodiments recited above and hereinafter, form very good, especially very homogeneous, films from solutions.
3. Mixtures of compounds OSM1 and OSM2 usable in accordance with the invention or oligomers, polymers or dendrimers derived therefrom, or the preferred embodiments recited above and hereinafter, exhibit very high stability and lead to compounds having a very long lifetime.
4, With mixtures of compounds OSM1 and OSM2 usable in accordance with the invention or oligomers, polymers or dendrimers derived therefrom, or the preferred embodiments recited above and hereinafter, it is possible to avoid the formation of optical loss channels in electronic devices, especially organic electroluminescent devices. As a result, these devices feature a high PL efficiency and hence high EL efficiency of emitters, and excellent energy transmission of the matrices to dopants.
5. Mixtures of compounds OSM1 and OSM2 usable in accordance with the invention or oligomers, polymers or dendrimers derived therefrom, or the preferred embodiments recited above and hereinafter, are notable for excellent thermal stability.
6, Mixtures of compounds OSM1 and OSM2 usable in accordance with the invention or oligomers, polymers or dendrimers derived therefrom, or the preferred embodiments recited above and hereinafter, have excellent glass film formation.
7. Electronic devices, especially organic electroluminescent devices, containing mixtures of compounds OSM1 and OSM2 usable in accordance with the invention or oligomers, polymers or dendrimers derived therefrom, or the preferred embodiments recited above and hereinafter, especially as wide band gap materials, as fluorescent emitters or as electron-conducting and/or hole-conducting materials, have a very good lifetime. In this context, these compounds especially bring about low roll-off, i.e. a small drop in power efficiency of the device at high luminances.
8. Electronic devices, especially organic electroluminescent devices, containing mixtures of compounds OSM1 and OSM2 usable in accordance with the invention or oligomers, polymers or dendrimers derived therefrom, or the preferred embodiments recited above and hereinafter, as fluorescent emitters or as electron-conducting materials, hole-conducting materials and/or host materials, have excellent efficiency. In this context, mixtures of compounds OSM1 and OSM2 usable in accordance with the invention or oligomers, polymers or dendrimers derived therefrom, or the preferred embodiments recited above and hereinafter, bring about a low operating voltage when used in electronic devices.

These abovementioned advantages are not accompanied by a deterioration in the further electronic properties.

The mixtures of the invention are suitable for use in an electronic device. An electronic device is understood here to mean a device containing at least one layer containing at least one organic compound. The component may, however, also comprise inorganic materials or else layers formed entirely from inorganic materials.

The present invention therefore further provides for the use of the mixtures of the invention in an electronic device, especially in an organic electroluminescent device.

The present invention still further provides for the use of an inventive mixture of compounds OSM1 and OSM2 usable in accordance with the invention and/or of an oligomer, polymer or dendrimer of the invention in an electronic device as fluorescent emitter, host material for phosphorescent emitters, electron transport material and/or hole transport material, preferably as host material for phosphorescent emitters or as hole transport material or as electron transport material.

The present invention still further provides an electronic device comprising at least one of the above-detailed mixtures of the invention. In this case, the preferences detailed above for the compound also apply to the electronic devices. More preferably, the electronic device is selected from the group consisting of organic electroluminescent devices (OLEDs, PLEDs), organic integrated circuits (O-ICs), organic field-effect transistors (O-FETs), organic thin-film transistors (O-TFTs), organic light-emitting transistors (O-LETs), organic solar cells (O-SCs), organic optical detectors, organic photoreceptors, organic field-quench devices (O-FQDs), organic electrical sensors, light-emitting electrochemical cells (LECs), organic laser diodes (O-lasers) and organic plasmon emitting devices (D. M. Koller et al., Nature Photonics 2008, 1-4), preferably organic electroluminescent devices (OLEDs, PLEDs), especially phosphorescent OLEDs.

In a further embodiment of the invention, the organic electroluminescent device of the invention does not contain any separate hole injection layer and/or hole transport layer and/or hole blocker layer and/or electron transport layer, meaning that the emitting layer directly adjoins the hole injection layer or the anode, and/or the emitting layer directly adjoins the electron transport layer or the electron injection layer or the cathode, as described, for example, in WO 2005/053051. It is additionally possible to use a metal complex identical or similar to the metal complex in the emitting layer as hole transport or hole injection material directly adjoining the emitting layer, as described, for example, in WO 2009/030981.

In the further layers of the organic electroluminescent device of the invention, it is possible to use any materials as typically used according to the prior art. The person skilled in the art is therefore able, without exercising inventive skill, to use any materials known for organic electroluminescent devices in combination with the inventive mixture of compounds OSM1 and OSM2 usable in accordance with the invention or according to the preferred embodiments.

The inventive mixtures of compounds OSM1 and OSM2 usable in accordance with the invention, when used in organic electroluminescent devices, generally have very good properties. At the same time, the further properties of the organic electroluminescent device, especially the efficiency and voltage, are likewise better or at least comparable.

It should be pointed out that variations of the embodiments described in the present invention are covered by the scope of this invention. Any feature disclosed in the present invention may, unless this is explicitly ruled out, be exchanged for alternative features which serve the same purpose or an equivalent or similar purpose. Thus, any feature disclosed in the present invention, unless stated otherwise, should be considered as an example of a generic series or as an equivalent or similar feature.

All features of the present invention may be combined with one another in any manner, unless particular features and/or steps are mutually exclusive. This is especially true of preferred features of the present invention. Equally, features of non-essential combinations may be used separately (and not in combination).

It should also be pointed out that many of the features, and especially those of the preferred embodiments of the present invention, should themselves be regarded as inventive and not merely as some of the embodiments of the present invention. For these features, independent protection may be sought in addition to or as an alternative to any currently claimed invention.

The technical teaching disclosed with the present invention may be abstracted and combined with other examples.

The invention is illustrated in detail by the examples which follow, without any intention of restricting it thereby.

The person skilled in the art will be able to use the details given, without exercising inventive skill, to produce further electronic devices of the invention and hence to execute the invention over the entire scope claimed.

### EXAMPLES

To check the solution stability of isomer mixtures, individual substances and isomer mixtures are tested for stability in various solvents. The solvents used are, by way of example, toluene and 3-phenoxytoluene. The individual substances and isomer mixtures are used in accordance with the invention in individual material concentrations of 10 g/l to 40 g/l. The individual substances and isomer mixtures are dissolved in the solvents at room temperature and, on completion of dissolution, stored at room temperature for 36 hours. After this period, the solutions are examined visually for precipitation.
1. Three different materials that are structural isomers of one another are used. The structures are depicted in Table 1.

TABLE 1
Structures of isomeric materials.

| | |
|---|---|
| 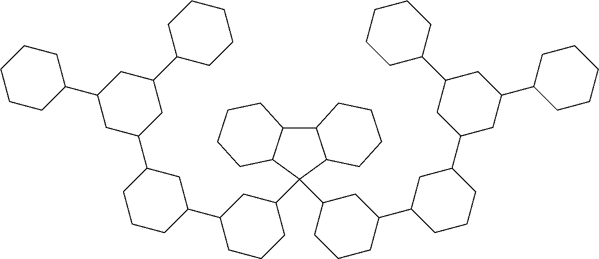 [SMILES: C1CCC(C2CC(C3CCCCC3)CC(C3CCCC(C4CCCC(C5(C6CCCC(C7CCCC(C8CC(C9CCCCC9)CC(C9CCCCC9)C8)C7)C6)C6CCCCC6C6CCCCC65)C4)C3)C2)CC1] | M1 |
| 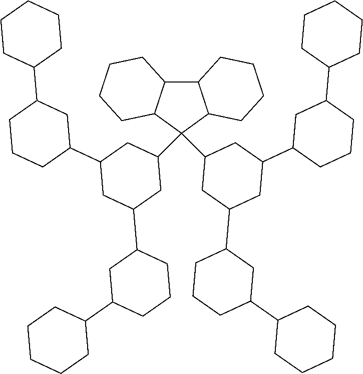 [SMILES: C1CCC(C2CCCC(C3CC(C4CCCC(C5CCCCC5)C4)CC(C4(C5CC(C6CCCC(C7CCCCC7)C6)CC(C6CCCC(C7CCCCC7)C6)C5)C5CCCCC5C5CCCCC54)C3)C2)CC1] | M2 |
| 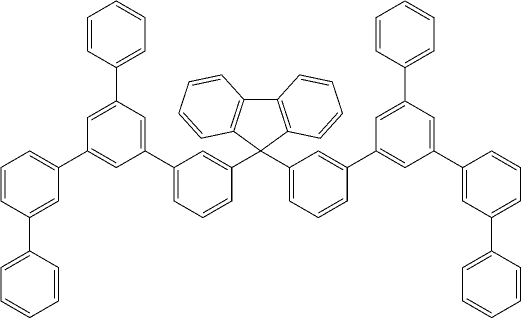 [SMILES: c1ccc(-c2cccc(-c3cc(-c4ccccc4)cc(-c4cccc(C5(c6cccc(-c7cc(-c8ccccc8)cc(-c8cccc(-c9ccccc9)c8)c7)c6)c6ccccc6-c6ccccc65)c4)c3)c2)cc1] | M3 |

The solution stability of materials M1 to M3 is examined in various solvents. All the materials dissolve completely in the solvents within a short period of time (seconds to a few minutes) under agitation. FB1 is very unstable both in 3-phenoxytoluene and in toluene, and so a distinct precipitate is visible at different concentrations after 36 hours; see Table 2.

TABLE 2
Stability of the individual materials in different solvents

| Solvent | Concentration | M1 | M2 | M3 |
|---|---|---|---|---|
| 3- | 40 g/l | unstable | stable | stable |
| Phenoxytoluene | 20 g/l | unstable | stable | stable |
| Toluene | 20 g/l | unstable | unstable | stable |
| | 10 g/l | unstable | stable | stable |

The solution stability of various isomeric mixtures of the invention is examined in various solvents. All the isomeric mixtures of the invention dissolve completely in the solvents within a short period of time (seconds to a few minutes) under agitation. Table 3 shows the results of the visual examination for precipitation. All the material mixtures of the structural isomers M1, M2 and M3, even in different concentrations, are stable in various solvents in accordance with the invention and do not show any precipitation at all, after storage at room temperature for 36 hours. It is thus possible to stabilize unstable materials, for example FB1, in combination with structural isomers.

TABLE 3
Stability of the isomer mixtures of the invention in different
solvents, where the concentration figures in g/l relate to the
concentration of the individual materials in the respective
solvents and are not a total concentration in the mixture. The
total concentration of the materials in the mixture is calculated
from the mixing ratio used (for example 80% M1 and 20%
M2), the mixing ratio being reported in % by weight.

| | | M1 | M1 | M1 | M2 |
|---|---|---|---|---|---|
| | | (50%) | (80%) | (50%) | (50%) |
| | | M2 | M2 | M3 | M3 |
| Solvent | Concentration | (50%) | (20%) | (50%) | (50%) |
| 3-Phenoxy- | 40 g/l | stable | stable | stable | stable |
| toluene | per material | | | | |
| | 20 g/l | stable | stable | — | — |
| | per material | | | | |
| Toluene | 20 g/l | stable | — | stable | stable |
| | per material | | | | |
| | 10 g/l | stable | — | stable | stable |
| | per material | | | | |

2) In a further example, two different materials that are structural isomers of one another are used. The structures are depicted in Table 4.

TABLE 4
Structures of isomeric materials.

| | |
|---|---|
| 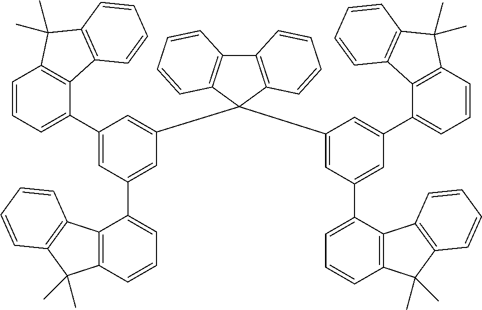 | M4 |
| 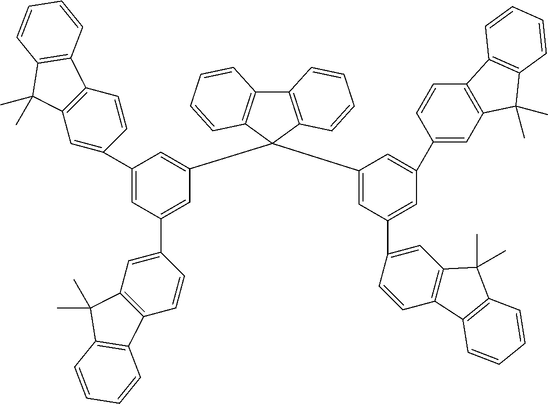 | M5 |

TABLE 5
Stability of the individual materials in different solvents

| Solvent | Concentration | M4 | M5 |
|---|---|---|---|
| 3-Phenoxy- | 20 g/l | stable | unstable |
| toluene | 10 g/l | stable | unstable |
| Toluene | 10 g/l | stable | unstable |
| Butyl benzoate | 20 g/l | stable | unstable |

TABLE 6
Stability of the isomer mixtures of the invention in different solvents

| | | M4 (50%) | M4 (30%) |
|---|---|---|---|
| Solvent | Concentration | M5 (50%) | M5 (70%) |
| 3-Phenoxy- | 20 g/l | stable | stable |
| toluene | per material | | |
| | 10 g/l | stable | stable |
| | per material | | |
| Toluene | 10 g/l | stable | stable |
| | per material | | |
| Butyl | 20 g/l | stable | unstable |
| benzoate | per material | | |

3) The solution stability of the materials M6 and M7 is examined in various solvents (for structures see Table 7). The materials dissolve completely in the solvents within a short period of time (seconds to a few minutes) under agitation. M6 is very unstable both in 3-phenoxytoluene and in toluene, and so a distinct precipitate is visible at different concentrations after 36 hours; see Table 5. M7 has much more sparing solubility in the solvents mentioned and, after storage at room temperature for 36 hours, even at low concentrations, a distinct precipitate is visible.

TABLE 7
Structures of isomeric materials.

| | |
|---|---|
| 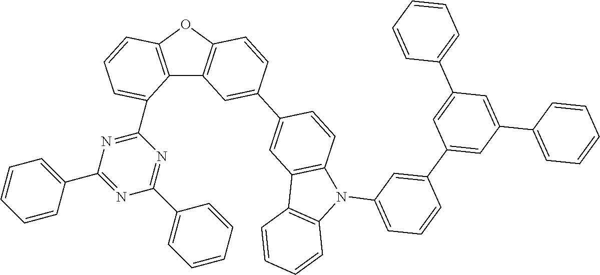 | M6 |
| 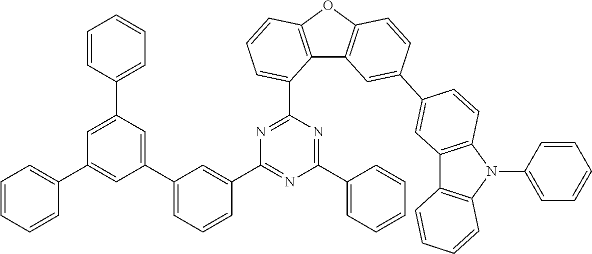 [SMILES: c1ccc(-c2cc(-c3ccccc3)cc(-c3cccc(-c4nc(-c5ccccc5)nc(-c5cccc6oc7ccc(-c8ccc9c(c8)c8ccccc8n9-c8ccccc8)cc7c56)n4)c3)c2)cc1] | M7 |

TABLE 8
Stability of the individual materials in different solvents

| Solvent | Concentration | M6 | M7 |
|---|---|---|---|
| 3-Phenoxy- | 20 g/l | stable | unstable |
| toluene | 10 g/l | stable | unstable |
| Toluene | 10 g/l | stable | unstable |

The solution stability of various isomeric mixtures of the invention is examined in various solvents. All the isomeric mixtures of the invention dissolve completely in the solvents within a short period of time (seconds to a few minutes) under agitation. Table 6 shows the results of the visual examination for precipitation. The material mixtures of the structural isomers M6 and M7, in different concentrations, are stable in accordance with the invention in various solvents and do not show any precipitation at all after storage at room temperature for 36 hours.

TABLE 9
Stability of the isomer mixtures of the invention in different
solvents.

| | | M6 (50%) |
|---|---|---|
| Solvent | Concentration | M7 (50%) |
| 3-Phenoxy- | 20 g/l | stable |
| toluene | 10 g/l | stable |
| Toluene | 10 g/l | stable |

Production of Solution-Processed OLEDs

There are already many descriptions of the production of completely solution-based OLEDs in the literature, for example in WO 2004/037887. There have likewise been many previous descriptions of the production of vacuum-based OLEDs, including in WO 2004/058911. In the examples discussed hereinafter, layers applied in a solution-based and vacuum-based manner are combined within an OLED, and so the processing up to and including the emission layer was effected from solution and in the subsequent layers (hole blocker layer and electron transport layer) from vacuum. For this purpose, the previously described general methods are matched to the circumstances described here and combined as follows.

The structure of the components is as follows:
substrate
ITO (50 nm)
hole injection layer (HIL) (20 nm)
hole transport layer (HTL) (20 nm)
emission layer (EML) (60 nm)
hole blocker layer (HBL) (10 nm)
electron transport layer (ETL) (40 nm)
cathode

Substrates used are glass plates coated with structured ITO (indium tin oxide) of thickness 50 nm. For better processing, they are coated with PEDOT:PSS (poly(3,4-ethylenedioxy-2,5-thiophene) polystyrenesulfonate, purchased from Heraeus Precious Metals GmbH & Co. KG, Germany). PEDOT:PSS is spun on from water under air and subsequently baked under air at 180° C. for 10 minutes in order to remove residual water. The hole transport layer and the emission layer are applied to these coated glass plates. The hole transport layer used is crosslinkable. A polymer of the structure shown below is used, which can be synthesized according to WO2010/097155.

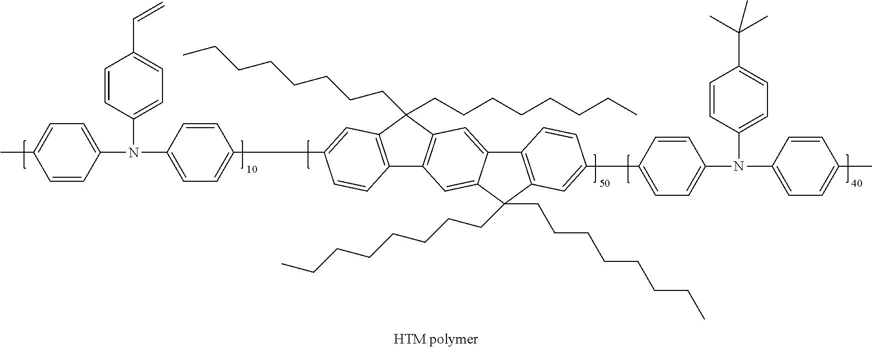

The hole transport polymer is dissolved in toluene. The typical solids content of such solutions is about 5 g/l when, as here, the layer thickness of 20 nm which is typical of a device is to be achieved by means of spin-coating. The layers are spun on in an inert gas atmosphere, argon in the present case, and baked at 180° C. for 60 minutes.

The emission layer is always composed of at least two matrix materials (host material, H) and an emitting dopant (emitter, D). In addition, mixtures of a plurality of matrix materials and co-dopants may occur. Details given in such a form as H1 (40%):H2 (40%):D (20%) mean here that the material H1 is present in the emission layer in a proportion by weight of 40%, the material H2 in a proportion by weight of likewise 40%, and the dopant D in a proportion by weight of 20%. The mixture for the emission layer is dissolved in toluene or optionally chlorobenzene. The typical solids content of such solutions is about 18 g/I when, as here, the layer thickness of 60 nm which is typical of a device is to be achieved by means of spin-coating. The layers are spun on in an inert gas atmosphere, argon in the present case, and baked at 160° C. for 10 minutes. Materials used are listed in Tables 10 and 11—these are both known compounds and isomers.

TABLE 10
Structural formulae of the materials used in the OLEDs (without
isomeric materials of the invention)

| | |
|---|---|
| 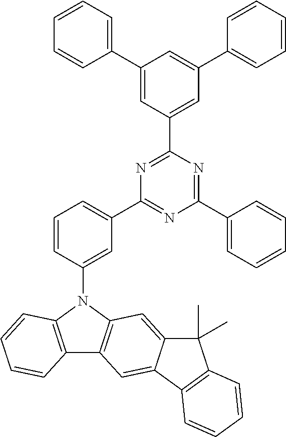 [SMILES: CC1(C)c2ccccc2-c2cc3c4ccccc4n(-c4cccc(-c5nc(-c6ccccc6)nc(-c6cc(-c7ccccc7)cc(-c7ccccc7)c6)n5)c4)c3cc21] | H1 |
| 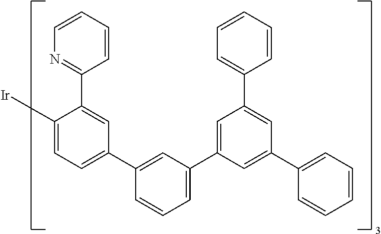 | D_G |
| 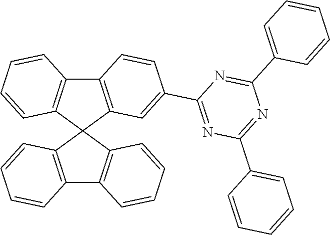 [SMILES: c1ccc(-c2nc(-c3ccccc3)nc(-c3ccc4c(c3)C3(c5ccccc5-c5ccccc53)c3ccccc3-4)n2)cc1] | ETM1 |
| 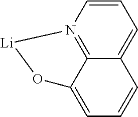 | ETM2 |

The materials for the electron transport layer are applied by thermal vapour deposition in a vacuum chamber. The electron transport layer, for example, may consist of more than one material, the materials being added to one another by co-evaporation in a particular proportion by volume. Details given in such a form as ETM1:ETM2 (50%:50%) mean here that the ETM1 and ETM2 materials are present in the layer in a proportion by volume of 50% each. The materials used in the present case are shown in Table 10. The cathode is formed by the thermal evaporation of an aluminium layer of thickness 100 nm.

TABLE 11
Structural formulae of the isomeric materials

| | |
|---|---|
| 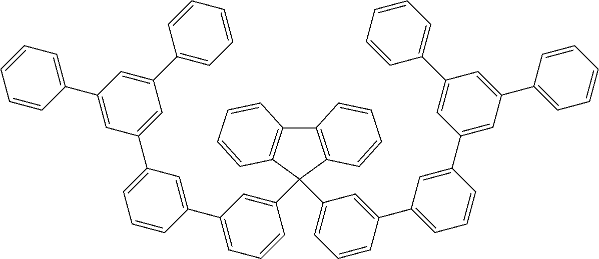 [SMILES: c1ccc(-c2cc(-c3ccccc3)cc(-c3cccc(-c4cccc(C5(c6cccc(-c7cccc(-c8cc(-c9ccccc9)cc(-c9ccccc9)c8)c7)c6)c6ccccc6-c6ccccc65)c4)c3)c2)cc1] | H2 |
| 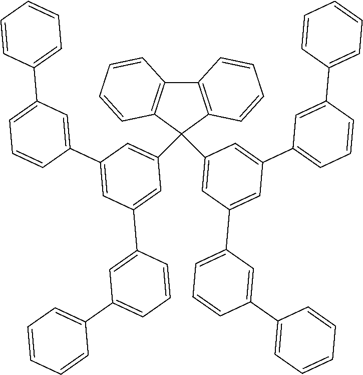 [SMILES: c1ccc(-c2cccc(-c3cc(-c4cccc(-c5ccccc5)c4)cc(C4(c5cc(-c6cccc(-c7ccccc7)c6)cc(-c6cccc(-c7ccccc7)c6)c5)c5ccccc5-c5ccccc54)c3)c2)cc1] | H3 |

The OLEDs are characterized in a standard manner. For this purpose, the electroluminescence spectra, current-voltage-luminance characteristics (IUL characteristics) assuming Lambertian radiation characteristics and the (operating) lifetime are determined. The IUL characteristics are used to determine parameters such as the operating voltage U (in V) and the external quantum efficiency (in %) at a particular brightness. LD80 @ 10 000 cd/m² is the lifetime until the OLED, given a starting brightness of 10 000 cd/m², has dropped to 80% of the starting intensity, i.e. to 8000 cd/m².

The optoelectronic characteristics of the various OLEDs are collated in Table 13. The examples Comp1 and Comp2 are comparative examples with isomerically pure mixtures; Example 11 shows data for OLEDs with isomer mixtures of the invention. According to the invention, two isomers are used in a 1:1 mixture at the same total concentration. The exact description of the materials used in the EML can be found in Table 12.

TABLE 12
EML mixtures of different device examples with specification of
the mixing ratios in per cent by weight.

| | EML composition |
|---|---|
| Comp1 | H1(20%); H2(60%); D_G(20%) |
| Comp2 | H1(20%); H3(60%); D_G(20%) |
| I1 | H1(20%); H2(30%); H3(30%); D_G(20%) |

Some of the examples are elucidated in detail hereinafter, in order to illustrate the advantages of the compounds of the invention. However, it should be pointed out that this merely constitutes a selection.

TABLE 13
Working examples comprising the isomer mixtures of the
invention

| | Efficiency | LT80 at |
|---|---|---|
| Exp. | at 1000 cd/m2 | 8000 cd/m² [h] |
| Comp1 | 75.2 cd/A | 2200 |
| Comp2 | 72.9 cd/A | 1500 |
| I1 | 74.2 cd/A | 1900 |

It is apparent in Table 13 that the OLED devices with isomer-stabilized EML ink tend to be above average in terms of efficiency and lifetime for the two comparative examples with isomerically pure EML inks. Thus, the arithmetic mean of the efficiency is about 74.05 cd/A and the lifetime LT80 at 8000 cd/m² is about 1850 hours. In view of the higher stability of the solution of the invention, as detailed particularly in Tables 2 and 3, the mixtures of the invention thus lead to synergistic advantages that were unforeseeable. Thus, the use of isomer-stabilized inks in OLED devices does not show any disadvantages at all, but tends to lead to improvements.

1.-18. (canceled)

19. A mixture comprising at least two organic-functional compounds OSM1 and OSM2 usable for production of functional layers of electronic devices, wherein the compounds OSM1 and OSM2 are constitutional isomers of one another.

20. The mixture according to claim 19, wherein the two organic-functional compounds OSM1 and OSM2 usable for production of functional layers of electronic devices are selected from the group consisting of fluorescent emitters, phosphorescent emitters, emitters that exhibit TADF (thermally activated delayed fluorescence), host materials, electron transport materials, exciton blocker materials, electron injection materials, hole conductor materials, hole injection materials, n-dopants, p-dopants, wide band gap materials, electron blocker materials and hole blocker materials.

21. The mixture according to claim 19, wherein the at least two organic-functional compounds OSM1 and OSM2 are selected from the group of the fluorenes, indenofluorenes, spirobifluorenes, carbazoles, indenocarbazoles, indolocarbazoles, spirocarbazoles, pyrimidines, triazines, lactams, triarylamines, dibenzofurans, dibenzothienes, imidazoles, benzimidazoles, benzoxazoles, benzothiazoles, 5-arylphenanthridin-6-ones, 9,10-dehydrophenanthrenes, fluoranthenes, anthracenes, benzanthracenes and fluoradenes.

22. The mixture according to claim 21, wherein the organic-functional compound OSM1 comprises at least one functional structural element and at least one substituent S1 and the organic-functional compound OSM2 comprises at least one functional structural element and at least one substituent S2, where the functional structural element of the organic-functional compound OSM1 and of the organic-functional compound OSM2 are the same.

23. The mixture according to claim 22, wherein the substituent S1 binds to the functional structural element in the organic-functional compound OSM1 at a different site from the substituent S2 in the organic-functional compound OSM2.

24. The mixture according to claim 22, wherein the substituent S1 of the organic-functional compound OSM1 and the substituent S2 of the organic-functional compound OSM2 are constitutional isomers of one another.

25. The mixture according to at least claim 22, wherein the functional structural element is selected from the group consisting of hole transport groups, electron transport groups, host material groups and wide band gap groups.

26. Mixture according to claim 22, wherein the substituent S1, the substituent S2 and/or the group B comprises a solubilizing structural element or a crosslinkable group.

27. The mixture according to claim 22, wherein the substituent S1 and the substituent S2 in each case is selected from the group consisting of phenyl, ortho-, meta- or para-biphenyl, terphenyl, quaterphenyl, 1-, 2-, 3- or 4-fluorenyl, 9,9′-diarylfluorenyl 1-, 2-, 3- or 4-spirobifluorenyl, pyridyl, pyrimidinyl, 1-, 2-, 3- or 4-dibenzofuranyl, 1-, 2-, 3- or 4-dibenzothienyl, pyrenyl, triazinyl, imidazolyl, benzimidazolyl, benzoxazolyl, benzothiazolyl, 1-, 2-, 3- or 4-carbazolyl, 1- or 2-naphthyl, anthracenyl, trans- and cis-indenofluorenyl, indenocarbazolyl, indolocarbazolyl, spirocarbazolyl, 5-aryl-phenanthridin-6-on-yl, 9,10-dehydrophenanthrenyl, fluoranthenyl, tolyl, mesityl, phenoxytolyl, anisolyl, triarylaminyl, bis(triarylaminyl), tris(triarylaminyl), hexamethylindanyl, tetralinyl, monocycloalkyl, biscycloalkyl, tricycloalkyl, alkyl, alkoxyl, alkylsulfanyl, alkylaryl, triarylsilyl, trialkylsilyl, xanthenyl, 10-arylphenoxazinyl, phenanthrenyl and triphenylenyl, each of which may be substituted by one or radicals.

28. The mixture according to claim 22, wherein the substituent S1 and the substituent S2 in each case is selected from the group consisting of more radicals phenyl, spirobifluorene, fluorene, dibenzofuran, dibenzothiophene, anthracene, phenanthrene and triphenylene groups.

29. The mixture according to claim 19, wherein the at least two organic-functional constitutional isomers have a similarity calculated according to Tanimoto in the range from 80% to less than 100%.

30. The mixture according to claim 19, wherein the at least two organic-functional compounds OSM1 and OSM2 are used in a weight ratio in the range from 1:1 to 100:1, employing the ratio of the compounds that are constitutional isomers of one another with the highest and the lowest proportion.

31. The mixture according to claim 19, wherein the mixture comprises, in addition to the at least two organic-functional compounds OSM1 and OSM2 that are constitutional isomers of one another, at least one fluorescent emitter, at least one phosphorescent emitter and/or at least one emitter that exhibits TADF (thermally activated delayed fluorescence).

32. A mixture of oligomers, polymers or dendrimers comprising one or more constitutional isomers according to claim 19, wherein one or more bonds to the respective constitutional isomer in the mixture to the polymer, oligomer or dendrimer are present rather than a hydrogen atom or a substituent.

33. A composition comprising at least one mixture according to claim 19 or a mixture of oligomers, polymers or dendrimers according to claim 31 and at least one further compound selected from the group consisting of fluorescent emitters, phosphorescent emitters, emitters that exhibit TADF (thermally activated delayed fluorescence), host materials, electron transport materials, electron injection materials, hole conductor materials, hole injection materials, electron blocker materials and hole blocker materials.

34. A formulation comprising at least one mixture according to claim 19 and at least one solvent.

35. A host material, hole conductor material or electron transport material in an electronic device comprising the mixture as claimed in claim 19.

36. A process for preparing a mixture according to claim 19 which comprises preparing and mixing two constitutional isomers.

37. A process for preparing a mixture according to claim 19 which comprises preparing by a coupling reaction two constitutional isomers.

38. An electronic device comprising at least one mixture according to claim 19, wherein the electronic device is selected from the group consisting of organic electroluminescent devices, organic integrated circuits, organic field-effect transistors, organic thin-film transistors, organic light-emitting transistors, organic solar cells, organic optical detectors, organic photoreceptors, organic field-quench devices, light-emitting electrochemical cells and organic laser diodes.
